(19) United States
(12) Patent Application Publication
(10) Pub. No.: US 2023/0262988 A1
(43) Pub. Date: Aug. 17, 2023

(54) MEMORY STRUCTURE INCLUDING THREE-DIMENSIONAL NOR MEMORY STRINGS OF JUNCTIONLESS FERROELECTRIC MEMORY TRANSISTORS AND METHOD OF FABRICATION

(71) Applicant: SUNRISE MEMORY CORPORATION, San Jose, CA (US)

(72) Inventor: Eli Harari, Saratoga, CA (US)

(21) Appl. No.: 17/936,320

(22) Filed: Sep. 28, 2022

Related U.S. Application Data
(60) Provisional application No. 63/330,622, filed on Apr. 13, 2022.
(60) Provisional application No. 63/309,994, filed on Feb. 14, 2022.

(51) Int. Cl. H01L 27/11597; H01L 27/1159; H01L 27/11592

(52) U.S. Cl. CPC H01L 27/11597; H01L 27/1159; H01L 27/11592

(57) ABSTRACT

A memory structure including three-dimensional NOR memory strings and method of fabrication is disclosed. In some embodiments, a memory structure includes randomly accessible ferroelectric storage transistors organized as horizontal NOR memory strings. The NOR memory strings are formed over a semiconductor substrate in multiple scalable memory stacks of thin-film storage transistors. The three-dimensional memory stacks are manufactured in a process that includes forming operational trenches for vertical local word lines and forming auxiliary trenches to facilitate back-alley metal replacement and channel separation by a backside selective etch process. In some embodiments, the ferroelectric storage transistors are junctionless field-effect transistors (FeFETs) having a ferroelectric polarization layer as the gate dielectric layer formed adjacent a semiconductor oxide layer as the channel region.

### CROSS REFERENCE TO RELATED APPLICATIONS

This application claims priority to U.S. Provisional Patent Application No. 63/309,994, entitled MEMORY STRUCTURE INCLUDING THREE-DIMENSIONAL NOR MEMORY STRINGS OF JUNCTIONLESS FERROELECTRIC STORAGE TRANSDISTORS AND METHOD OF FABRICATION, filed Feb. 14, 2022, and to U.S. Provisional Patent Application No. 63/330,622, entitled MEMORY STRUCTURE INCLUDING THREE-DIMENSIONAL NOR MEMORY STRINGS OF JUNCTIONLESS FERROELECTRIC MEMORY TRANSDISTORS AND METHOD OF FABRICATION, filed Apr. 13, 2022, which applications are incorporated herein by reference in their entireties.

### FIELD OF THE INVENTION

The invention relates to high-density memory structures, and in particular, the present invention relates to high-density, low read-latency memory structures formed by interconnected thin-film storage elements (e.g., 3-dimensional array of thin-film storage transistors), including those organized as NOR-type memory strings (“NOR memory strings”), and fabrication processes thereof.

### BACKGROUND OF THE INVENTION

A NOR-type memory string includes storage transistors that share a common source region and a common drain region, where each storage transistor can be individually addressed and accessed. U.S. Pat. No. 10,121,553 (the '553 Patent), entitled “Capacitive-Coupled Non-Volatile Thin-film Transistor NOR Strings in Three-Dimensional Arrays,” issued on Nov. 6, 2018, discloses storage transistors (or memory transistors) organized as 3-dimensional arrays of NOR memory strings formed above a planar surface of a semiconductor substrate. The '553 Patent is hereby incorporated by reference in its entirety for all purposes. In the '553 Patent, a NOR memory string includes numerous thin-film storage transistors that share a common bit line and a common source line. In particular, the '553 Patent discloses a NOR memory string that includes (i) a common source region and a common drain region both running lengthwise along a horizontal direction and (ii) gate electrodes for the storage transistors each running along a vertical direction. In the present description, the term “vertical” refers to the direction normal to the surface of a semiconductor substrate, and the term “horizontal” refers to any direction that is parallel to the surface of that semiconductor substrate. In a 3-dimensional array, the NOR memory strings are provided on multiple planes (e.g., 8 or 16 planes) above the semiconductor substrate, with the NOR memory strings on each plane arranged in rows. For a charge-trap type storage transistor, data is stored in each storage transistor using a charge storage film as the gate dielectric material. For example, the charge storage film may include a tunneling dielectric layer, a charge trapping layer and a blocking layer, which can be implemented as a multilayer including silicon oxide or oxynitride, silicon-rich nitride, and silicon oxide, arranged in this order and referred to as an ONO layer. An applied electrical field across the charge storage film adds or removes charge from charge traps in the charge trapping layer, thus altering the threshold voltage of the storage transistor to encode a given logical state in the storage transistor.

Advances in electrically polarizable materials (“ferroelectric materials”), especially those that are being used in semiconductor manufacturing processes, suggest new potential applications in ferroelectric memory circuits. For example, the article “Ferroelectricity in Hafnium Oxide: CMOS compatible Ferroelectric Field Effect Transistors,” by T. S. Böscke et al., published in 2011 International Electron Devices Meeting (IEDM), pp. 24.5.1-24.5.4, discloses a ferroelectric field effect transistor (“FeFET”) that uses hafnium oxide as a gate dielectric material. By controlling the polarization direction in a ferroelectric gate dielectric layer, the FeFET may be programmed to have either one of two threshold voltages. Each threshold voltage of the FeFET constitutes a state, for example, a “programmed” state or an “erased” state, that represents a designated logical value. Such an FeFET has application in high-density memory circuits. For example, U.S. Pat. No. 9,281,044, entitled “Apparatuses having a ferroelectric field-effect transistor memory array and related method,” by D. V. Nirmal Ramaswamy et al., filed on May 17, 2013, discloses a 3-dimensional array of FeFETs.

### SUMMARY OF THE INVENTION

The present disclosure discloses a memory structure including three-dimensional NOR memory strings of junctionless ferroelectric memory transistors and method of fabrication, substantially as shown in and/or described below, for example in connection with at least one of the figures, as set forth more completely in the claims.

In some embodiments, a three-dimensional memory structure formed above a planar surface of a semiconductor substrate includes multiple memory stacks arranged along a first direction, each memory stack being separated from each of its immediately neighboring memory stacks along the first direction by a trench, each memory stack and each trench extending in a second direction, the first and second directions being orthogonal to each other and both being substantially parallel to the planar surface of the semiconductor substrate. Each memory stack includes at least one active layer, the active layer including a first conductive layer and a second conductive layer spaced apart by a first isolation layer. The trenches include trenches of a first type and trenches of a second type, alternately arranged along the first direction.

The memory structure further includes multiple gate electrode structures provided in the trenches of the first type and arranged spaced apart in the second direction, the gate electrode structures extending in a third direction substantially normal to the planar surface of the semiconductor substrate. Each gate electrode structure includes (i) a semiconductor oxide layer formed on the sidewalls of the trenches of the first type and in contact with the first and second conductive layers; (ii) a ferroelectric dielectric layer provided adjacent the semiconductor oxide layer; and (iii) a gate conductor layer formed adjacent the ferroelectric dielectric layer. The memory structure further includes an isolation material provided in the trenches of the second type.

Each active layer in the memory stack forms multiple thin-film ferroelectric memory transistors organized as a NOR memory string. Each memory transistor is formed at the intersection of the active layer and a gate electrode structure. The multiple memory stacks form multiple NOR memory strings in the trenches of the first type.

These and other advantages, aspects and novel features of the present invention, as well as details of an illustrated embodiment thereof, will be more fully understood from the following description and drawings.

### BRIEF DESCRIPTION OF THE DRAWINGS

Various embodiments of the invention are disclosed in the following detailed description and the accompanying drawings. Although the drawings depict various examples of the invention, the invention is not limited by the depicted examples. It is to be understood that, in the drawings, like reference numerals designate like structural elements. Also, it is understood that the depictions in the figures are not necessarily to scale.

FIG. 1, which includes FIG. 1(a), is a perspective view of a memory structure including a 3-dimensional array of NOR memory strings in some embodiments.

FIG. 2 illustrates a cross-sectional view of a tile in a memory device of FIG. 1 in the Y-Z plane in embodiments of the present invention.

FIG. 3 illustrates an application of a memory device of the present invention as an embedded memory device in some embodiments.

FIGS. 4(a) to 4(p), including FIGS. 4(e1), 4(m1) and 4(o1), illustrate a process for fabricating a memory structure including HNOR memory strings in embodiments of the present invention.

FIG. 5(a) is a cross-sectional view of a portion of a memory structure in the X-Y plane illustrating NOR memory strings with designated precharge transistors in embodiments of the present invention.

FIG. 5(b) is a cross-sectional view of a portion of a memory structure in the X-Y plane illustrating NOR memory strings with precharge transistors in embodiments of the present invention.

FIG. 5(c) is a cross-sectional view of a portion of a memory structure in the X-Y plane illustrating NOR memory strings with precharge transistors in embodiments of the present invention.

FIGS. 6(a), 6(b), 6(c) and 6(d) illustrate the detail construction of junctionless ferroelectric storage transistors in alternate embodiments.

FIGS. 6(e) and 6(f) illustrate the detail construction of junctionless ferroelectric storage transistors in alternate embodiments.

FIG. 7 is a cross-sectional view of a memory structure including a 3-dimensional array of NOR memory strings in alternate embodiments of the present invention.

FIGS. 8(a) and 8(b) illustrate an alternate process for fabricating a memory structure including HNOR memory strings in embodiments of the present invention.

FIG. 9 illustrates a memory structure formed using dummy layers for isolating the channel layer for global word line connections in some embodiments.

FIGS. 10(a) to 10(h) illustrate an alternate process for fabricating a memory structure including HNOR memory strings in embodiments of the present invention.

### DETAILED DESCRIPTION OF THE INVENTION

In embodiments of the present invention, a memory structure includes randomly accessible ferroelectric storage transistors organized as horizontal NOR memory strings. The NOR memory strings are formed over a semiconductor substrate in multiple scalable memory stacks of thin-film storage transistors. The three-dimensional memory stacks are manufactured in a process that includes forming operational trenches for vertical local word lines and forming auxiliary trenches to facilitate back-alley metal replacement and channel separation by a backside selective etch process.

In some embodiments, the ferroelectric storage transistors are thin-film ferroelectric field-effect transistors (FeFETs) having a ferroelectric polarization layer as a gate dielectric layer. The ferroelectric polarization layer, also referred to as a “ferroelectric gate dielectric layer,” is formed adjacent a semiconductor oxide layer as a channel region. The ferroelectric storage transistors include source and drain regions—both formed of a metallic conductive material—in electrical contact with the semiconductor oxide channel region. The ferroelectric storage transistors thus formed are each a junctionless transistor without a p/n junction in the channel and in which the threshold voltage is modulated by the polarization of the mobile carriers in the ferroelectric polarization layer. In the memory structure of the present invention, the ferroelectric storage transistors in each NOR memory string are controlled by individual control gate electrodes to allow each storage transistor to be individually addressed and accessed. In some embodiments, the ferroelectric polarization layer is formed of a doped hafnium oxide material and the semiconductor oxide channel region is formed of an amorphous metal oxide semiconductor material.

In the present description, the term “storage transistor” is used interchangeably with “memory transistor” to refer to the memory device formed in the memory structure described herein. In some examples, the memory structure of the present disclosure including NOR memory strings of randomly accessible storage transistors (or memory transistors) can have applications in computing systems as the main memory where the memory locations are directly accessible by the processors of the computer systems, for instance, in a role served in the prior art by conventional random-access memories (RAMs), such as dynamic RAMs (DRAMS) and static RAMs (SRAMs). For example, the memory structure of the present disclosure can be applied in computing systems to function as a random-access memory to support the operations of microprocessors, graphical processors and artificial intelligence processors. In other examples, the memory structure of the present disclosure is also applicable to form a storage system, such as a solid-state drive or replacing a hard drive, for providing long term data storage in computing systems.

In the present description, the term “semiconductor oxide layer” (sometimes also referred to as “oxide semiconductor layer” or “metal oxide semiconductor layer”) as used herein refers to thin film semiconducting materials made from a conductive metal oxide, such as zinc oxide and indium oxide, or any suitable conductive metal oxides with charge-carriers having mobilities that can be modified or modulated using suitable preparation or inclusion of suitable impurities.

In embodiments of the present invention, the memory structure includes memory stacks where each memory stack includes multiple NOR memory strings formed one on top of another in the vertical direction. In some embodiments, the stacks of NOR memory strings are formed by groups of thin films successively deposited over a planar surface of a semiconductor substrate, each group of thin films being referred to as an “active layer” in the present description. The active layers in each stack of NOR memory strings are provided one on top of another and each active layer is separated from the other active layers by an inter-layer isolation layer. Each active layer includes a common drain line and a common source line that are arranged spaced apart in the vertical direction by a channel spacer dielectric layer. Both the common source line and the common drain line extend along a horizontal direction.

The storage transistors in each NOR memory string share the common source line and the common drain line. The channel layer of the storage transistors is formed on the sidewalls of the memory stacks, in contact with the common source line and the common drain line of each NOR memory string. Gate dielectric layers and gate conductor layers of the storage transistors are formed in a vertical direction in narrow operational trenches between the memory stacks to form storage transistors in multiple parallel planes of each stack, a storage transistor being formed at each intersection of a gate conductor layer and the common source line and the common drain line of a memory string. The gate conductor layers are also referred herein as the local word lines (LWL) and the operational trenches are sometimes referred herein as “LWL trenches.” That is, the operational or LWL trenches are trenches in which the local word line gate conductors are formed and in which storage transistors are fabricated. As mentioned above, the term “vertical” refers to the direction normal to the surface of a semiconductor substrate, and the term “horizontal” refers to any direction that is parallel to the surface of that semiconductor substrate.

In the present embodiments, the storage transistors in the NOR memory strings are ferroelectric field effect transistors including a ferroelectric thin film as the gate dielectric layer, also referred to as the ferroelectric polarization layer or ferroelectric gate dielectric layer or ferroelectric dielectric layer. In a ferroelectric field effect transistor (FeFET), the polarization direction in the ferroelectric gate dielectric layer is controlled by an electric field applied between the transistor drain terminal and the transistor gate electrode, where changes in the polarization direction alters the threshold voltage of the FeFET. In some embodiments, the electric field is applied to both the transistor drain and source terminals, relative to the transistor gate electrode. For example, the FeFET may be programmed to have either one of two threshold voltages, where each threshold voltage of the FeFET can be used to encode a given logical state. For example, the two threshold voltages of the FeFET can be used to encode a “programmed” state and an “erased” state, each representing a designated logical value. In one example, the programmed state is associated with a lower threshold voltage and the erased state is associated with a higher threshold voltage. In some embodiments, more than two threshold voltages may be established to represent more than two memory states at each FeFET.

The memory structure of the present invention realizes many advantages over known or existing memory structures and devices.

First, ferroelectric storage transistors manufactured on vertical walls are very compact and can be manufactured in three-dimensional memory stacks at lower temperatures that are compatible with logic back-end-of-line (BEOL) processes. Ferroelectric storage transistors can operate at lower voltages than conventional charge-trapping storage transistors. These characteristics of the ferroelectric storage transistors enable easy integration of a memory array of three-dimensional horizontal NOR (HNOR) memory strings directly above digital and analog integrated circuits that are built at the surface of a semiconductor substrate. Until recently, ferroelectric transistors had limited endurance. Recent advances in ferroelectric memory research has demonstrated erase/write endurance in excess of 1×10¹¹ cycles as well as fast erase and fast program operations, which enable the use of ferroelectric storage transistors in embedded memory applications. For example, Tan et al. demonstrated ferroelectric memory transistors formed on a crystalline silicon channel with endurance exceeding 10¹⁰ cycles. (See, for example, Ava Jiang Tan et al., “Ferroelectric HfO₂ Memory Transistors with High-K Interfacial Layer and Write Endurance Exceeding 10¹⁰ Cycles,” arXiv:2103.08806 [physics.app-ph], submitted Mar. 16, 2021, available at https://arxiv.org/abs/2103.08806.)

In some embodiments, the ferroelectric storage transistors, as described herein, provide high endurance, long data retention, and relatively low voltage operations for both erase and programming operations (e.g., under +/−5.0 volts). By combining the ferroelectric or polarization characteristics with the 3-dimensional organization (e.g., as the thin-film NOR memory strings described herein), the memory structure of ferroelectric storage transistors of the present invention achieves the additional benefits of high-density, low-cost memory arrays with the advantages of high-speed, randomly accessed memory circuits with low read latency.

Second, the three-dimensional memory structure of the present invention includes ferroelectric storage transistors that use semiconductor oxide layer (or a metal oxide semiconductor layer) as the junctionless channel regions, eliminating the need for heavily doped polysilicon layers for source and drain regions, resulting in a reduced thickness of each active layer in a memory stack as compared to storage transistors formed using traditional polysilicon channel regions with heavily doped semiconductor layers as the source and drain regions. In particular, semiconductor oxide channels have the advantage of high mobility for greater switching performance and without concern for electron or hole tunneling, as compared to traditional polysilicon channels. Ferroelectric storage transistors with junctionless semiconductor oxide channels also support shorter channel length than is possible with polysilicon doped channels while providing lower channel leakage and reduced GIDL (Gate Induced Drain Leakage) effect.

More specifically, the length of the junctionless channel of the ferroelectric transistor can be significantly shorter than the length of the polysilicon channel, thereby allowing the ferroelectric memory structure of the present invention to be more scalable in stack height, making it easier to deposit and etch multiple layers of three dimensional ferroelectric memory strings that make up ever taller memory stacks. In particular, a thinner active layer results in a reduced aspect ratio (AR) for etching the deep trenches between the memory stacks. In turn, reduced aspect ratios allow building more memory planes within a given total height of the three-dimensional memory structure.

In some embodiments, a memory structure of one or more memory layers (or memory planes) of ferroelectric storage transistors can be configured to serve as high density embedded memory in logic integrated circuits; the high density is made possible by the fact that the ferroelectric storage transistors are formed along the vertical walls of memory stack, therefore requiring very little physical space in the horizontal X-Y dimension. For example, the three dimensional ferroelectric memory structure of the present invention can be constructed in the form of a “skyscraper,” allows the formation of a high capacity memory circuit embedded within a logic integrated circuit. Embedding the memory structure of the present invention is made possible by virtue of the relatively low temperatures (typically under 500° C.) required to build the ferroelectric memory stacks, therefore minimizing any damage to the transistors making up the logic integrated circuits sharing the same substrate.

Third, the memory structure of the present invention is formed in a fabrication process in which the channel layer is deposited as a continuous layer on the sidewalls of the memory stacks and which is subsequently separated and isolated to each memory string in the stack by a backside selective etch process using access through a set of auxiliary trenches. In the present description, “auxiliary trenches” refer to trenches that are formed between memory stacks and in which no storage transistors are formed. In embodiments of the present invention, the auxiliary trenches are used advantageously to facilitate a backside selective etch that separates or isolates the channel layer to each memory string. In some embodiment, the auxiliary trenches may further be used to facilitate a backside selective etch that separates the ferroelectric dielectric layer, in addition to the channel layer, formed on the sidewalls of the memory stacks. Furthermore, in some embodiments, the auxiliary trenches are also used to facilitate metal replacement for the common source line and the common drain line.

More specifically, in embodiments of the present invention, the channel layer is isolated to each active layer (i.e., at each memory plane) by etching through access openings provided by a sacrificial layer that is formed between active layers and to be replaced in subsequent process steps by an inter-layer isolation layer. The sacrificial layer is removed in intermediate processing steps to provide the access openings to the backside of the channel layer. In one example, the memory stacks are formed by groups of thin films (active layers) separated by an inter-layer sacrificial layer which is to be subsequently replaced by an inter-layer isolation layer. In one example, the inter-layer sacrificial layer can be an undoped amorphous silicon layer or a silicon germanium layer or a carbon layer, and the inter-layer isolation layer replacing the sacrificial layer can be a low-K dielectric layer or can be an air-gap cavity. During intermediate processing steps, the inter-layer sacrificial layer is removed which provides access openings to the channel layer formed on the sidewall of the stacks at the areas between adjacent active layers. The exposed portion of the channel layer (referred herein as the backside of the channel layer) at each stack is etched using the access openings to separate and isolate the channel layer to each active layer, thereby forming the channel regions for the NOR memory strings in multiple planes.

Fourth, in embodiments of the present invention, the memory structure can be constructed using air gaps as insulation in the vertical direction between the active layers forming the NOR memory strings. Air gaps have a dielectric constant approximately 1.0, which is considerably lower than most dielectric materials, thereby effectively reducing the parasitic capacitance in the vertical direction between an adjacent pair of NOR memory strings in a memory stack. Using air gaps as the isolation between active layers improves the isolation between adjacent NOR memory string and enhances the performance of the memory device formed therefrom. In some embodiment, the inter-layer isolation layer between active layers includes an air gap liner layer to passivate the surfaces of the exposed cavities, the remaining unfilled portion of the cavities forming the air gap isolation.

Furthermore, in some embodiments, the memory structure can implement one or two levels of air gap isolation. As described above, inter-layer air gap isolation can be incorporated to provide insulation between active layers in an active stack. In some embodiments, the memory structure includes a second level of air gap isolation where the cavities between active layers are capped and the remaining unfilled portions of the cavities form air gap isolation in the auxiliary trenches. The air gap isolation in the auxiliary trenches provides isolation and reduces parasitic capacitive coupling between active stacks in the memory structure.

Fifth, in some embodiments, each storage transistor in the stacks of NOR memory strings are isolated from other storage transistors in both the horizontal and the vertical directions. In particular, each NOR memory string in a memory stack is isolated from other NOR memory strings in the same stack by the inter-layer isolation layer, which can be an air gap isolation. The storage transistors in each NOR memory string are further separated and isolated from each other along the NOR memory string (in the horizontal direction). For example, the portions of the channel layer between adjacent local word lines formed in the LWL trenches are removed to isolate the storage transistors along the NOR memory strings in the horizontal direction. In this manner, each storage transistor is completely isolated from any other storage transistors in the same NOR memory string or from storage transistors in NOR memory strings formed in other planes in the same memory stack. The storage transistors in each NOR memory string are controlled by individual gate conductors (also referred to as local word lines or LWL) to allow each storage transistor to be individually addressed and accessed. In some cases, the storage transistors are only isolated in the vertical direction by the inter-layer isolation layer and the channel layer between adjacent local word lines may remain in the LWL trenches. Isolation of the storage transistors in a NOR memory string in the horizontal direction is optional and may be omitted in some embodiments.

These and other advantages of the memory structure of the present invention will be described further in the following description. In the present description, to facilitate reference to the figures, a Cartesian coordinate reference frame is used, in which the Z-direction is normal to the planar surface of the semiconductor surface and the X-direction and the Y-directions are orthogonal to the Z-direction and to each other, as indicated in the figures.

Furthermore, the drawings provided herein are idealized representations to illustrate embodiments of the present disclosure and are not meant to be actual views of any particular component, structure, or device. The drawings are not to scale, and the thickness and dimensions of some layers may be exaggerated for clarity. Variations from the shapes of the illustrations are to be expected. For example, a region illustrated as a box shape may typically have rough and/or nonlinear features. Sharp angles that are illustrated may be rounded. Like numerals refer to like components throughout.

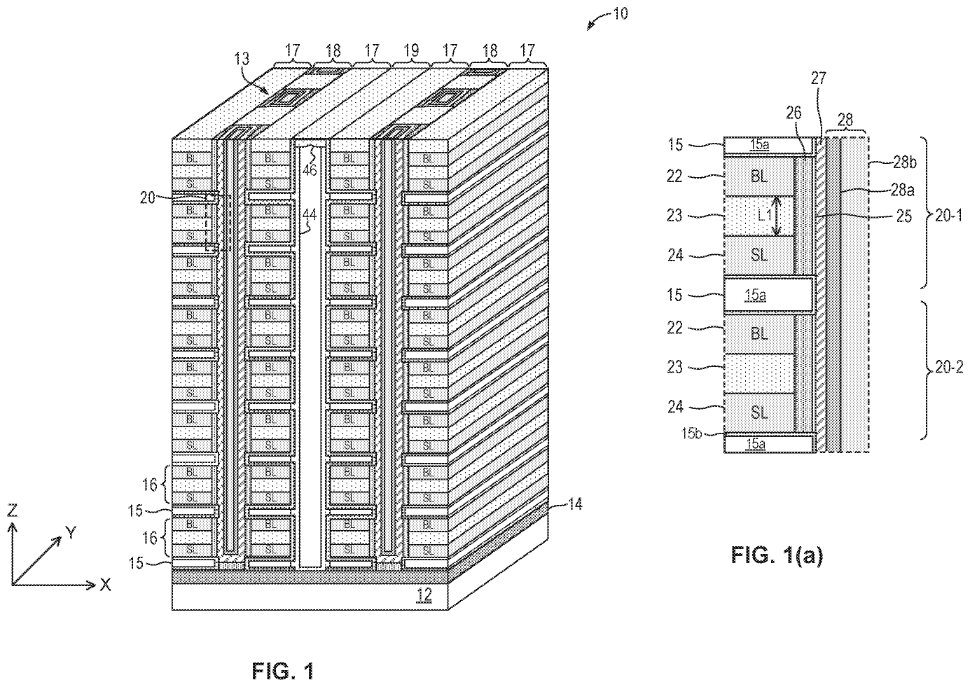

FIG. 1, which includes FIG. 1(a), is a perspective view of a memory structure including a 3-dimensional array of NOR memory strings in some embodiments. The memory structure can be used to implement part of a semiconductor memory device in some examples. Referring to FIG. 1, a memory structure 10 includes a number of active layers 16 formed on a planar surface of a semiconductor substrate 12. An insulating layer 14 may be provided between the semiconductor substrate 12 and the active layers 16 formed on the substrate. The active layers 16 are formed one on top of another in the Z-direction (i.e., along a direction normal to the planar surface of the substrate 12) and separated from each other by an inter-layer isolation layer 15. The active layers 16 are divided in the X-direction into narrow strips (“active strips”) that are stacked one on top of another to form stacks 17 of active strips (“active stacks”) extending in the Y-direction. The stacks 17 are also referred to as memory stacks in the present description.

In the present embodiment, the active stacks 17 of the memory structure 10 are separated by narrow trenches including operational trenches 18 (also referred to as “LWL trenches”) and auxiliary trenches 19. In particular, the active stacks 17 are separated by alternating operational trenches 18 and auxiliary trenches 19. In the present description, operational trenches 18 are narrow trenches between active stacks 17 in which the local word line structures are provided and storage transistors are formed. Auxiliary trenches 19 are narrow trenches between active stacks 17 where no storage transistors are formed.

Each active layer 16 includes first and second low resistivity conductive layers (e.g., titanium nitride (TiN)-lined tungsten (W)) separated by a channel spacer dielectric layer (e.g., silicon oxide). During intermediate processing steps, the active layer may include sacrificial layers (e.g., silicon nitride) to be subsequently replaced by conductive layers. Subsequent processing steps form the channel layers, the gate dielectric layers, and the gate conductor layers in the operational trenches 18 between the separated active stacks. The gate conductor layers and the gate dielectric layers are formed as columnar structures extending in the Z-direction. In the present description, the gate conductor layers are also referred to as “local word lines” and the gate conductor layer with a gate dielectric layer is collectively referred to a local word line (LWL) structure 13. The first and second conductive layers of each active strip form a drain region (“common bit line”) and a source region (“common source line”), respectively, of the storage transistors. In the present embodiment, the storage transistors are formed along the vertical side of the active stacks 17 facing the operational trenches 18. In particular, a storage transistor 20 is formed at the intersection of an active strip with the channel layer and an LWL structure 13. The local word line structures 13 in each trench 18 are separated from each other by a dielectric-filled shaft.

FIG. 1(a) illustrates the detail construction of the storage transistor 20 formed in the memory structure 10 in some embodiments. In particular, FIG. 1(a) illustrates a pair of storage transistors 20-1 and 20-2 in two adjacent planes of an active stack 17, also referred to as a memory stack. Referring to FIG. 1(a), the storage transistor 20 includes a first conductive layer 22 forming the drain region (the common drain line or the common bit line) and a second conductive layer 24 forming the source region (the common source line), the conductive layers being spaced apart by the channel spacer dielectric layer 23. The storage transistor 20 further includes the channel layer 26 formed vertically along the sidewall of the memory stack and in contact with both the first conductive layer 22 and the second conductive layer 24. The gate dielectric layer 27 and the gate conductor layer 28 are formed on the sidewall of the memory stack. The storage transistor 20 is isolated from adjacent storage transistors in the stack by an inter-layer isolation layer 15. As thus configured, along each active strip (in the Y-direction), the storage transistors that share the common source line and the common bit line form a NOR memory string (referred herein as a “Horizontal NOR memory string” or “HNOR memory string”).

In embodiments of the present invention, the storage transistors in the memory structure 10 are junctionless ferroelectric storage transistors. Accordingly, each storage transistor 20 includes only conductive layers as the source and drain regions, without any semiconductor layers. The first and second conductive layers are formed using a low resistivity metallic conductive material. In some embodiments, the first and second conductive layers are metal layers, such as a titanium nitride (TiN)-lined tungsten (W) layer, a tungsten nitride (WN)-lined tungsten (W) layer, a molybdenum nitride (MoN) lined molybdenum (Mo) layer, or a liner-less tungsten or molybdenum or cobalt layer, or other metal layers. The channel spacer dielectric layer 23 between the first and second conductive layers may be a low-k dielectric layer, such as silicon oxide (SiO₂). The channel layer 26 is a semiconductor oxide layer. In some examples, the channel layer 26 is formed using an amorphous oxide semiconductor material, such as indium gallium zinc oxide (InGaZnO or IGZO), indium zinc oxide (IZO), indium tungsten oxide (IWO), or indium tin oxide (ITO), or other such semiconductor oxide materials. A semiconductor oxide channel region has the advantage of a high mobility for greater switching performance and without concern for electron or hole tunneling. For example, an IGZO film has an electron mobility of 10.0-100.0 cm²/V, depending on the relative compositions of indium, gallium, zinc and oxygen.

To form the ferroelectric storage transistor, the storage transistor 20 includes a ferroelectric gate dielectric layer or ferroelectric polarization layer 27 in contact with the channel layer 26. The ferroelectric polarization layer 27 serves as the storage layer of the storage transistor. In some embodiments, an interfacial layer 25 may be provided between the semiconductor oxide channel layer 26 and the ferroelectric polarization layer 27. The interfacial layer 25 is a thin layer and may be 0.5 nm to 2 nm thick. In some embodiments, the interfacial layer is formed using a material with a high dielectric constant (K) (also referred to as “high-K” material). In some embodiments, the interfacial layer 25 may be a silicon nitride (Si₃N₄) layer, or a silicon oxynitride layer, or an aluminum oxide (Al₂O₃) layer. In one example, the interfacial layer, if present, may have a thickness of 1.5 nm when the ferroelectric polarization layer has a thickness of 4-5 nm. The inclusion of the interfacial layer 25 in FIG. 1(a) is illustrative only and not intended to be limiting. The interfacial layer 25 is optional and may be omitted in other embodiments of the present invention. In other embodiments, the interfacial layer 25, when included, may be formed as a multilayer of different dielectric materials. In the present description, a material with a high dielectric constant or a high-K material refers to a material with a dielectric constant greater than the dielectric constant of silicon dioxide.

In some embodiments, the ferroelectric polarization layer is formed of a doped hafnium oxide material, such as zirconium-doped hafnium oxide (HfZrO or “HZO”). In other embodiments, the hafnium oxide can be doped with silicon (Si), iridium (Ir) or lanthanum (La). In some embodiments, the ferroelectric polarization layer is a material selected from: zirconium-doped hafnium oxide (HZO), silicon-doped hafnium oxide (HSO), aluminum zirconium-doped hafnium oxide (HfZrAlO), aluminum-doped hafnium oxide (HfO₂:Al), lanthanum-doped hafnium oxide (HfO₂:La), hafnium zirconium oxynitride (HfZrON), hafnium zirconium aluminum oxide (HfZrAlO), and any hafnium oxide that includes zirconium impurities.

The ferroelectric polarization layer contacts the channel layer 26 on one side and the gate conductor layer 28 on the opposite side. In some embodiments, the gate conductor layer 28 includes a conductive liner 28a as an adhesion layer and a low resistivity conductor 28b. In some examples, the conductive liner 28a is a titanium nitride (TiN) layer, a tungsten nitride (WN) layer, or a molybdenum nitride (MoN), and the conductor 28b is formed using tungsten or molybdenum, or other metals. In some cases, the conductive liner 28a is not needed and the gate conductor layer 28 includes only the low resistivity conductor 28b, such as a liner-less tungsten or molybdenum layer. In other examples, the conductor 28b can be heavily doped n-type or p-type polysilicon, which can be used with or without the conductive liner. The gate conductor layer 28, including the conductive liner 28a (if any) and the conductor 28b, together forms the control gate electrode of the storage transistor and functions as the local word line in the memory structure.

As thus constructed, the semiconductor oxide channel layer 26 forms an N-type, unipolarity channel region where the conductive layers 22, 24 forming the drain and source terminals directly contact the channel region. The ferroelectric storage transistor thus formed is a depletion mode device where the transistor is normally on (i.e., conducting) and can be turned off (i.e., non-conducting) by depleting the N-type carriers in the channel region. The threshold voltage of the ferroelectric storage transistor is a function of the thickness (X-direction) of the semiconductor oxide channel layer 26. That is, the threshold voltage of the ferroelectric storage transistor is the amount of voltage necessary to deplete the carriers within the thickness of the semiconductor oxide channel region to shut off the ferroelectric storage transistor.

Each storage transistor 20 is isolated from adjacent storage transistors along an active stack (in the Z-direction) by the inter-layer isolation layer 15. In the present embodiment, the inter-layer isolation layer 15 is an air gap isolation formed by an air gap cavity 15a and an optional air gap liner 15b. The air gap liner 15b is a dielectric layer used to cover or passivate the exposed surface of the air gap cavity 15a. In some embodiments, the air gap liner 15b is a silicon nitride layer or an aluminum oxide (Al₂O₃) layer. The air gap liner 15b may be 1 nm-3 nm thick. In FIG. 1(a), elements are sometimes exaggerated in size for illustrative purposes only. It is understood that the depictions in this and other figures are not necessarily to scale. The air gap cavities 15a forming the inter-layer isolation layer 15 provides effective isolation between adjacent storage transistors 20 along a memory stack. In embodiments of the present invention, the inter-layer isolation layer 15 is also used to provide physical separation between the channel layer 26 of one storage transistor and the channel layer of the storage transistors above or below it in the same memory stack, thereby providing isolation of each storage transistor in a memory stack.

Returning to FIG. 1, in the exemplary embodiment as shown, the memory structure 10 includes a dielectric layer 44 which serves as a capping layer to cap the air gap cavities 15a. In some embodiments, the dielectric layer 44 is a non-conformally deposited dielectric layer, such as a silicon oxide (SiO₂) layer or silicon nitride (Si₃N₄), and is formed to cap the ends of the inter-layer cavities facing the auxiliary trenches 19. The memory structure 10 further includes a dielectric layer 46 as a capping layer to cap the top portions of the auxiliary trenches 19. In some embodiments, the dielectric layer 46 is the same dielectric material as the dielectric layer 44. As thus formed, the memory structure 10 includes two levels of air gap isolation. A first level of air gap isolation is provided as the inter-layer air gap isolation 15a between the active layers 16 in the memory stacks. The first level of air gap isolation provides isolation between storage transistors formed in a memory stack 17. The second level of air-gap isolation is provided in the auxiliary trenches 19 and provides isolation and reduces the parasitic capacitance between adjacent memory stacks 17.

In embodiments of the present invention, the three-dimensional array of NOR memory strings of ferroelectric storage transistors can be applied to implement a non-volatile memory device or a quasi-volatile memory device. For example, a quasi-volatile memory has an average retention time of greater than 100 ms, such as about 10 minutes or a few hours, whereas a non-volatile memory device may have a minimum data retention time exceeding 5 years. As a quasi-volatile memory, the ferroelectric storage transistor 20 may require refresh from time to time to restore the intended programmed and erased polarization states. For example, the ferroelectric storage transistors 20 in memory structure 10 may be refreshed every few minutes or hours. In particular, the ferroelectric storage transistors in the present disclosure can form a quasi-volatile memory device where the refresh intervals can be on the order of hours, significantly longer than the refresh intervals of DRAMs which require much more frequent refreshes, such as in tens of milli-seconds.

A salient feature of the ferroelectric storage transistor 20 is that the storage transistor can have a very short channel length, which is operative to increase the voltage separation between the different threshold voltages, while the memory structure 10 can be manufactured without requiring costly lithography techniques to realize the short channel length. In particular, the channel length of the ferroelectric storage transistor 20 is determined by the thickness L1 of the channel spacer dielectric layer 23 (FIG. 1(a)). The thickness L1 can be accurately controlled during the deposition of the sublayers 22, 23, 24 forming the initial memory stack. The ability to control the thickness L1 by deposition process, together with the very low channel leakage of semiconductor oxide channel layer, make it possible to provide a ferroelectric storage transistor 20 with very short channel length, such as a channel length of 5 nm, without needing to employ costly lithography such as extreme ultraviolet scanners (EUV) that are necessary to pattern short channels in planar transistors. In some embodiments, the thickness L1, or the channel length of the storage transistor, can be between 5 nm and 20 nm, or between 5-7 nm.

Referring again to FIG. 1, to complete the memory circuit, various types of circuitry are formed in or at the surface of the semiconductor substrate 12 to support the operations of the HNOR memory strings. Such circuits are referred to as “circuits under array” (“CuA”) and may include digital and analog circuitry such as decoders, drivers, sense amplifiers, sequencers, state machines, exclusive OR circuits, memory caches, multiplexers, voltage level shifters, voltage sources, latches and registers, and connectors, that execute repetitive local operations such as processing random address, activate, erase, program, read, and refresh commands with the memory arrays formed above the semiconductor substrate 12. In some embodiments, the transistors in the CuA is built using a process optimized for the control circuits, such as an advanced manufacturing process that is optimized for forming low-voltage and faster logic circuits. In some embodiments, the CuA is built using fin field-effect transistors (FinFET) or gate-all-around field-effect transistors (GAAFET) to realize a compact circuit layer and enhanced transistor performance.

In some embodiments, the CuA provides the data path to and from the memory array and further to a memory controller that may be built on the same semiconductor substrate as the CuA. Alternatively, the memory controller may reside on a separate semiconductor substrate, in which case the CuA and the associated data path are electrically connected to the memory controller using various bonding techniques. In some examples, the memory controller includes control circuits for accessing and operating the storage transistors in the memory array connected thereto, performing other memory control functions, such as data routing and error correction, and providing interface functions with systems interacting with the memory array.

The memory structure 10 of FIG. 1 illustrates a construction of a 3-dimensional array of NOR memory strings in some embodiments. In some embodiments, the memory structure 10 is fabricated in a process that realizes advantageous features for the memory structure. First, the memory structure 10 is formed so that the storage transistors in the 3-dimensional array of NOR memory strings are individually isolated from other storage transistors. In particular each storage transistor is isolated in the vertical direction by the inter-layer isolation layer and also optionally isolated in the horizontal direction by isolating the channel layer to each local word line structure 13, as shown in FIG. 1. The performance characteristics of the storage transistors can be enhanced by individually isolating each storage transistors. Second, the channel layer can be deposited conformally and then channel separation between active layers in the memory stacks is realized by etching the channel backside through access openings formed by a sacrificial layer. This results in a simplified and more reliable process for forming the channel layer. Third, after the removal of the inter-layer sacrificial layer for channel separation, the remaining cavities between active layers can form air gap isolation between the active layers, realizing better isolation than most dielectric materials.

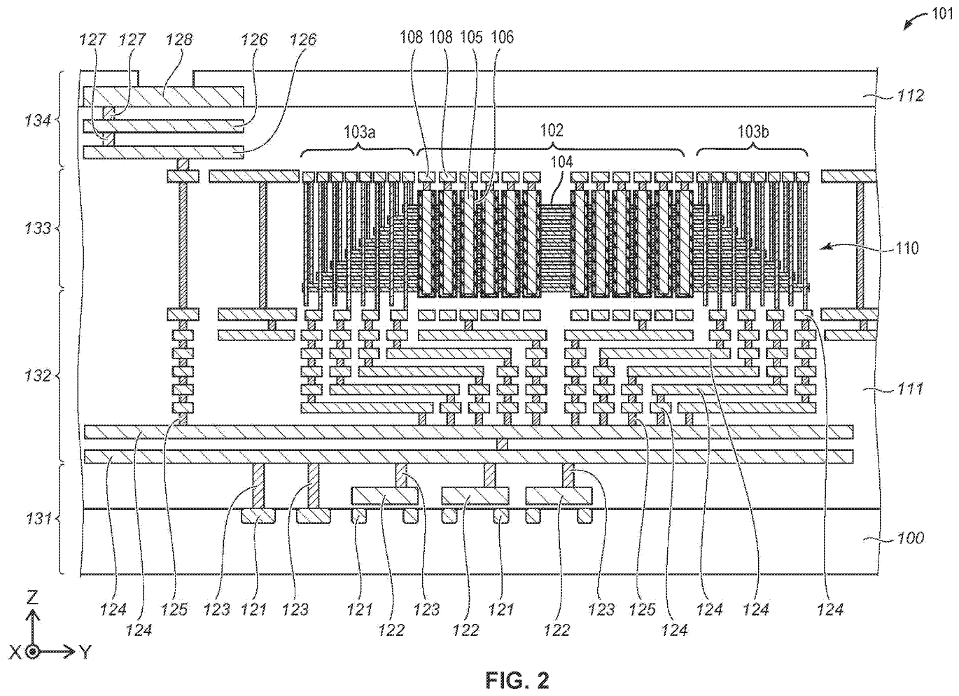

In embodiments of the present disclosure, the memory structure includes a memory array portion constructed as described above to form the 3-dimensional array of NOR memory strings. To complete the memory device, the memory structure includes staircase portions provided at the ends of the memory strings (in the Y-directions), as shown in FIG. 2 below. The thin-film storage transistors of the NOR memory strings are formed in the memory array portion while the staircase portions, on opposite sides of the array portion, include staircase structures to provide connections through conductive vias to the common bit lines and, optionally, the common source lines, of the NOR memory strings. In some embodiments, the common source lines are pre-charged to serve as virtual voltage reference source during programming, reading and erase operations, thereby obviating the need for a continuous electrical connection with the support circuitry during such operations. In the present description, the common source lines are described as being electrically floating to refer to the absence of a continuous electrical connection to the common source lines. In embodiments of the present disclosure, various processing steps for forming staircase structures in the memory structure can be used. The processing steps for forming the staircase structures can be before, after, or interleaved with the processing steps for forming the memory array portion.

The memory structure 10 of FIG. 1 illustrates the construction of a memory array including a three-dimensional array of NOR memory strings. The memory structure 10 can be used as a building block for forming a high capacity, high density memory device. In embodiments of the present disclosure, the memory structure 10 represents a modular memory unit, referred to as a “tile,” and a memory device is formed using an array of the modular memory units. In one exemplary embodiment, a memory device is organized as a two-dimensional array of tiles, arrayed along the X- and Y-directions, where each tile includes a three-dimensional array of ferroelectric storage transistors with support circuitry for each tile formed under the respective tile. More specifically, a memory device includes multiple memory arrays of thin-film ferroelectric storage transistors organized as a 2-dimensional array of “tiles” (i.e., the tiles are arranged in rows and columns) formed above a planar semiconductor substrate. Each tile can be configured to be individually and independently addressed or larger memory segments (e.g., a row of tiles or a 2-dimensional block of tiles) may be created and configured to be addressed together. In some examples, each row of tiles (a “tile row”) may be configured to form an operating unit, which is referred to as a “bank”. A group of banks, in turn, form a “bank group.” In that configuration, the banks within a bank group may share data input and output buses in a multiplexed manner. As thus configured, the tile is a modular unit that allows flexibility in configuring the memory module to adapt to application requirements.

FIG. 2 illustrates a cross-sectional view of a tile in a memory device of FIG. 1 in the Y-Z plane in embodiments of the present invention. Referring to FIG. 2, a tile 101 is formed on a semiconductor substrate 100. The memory structure of the tile 101 is formed in an insulating film 111 with a passivation film 112 formed thereon. In some embodiments, the insulating film 111 is formed of silicon oxide (SiOₓ) and the passivation film 112 is formed of polyimide. The memory structure includes a three-dimensional array of junctionless ferroelectric storage transistors (“memory array”), constructed as described with reference to the memory structure 10 of FIG. 1. P-type or N-type diffusion regions 121 are formed in the upper surface of the semiconductor substrate 100. Other structures (not shown in FIG. 2), such as isolation structures or shallow trench isolation (STI) structures, may also be formed in the semiconductor substrate 100. Gate electrodes 122 are formed on and insulated from the semiconductor substrate 100 by a gate dielectric layer. For example, the gate dielectric layer may be a thin silicon oxide layer. The gate electrodes 122 together with the P-type and N-type diffusion regions 121 form transistors in the semiconductor substrate 100, where the transistors can be used to form circuit elements. For example, the transistors can be used to form the support circuitry for operating the storage transistors in the 3-D NOR memory array formed in the tile 101. The circuit elements are interconnected to form the support circuitry by contacts 123 connecting to one or more layers of interconnects 124 and vias 125 formed in the insulating film 111 in a lower interconnect portion 132. In some embodiments, the support circuitry of the semiconductor memory device is formed in the circuit element portion 131 and the lower interconnect portion 132.

In the tile 101, a 3-D NOR memory array 110 is formed in a memory array portion 133. An upper interconnect portion 134 is formed on the memory array portion 133. Interconnects 126 and vias 127 are provided in the insulating film 111 in the upper interconnect portion 134 for forming additional electrical connections. In some embodiments, a conductive pad 128 is provided in the upper interconnect portion 134 for connecting to circuit elements external to the semiconductor memory device. For instance, the passivation film 112 is formed on and encapsulates the upper interconnect portion 134 with an opening exposing at least a part of the conductive pad 128.

In the memory array portion 133, the thin-film storage transistors are organized as a three-dimensional array of NOR memory strings in the memory array portion 102. The memory array portion 102 is provided between staircase portions 103a and 103b. Connections through conductive vias to common bit lines and, optionally, common source lines, of the NOR memory strings are provided in the staircase portions 103a and 103b. In some embodiments, the common source lines are precharged and then held at a relatively constant voltage to serve as a virtual voltage reference during programming, erase and read operations, thereby obviating the need for a continuous electrical connection with the support circuitry during such operations. In FIG. 2, the array portion 102 and the staircase portions 103a and 103b are not drawn to scale. For example, the array portion 102 may be much larger in area than either of staircase portions 103a and 103b.

In the memory array portion 102, the thin film storage transistors are formed at the intersection of the common drain line and common source line (collectively referenced by numeral 104) and a local word line 105. A gate dielectric layer 106 is formed between the conductive local word line and the channel layer (not shown in FIG. 2). With the common drain lines and common source lines arranged in multiple planes running in the Y-direction and the local word lines 105 formed as columnar structure extending in the Z-direction and arranged in the Y-direction, storage transistors are formed in a three-dimensional array on multiple planes in the Z-direction, along each memory string in the Y-direction and arranged in multiple rows in the X-direction. In FIG. 2, global word lines conductors 108 provide electrical connectivity between circuits 122 under memory array 110, and local word lines 105 associated with the three-dimensional memory stacks.

In the above-described embodiments, the supporting circuitry is described as being formed under the memory array portion 133. Such configuration is illustrative only and not intended to be limiting. For example, in other embodiments, both the memory array portion and the supporting circuitry may be directly formed on the semiconductor substrate 100. In such a case, for example, the supporting circuitry may be located at the periphery of the memory array portion. In other embodiments, the supporting circuitry may be formed on another semiconductor substrate. In such a case, for example, the semiconductor substrate in which the memory array portion is formed and the semiconductor substrate in which the supporting circuitry is formed are bonded after formation of the respective memory and circuit elements.

FIG. 2 illustrates one exemplary embodiment of a tile or a modular unit of a memory array. The depiction of the tile 101 in FIG. 2 is illustrative only and not intended to be limiting. FIG. 2 is provided to illustrate the incorporation of the memory structure 10 of FIG. 1 to form a modular memory unit (“tile) which can then be used to form a memory device including multiple arrays of three-dimensional junctionless ferroelectric storage transistors to provide the desired memory capacity at a high-density level.

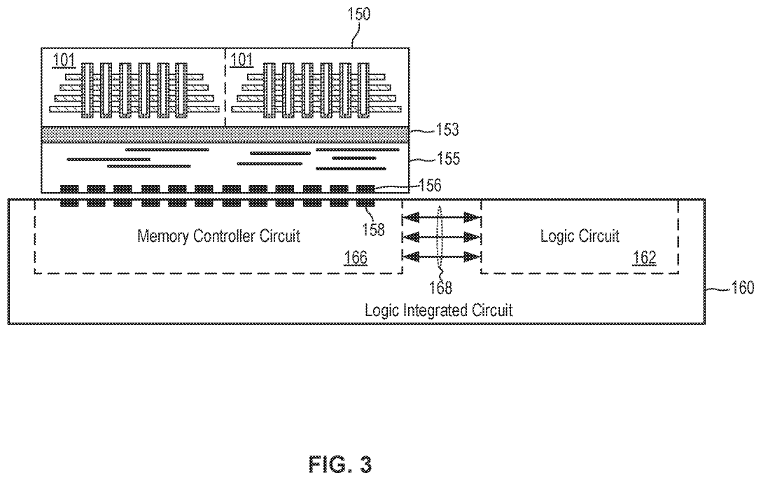

FIG. 3 illustrates an application of a memory device of the present invention as an embedded memory device in some embodiments. Referring to FIG. 3, a memory device 150 is constructed in the manner described above with reference to FIGS. 1 and 2 and includes a two-dimensional array of tiles 101, where each tile includes a memory array being a three-dimensional array of junctionless ferroelectric storage transistors. The memory arrays in tiles 101 are formed above a semiconductor substrate 155. An insulating layer 153 may be provided between the semiconductor substrate 155 and the memory arrays (tiles 101) formed on the substrate. Support circuitry (CuA) for operating the storage transistors in the memory arrays are formed in the semiconductor substrate 155. In some examples, the support circuitry for the ferroelectric storage transistors of each tile is provided for modularity in the portion of the semiconductor substrate underneath each tile.

In some embodiments, the memory device interacts with a memory controller to perform memory operations. As described above, the memory controller includes control circuits for accessing and operating the storage transistors in the memory device, and performing memory control functions, and managing interface functions for host access. In some embodiments, a memory module is formed with the memory device formed on one semiconductor die and the memory controller formed on a separate semiconductor die. The memory die and the memory controller die may be integrated using a variety of integration techniques, such as using TSVs, hybrid bonds, exposed contacts, interposers, printed circuit boards and other suitable interconnect techniques, especially techniques for high density interconnects.

In the present embodiment, the memory controller is embedded in the semiconductor substrate of a logic integrated circuit 160. In particular, the logic integrated circuit 160 may have formed thereon digital or analog logic circuits 162, such as a core processor. The memory controller circuit 166 is integrated into the logic integrated circuit 160 and formed in a portion of the semiconductor substrate of the logic integrated circuit 160. The memory device 150 is bonded to and electrically connected to the memory controller circuit 166 using various bonding techniques. In the present illustration, the memory device 150 includes an array of connectors 156 which are bonded to corresponding mating connectors 158 formed on the logic integrated circuit 160. In some embodiments, the connectors 156 and 158 are hybrid integration bonds, such as copper to copper bonds and may have a pitch of less than 2 micron or less than 1 micron.

As thus configured, the memory device 150, through embedded memory controller 166, operates as an embedded memory circuit in logic integrated circuit 160. The memory controller circuit 166 can be connected to the digital or analog circuits 162 on the logic integrated circuit 160 directly through interconnect lines 168 formed in the logic integrated circuit, without going through any interface circuits. Accordingly, the ferroelectric storage transistors in the memory device 150 become available to circuitry of the logic integrated circuit 160 with minimal delays. That is, the storage transistors can be accessed with low latency through the direct connectors 168 between the memory controller circuit 166 and the logic circuits 162. Such a configuration is sometimes referred to as “in memory compute.” In memory compute is particularly desirable in artificial intelligence and machine learning applications that are data intensive, and which require a great deal of memory in close proximity to the CPU and GPU core processors, which can be formed as the logic circuit 162 in the logic integrated circuit 160. In embodiments of the present invention, memory device 150, including arrays of three-dimensional NOR memory strings of ferroelectric storage transistors, can be used to form an embedded memory circuit to realize a low latency, high capacity in memory compute system for data intensive applications.

In some embodiments, the memory device 150 may be built directly on top of the logic integrated circuit 160 on the same semiconductor substrate. For example, the memory device 150 may be built on top of an insulating layer formed on the logic integrated circuit to protect the circuitry already manufactured. For example, the insulating layer may be a silicon oxide layer or a passivation layer, such as a polyimide layer. Electrical connections between the memory device 150 and the memory control circuit or directly to other application-specific logic circuits are provided through vias formed in the insulating layer. In this case, bonding of the memory device through connectors 156 is obviated.

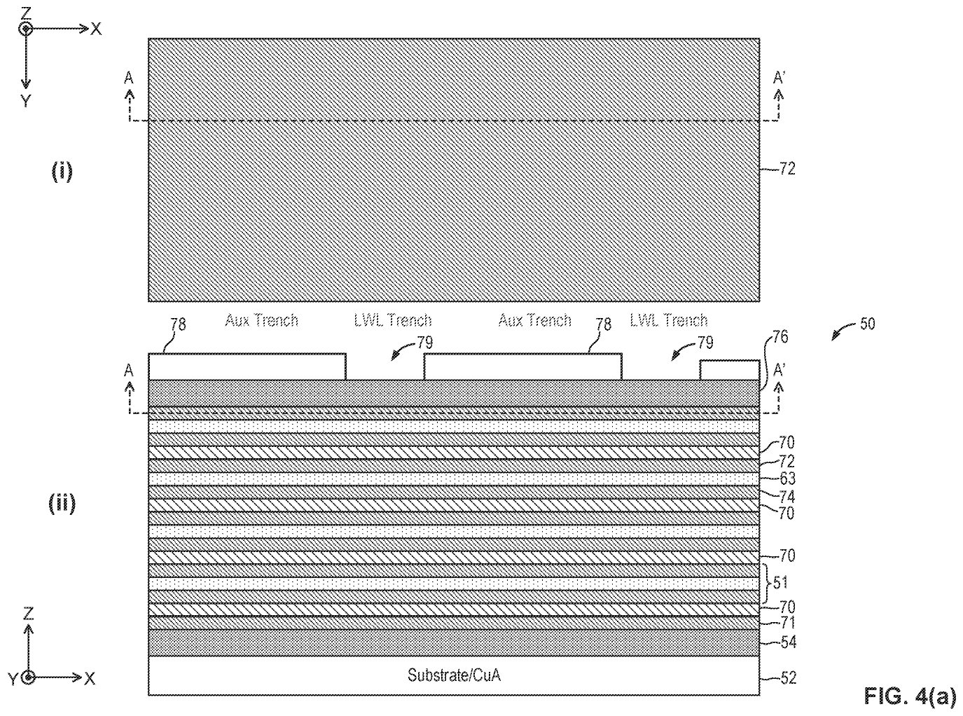

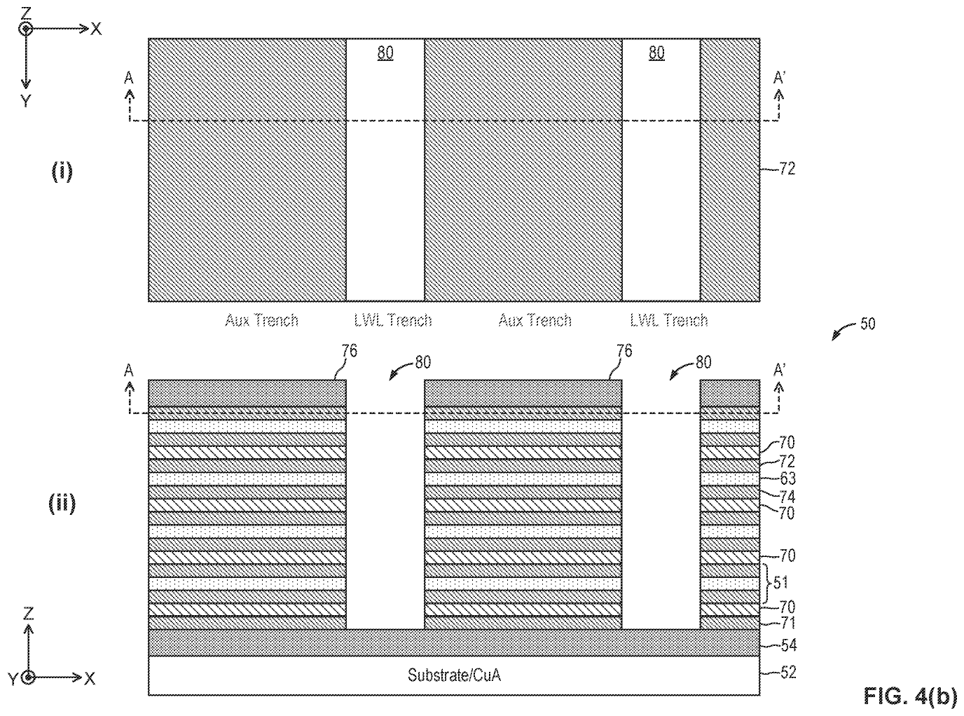

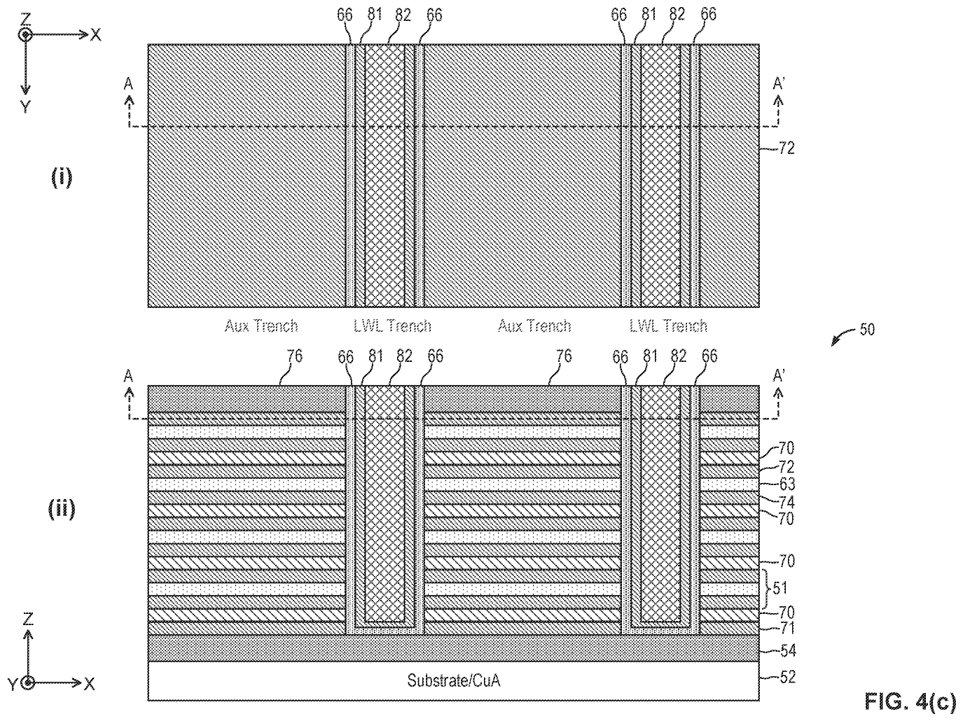

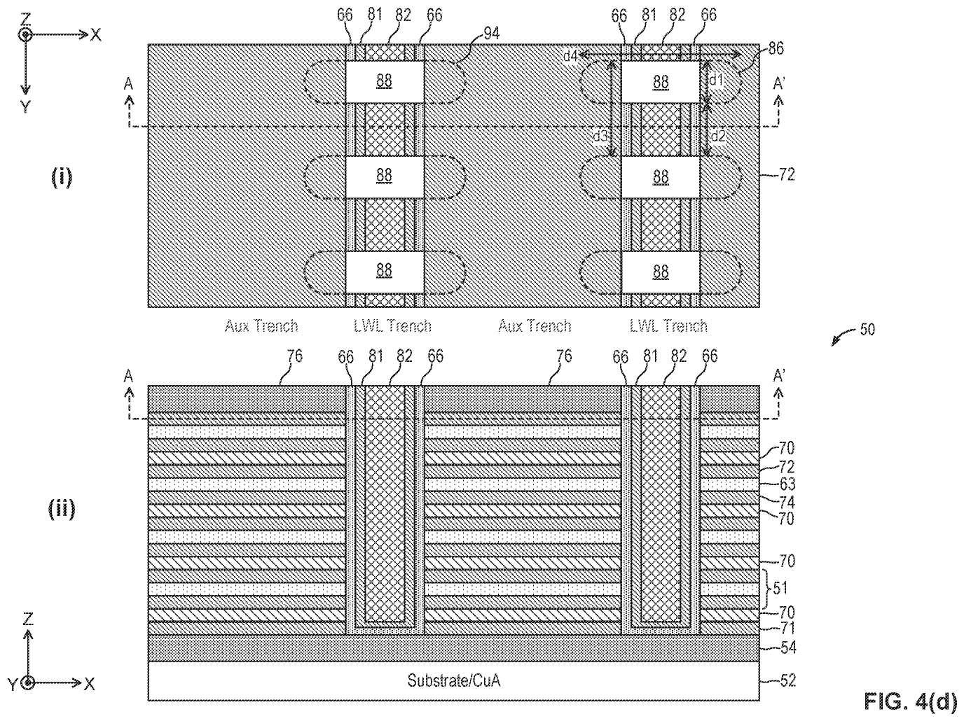

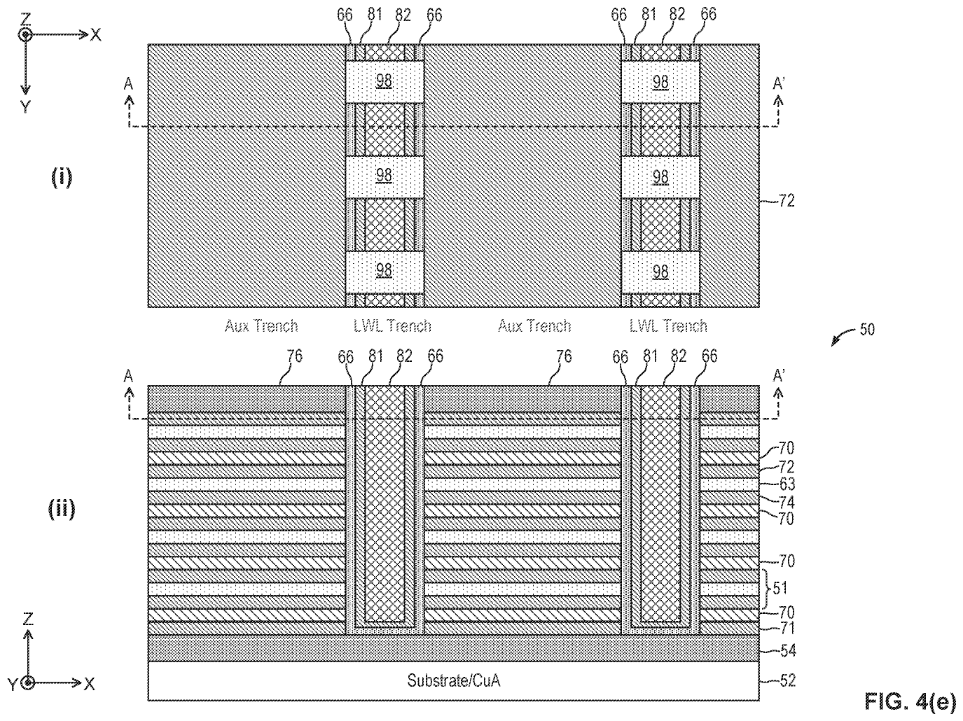

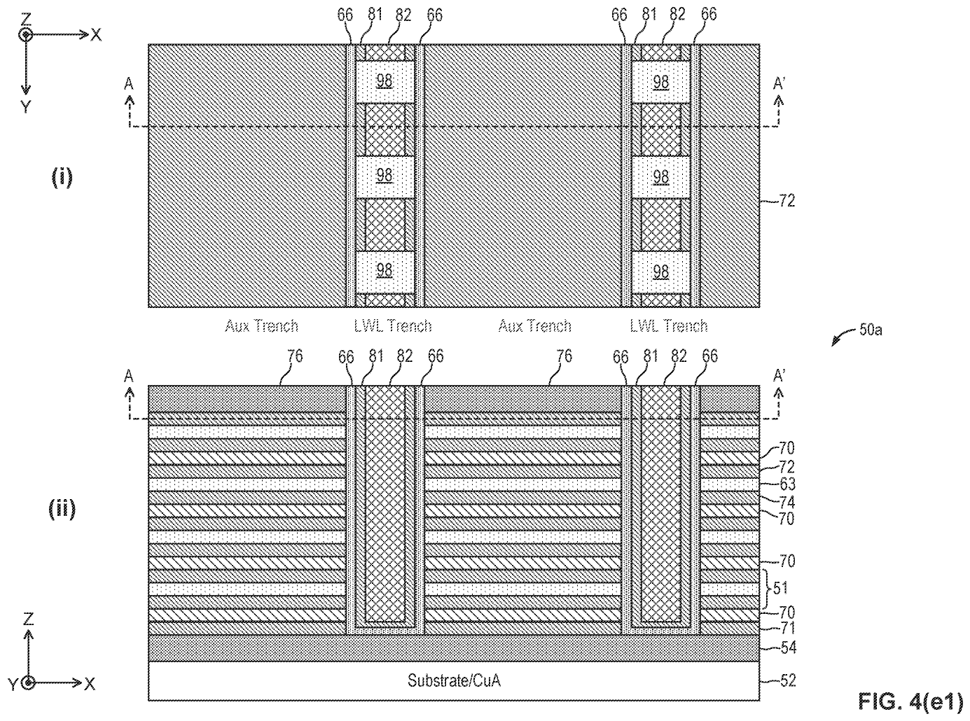

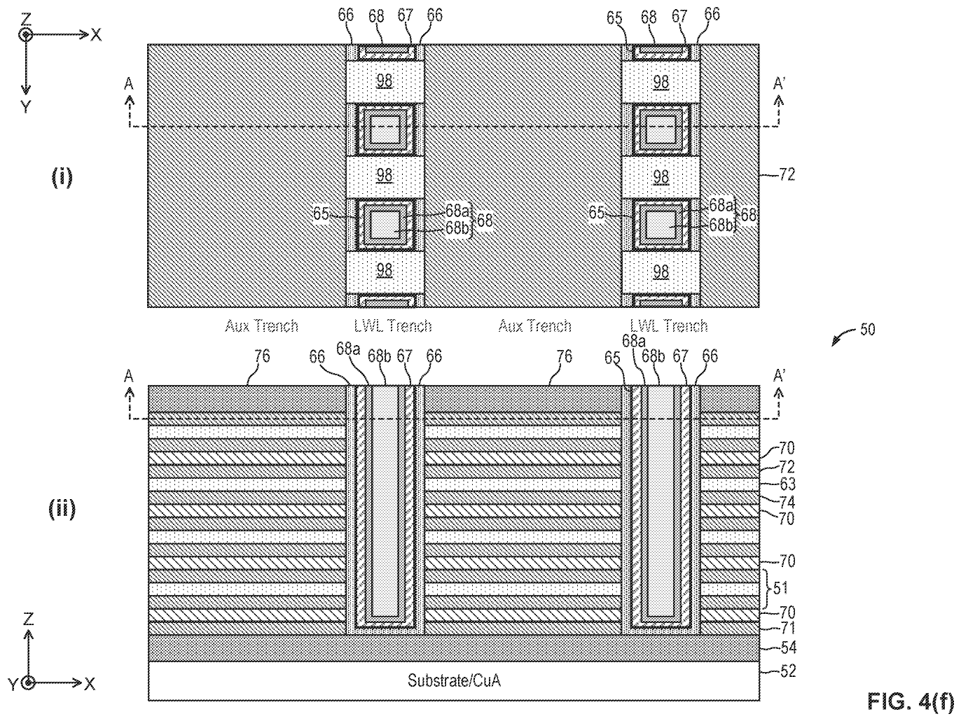

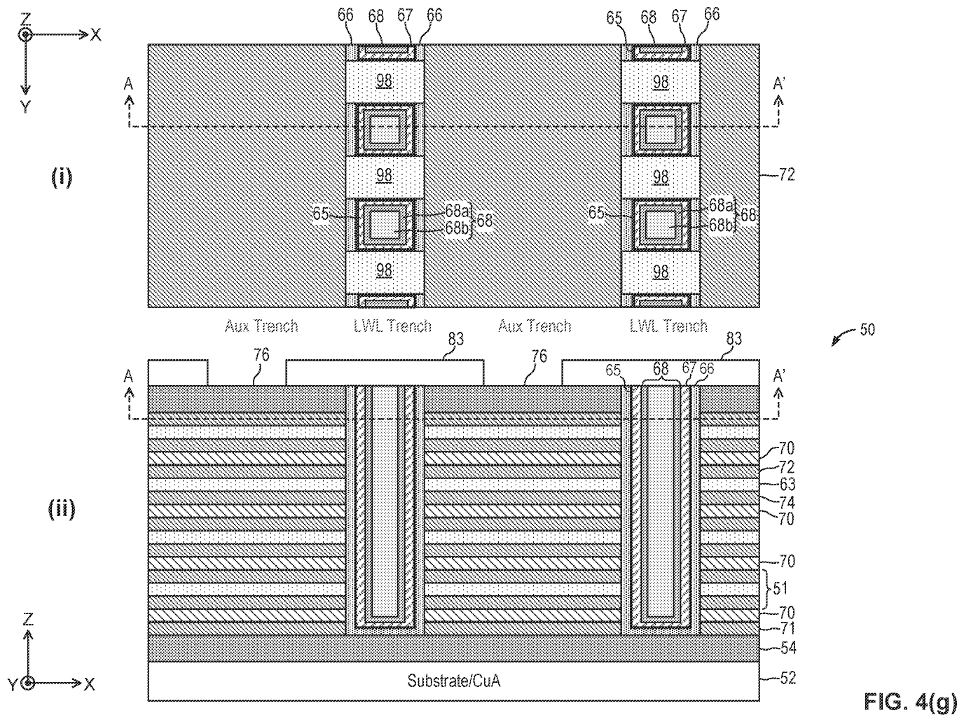

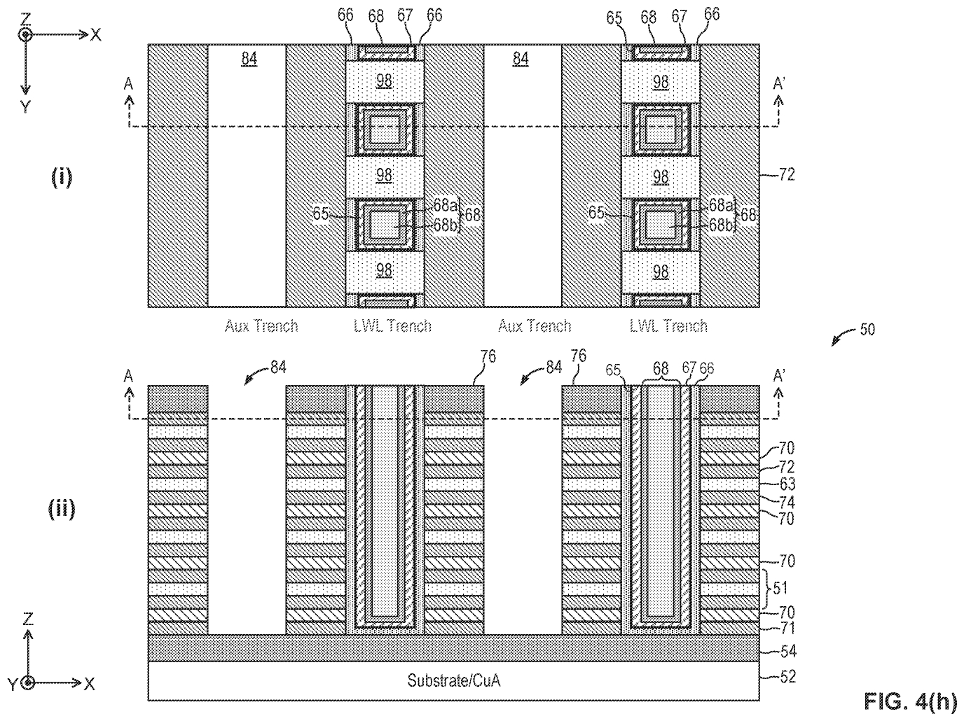

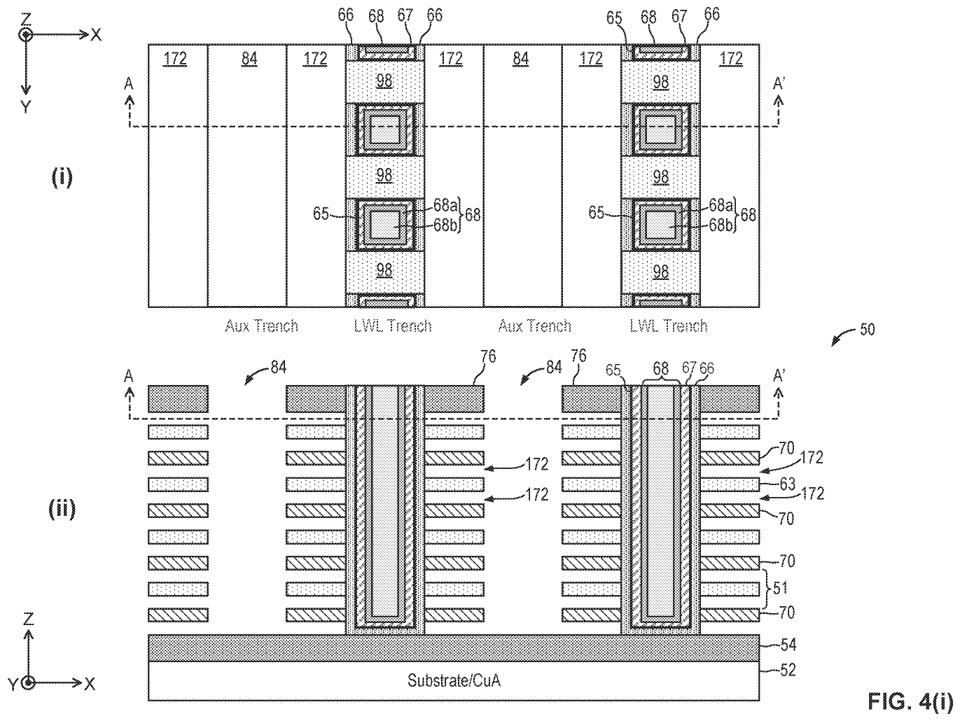

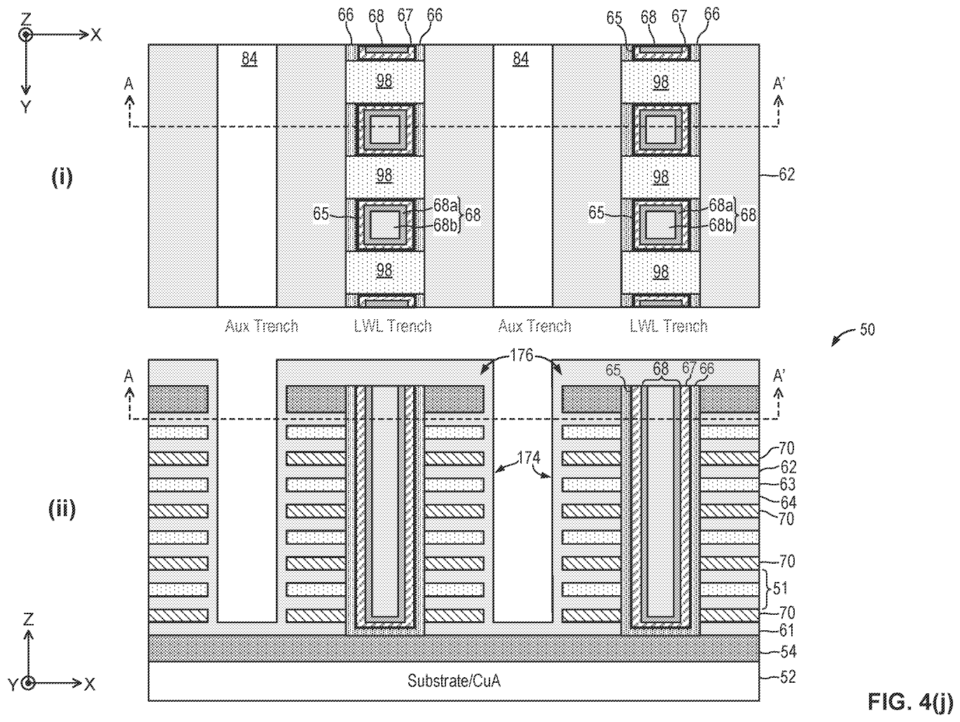

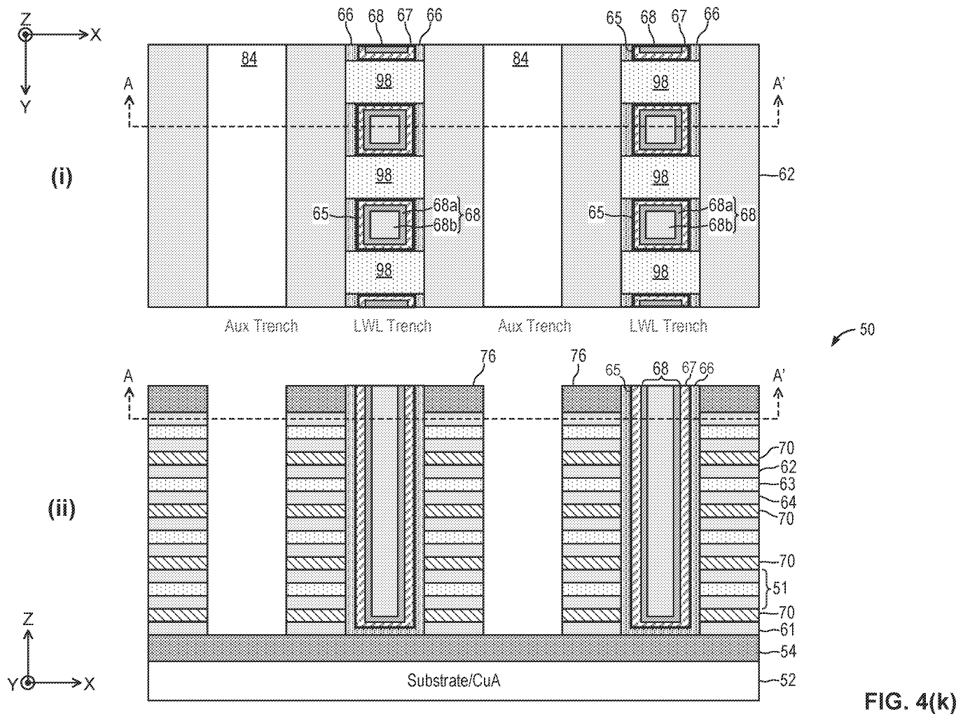

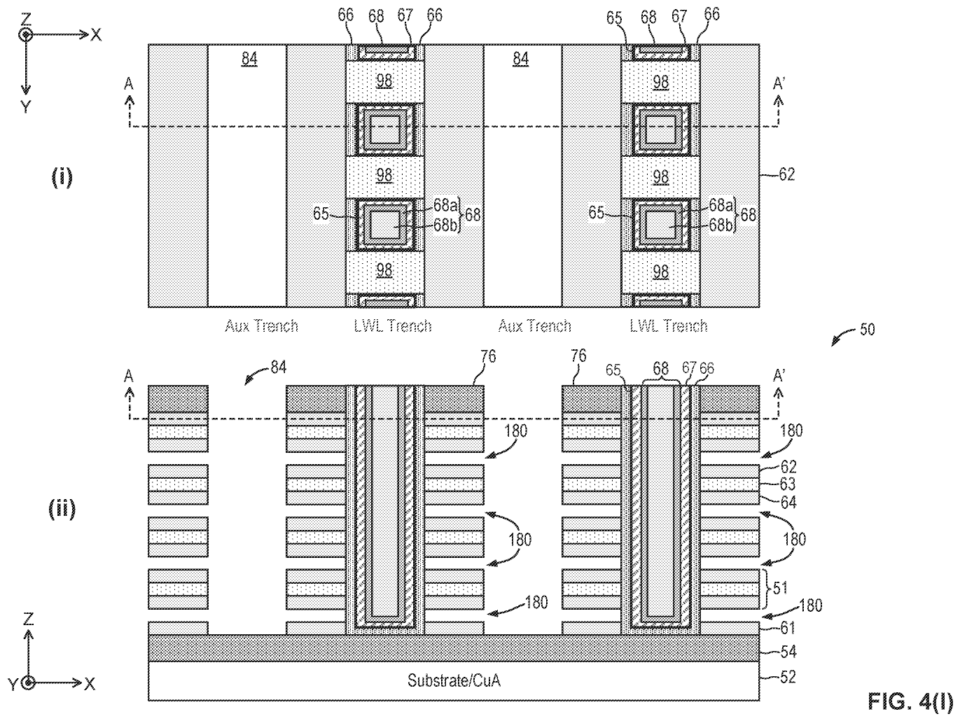

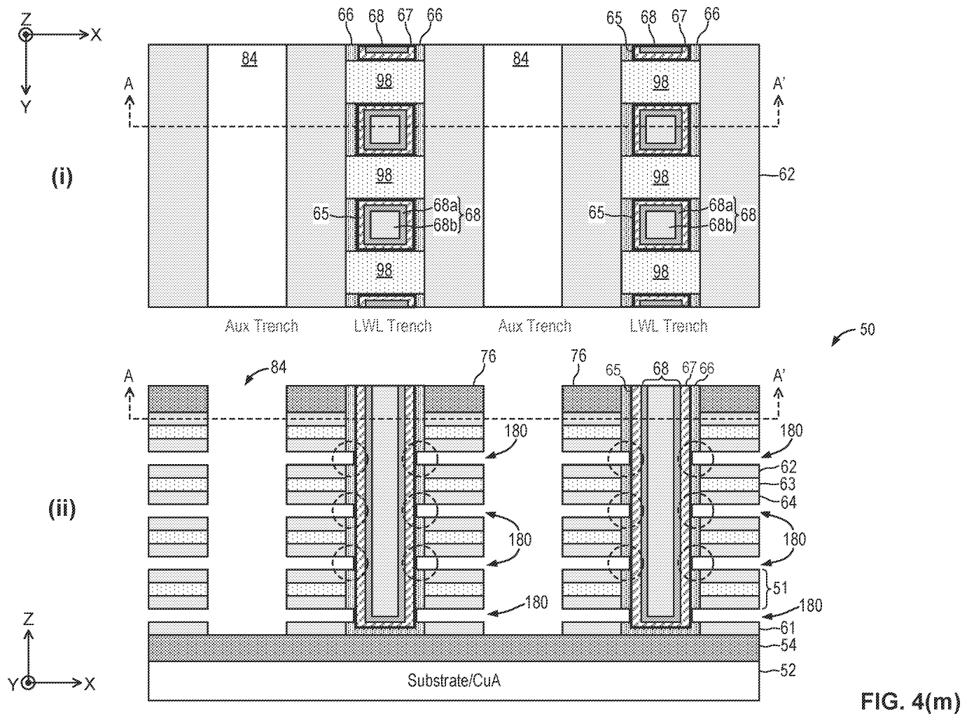

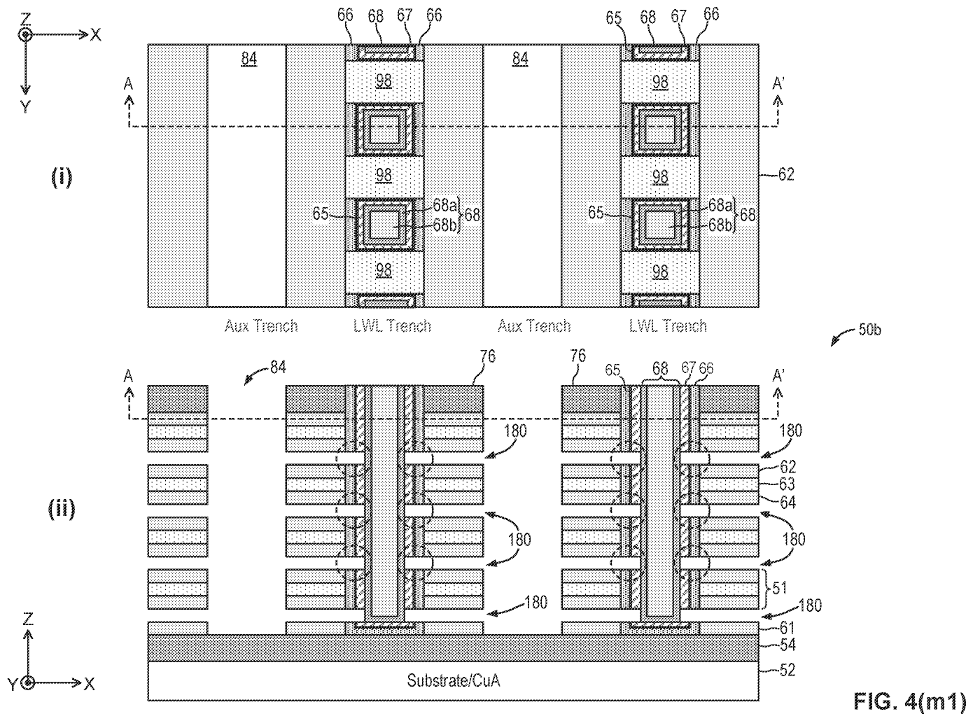

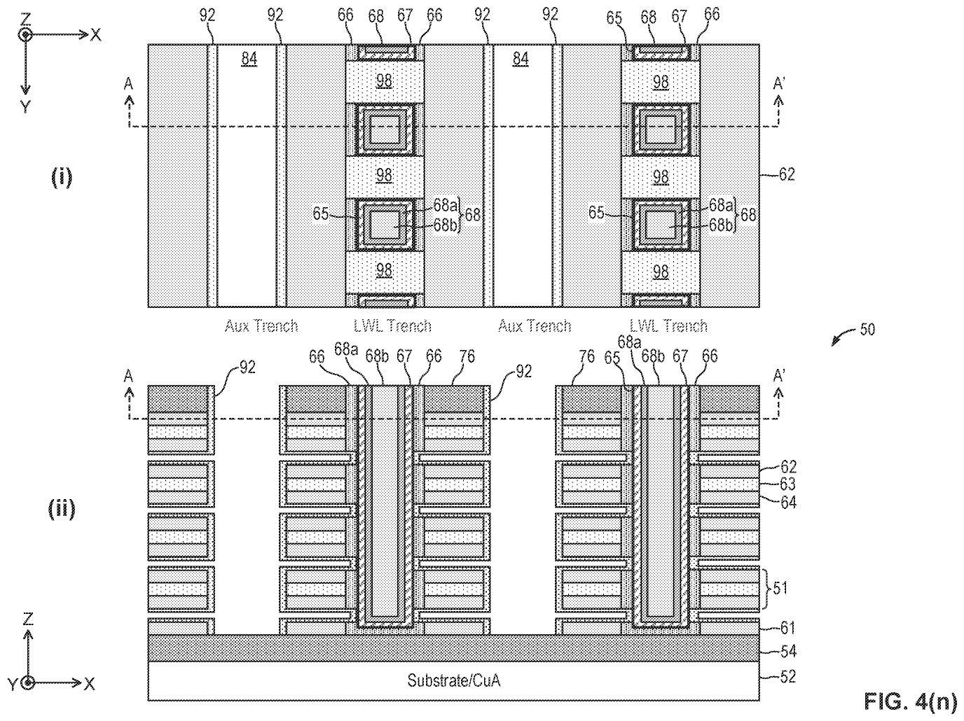

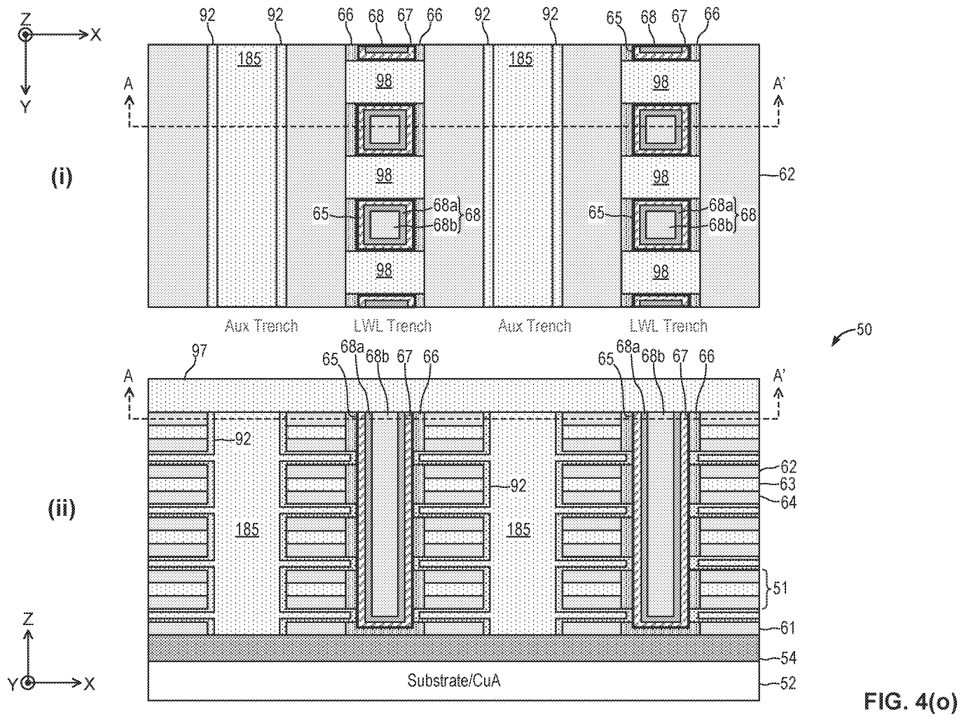

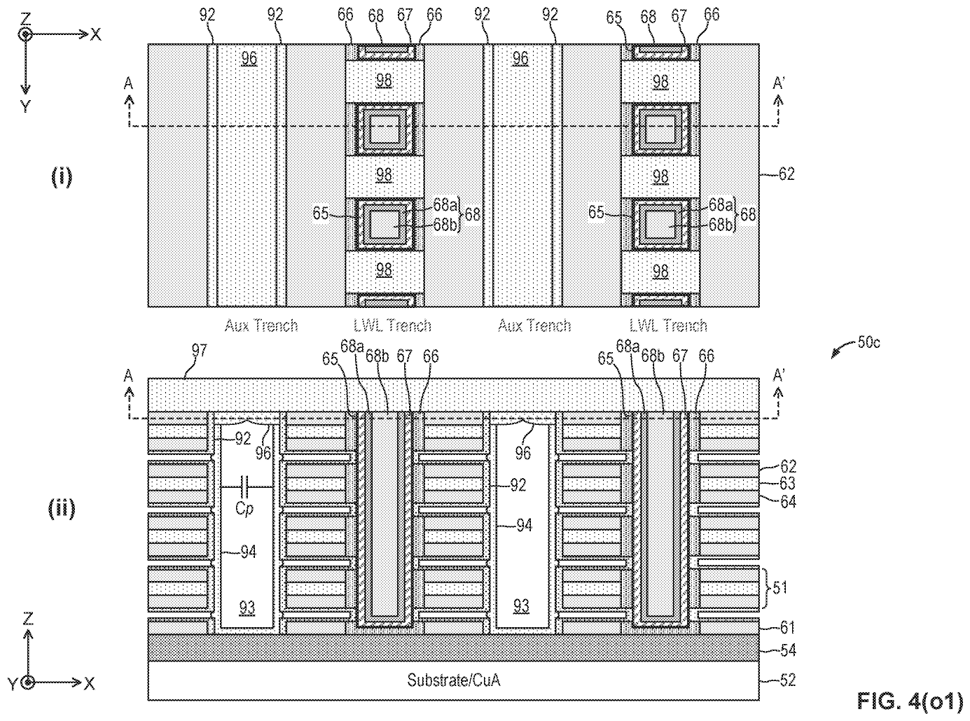

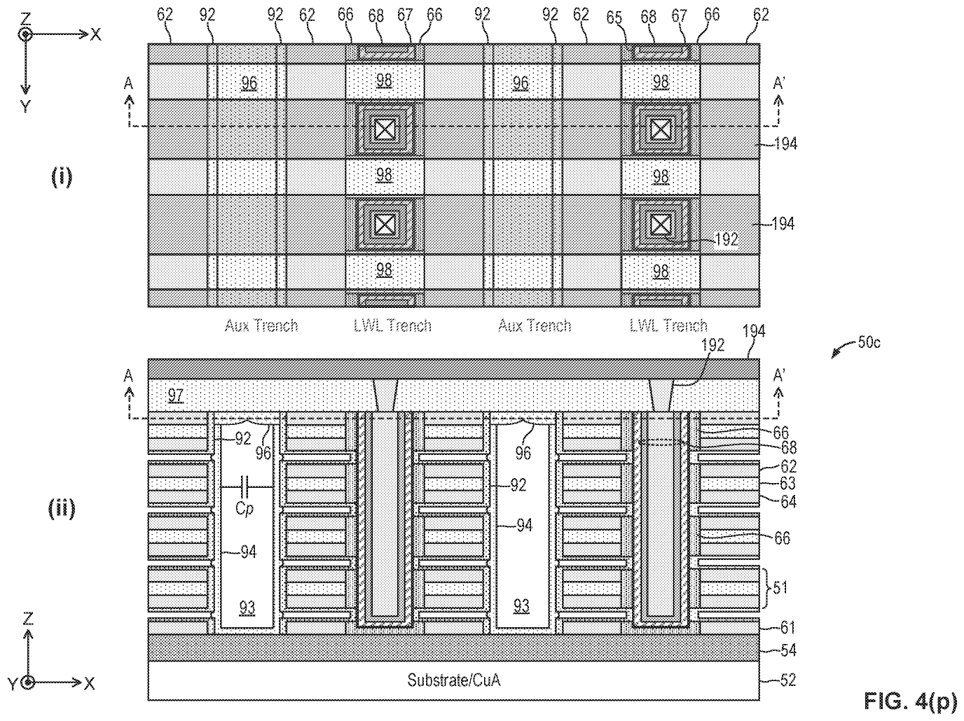

FIGS. 4(a) to 4(p), including FIGS. 4(e1), 4(m1) and 4(o1), illustrate a process for fabricating a memory structure including HNOR memory strings in embodiments of the present invention. Each figure in FIGS. 4(a) to 4(o1) includes two views: view (i) is a horizontal cross-sectional view (i.e., in an X-Y plane) along line A-A′ in view (ii), and view (ii) is a vertical cross-sectional view (i.e., in an X-Z plane) along line A-A′ in view (i).

Referring to FIG. 4(a), initially, a semiconductor substrate 52 is provided and any circuitry to be formed in the substrate 52, such as the CuA and the interconnect conductors, are fabricated in or on the substrate 52. An insulating layer 54 is provided on top of the semiconductor substrate to cover and protect the circuitry formed on and in the semiconductor substrate 52. In some embodiments, the insulating layer 54 is a dielectric layer which may also serve as an etch stop layer for the subsequent processing steps. In some embodiments, the insulating layer 54 is a silicon oxycarbide (SiOC) layer or an aluminum oxide (Al₂O₃) layer. The insulating layer 54 can be formed using any material with suitable selectivity for the subsequent etch processes to be performed.

Subsequently, a memory structure 50 is formed by successive depositions of (i) a multilayer 51 and (ii) an inter-layer sacrificial layer 70 on the planar surface of the semiconductor substrate 52, or in particular on the insulating layer 54 formed on the substrate 52. The multilayer 51 includes three sublayers: (a) a first sacrificial layer 72, (b) a channel spacer dielectric layer 63, and (c) a second sacrificial layer 74, in this order in the Z-direction. FIG. 4(a) shows the memory structure 50 after the depositions of the initial layers of thin films. Multilayer 51 is also referred to in this detailed description as an “active layer.” View (i) in FIG. 4(a) illustrates the horizontal cross-section along a line A-A′ in the first sacrificial layer 72 in view (ii). View (ii) in FIG. 4(a) illustrates the vertical cross-section of the memory structure 50 along the line A-A′ shown in view (i). The first and second sacrificial layers 72 and 74 are to be replaced by respective conductive layers in subsequent processing. The inter-layer sacrificial layer 70 (also referred herein as the third sacrificial layer) is to be replaced by an isolation material in subsequent processing to form an inter-layer isolation layer for providing separation between the active layers, as will be described in more details below. In one embodiment, each sublayer in the multilayer 51 and the inter-layer sacrificial layer 70 has a thickness of typically 30 nm or less. In another embodiment, the sublayers in the multilayer 51 and the inter-layer sacrificial layer 70 do not have the same thickness. In the present description, the dimensions are provided merely for illustrative purposes and are not intended to be limiting. In actual implementation, any suitable thicknesses or dimensions may be used.

In some embodiments, the first and second sacrificial layers 72 and 74 are each a silicon nitride layer. The channel spacer dielectric layer 63 is an insulating dielectric material, such as silicon oxide (SiO₂). The third sacrificial layer 70 is a sacrificial material selected from carbon, amorphous silicon (aSi), or silicon germanium (SiGe).

In some embodiments, dummy sublayers may be provided as the lowermost and uppermost layers of memory stack 50 where the dummy sublayers are not necessarily part of an active layer. In the embodiment shown in FIG. 4(a), a dummy sacrificial layer 71 is provided between the insulating layer 54 and the first inter-layer sacrificial layer 70 as the lowermost layer of the memory stack 50. The dummy sacrificial layer 71 is formed of the same material as the first and second sacrificial layers 72 and 74 and is to be replaced with a metal layer in later processing. The dummy sacrificial layer 71 is provided to form a dummy metal layer on the insulating layer 54 in later processing steps to realize bracing and anchoring support of the memory stacks formed thereon, as will be described in more detail below. In the present description, the dummy metal layer refers to a metal layer that is not used for any memory circuit related functions in the memory structure but provides mechanical support of the memory stacks formed thereon. In other embodiments, a dummy metal layer can also be provided as the uppermost layer of the memory stack. The use of the dummy metal layer is optional and may be omitted in other embodiments. The embodiment shown in FIG. 4(a) is illustrative only and not intended to be limiting. When the dummy metal layer for memory stack anchoring is not used, the dummy sacrificial layer 71 is omitted from the memory structure 50 in FIG. 4(a).

After the memory structure 50 is formed with the desired number of multilayers 51 with the third sacrificial layers 70 therebetween, a capping layer 76 is formed on the top of the memory structure. The capping layer 76 is used as a masking layer in subsequent processing, such as for use as a self align mask for forming the local word line structures. In some embodiments, the capping layer 76 is a silicon oxide layer or a silicon oxycarbide (SiOC) layer. A mask 78 is applied on the memory structure (on the capping layer 76) to define trenches to be formed in the memory structure. In some embodiments, the mask 78 is an amorphous hard mask, such as an amorphous carbon hard mask. The mask 78 is patterned, for example, using a photo-lithographical patterning step, to define openings 79 where trenches are to be formed in the memory structure. It is instructive to note that the mask 78 is not drawn to scale in FIG. 4(a) and it is understood that an amorphous hard mask of sufficient thickness is provided in the high-aspect ratio etch process of the multilayer memory structure 50.

The use of patterned mask 78 in the present embodiment is illustrative only and not intended to be limiting. Other photo-lithographic and patterning processes can be used to define the openings for forming trenches in the memory structure. In an alternate embodiment, a two-mask process can be used where a first mask is patterned to expose openings for forming a set of operational (or LWL) trenches as well as openings for forming a set of auxiliary trenches, alternately arranged in the X-direction across the memory structure and a second mask is patterned to cover the openings for forming the set of auxiliary trenches and exposes only the openings for the set of operational trenches. The fabrication process continues with the openings of the auxiliary trenches covered by the second mask until the auxiliary trenches are to be formed.

Referring to FIG. 4(b), using the patterned mask 78, a first set of trenches 80 are formed in memory structure 50 using, for example, a selective anisotropic etch process with the mask 78 as the masking layer. After the trench etch process, remaining portions of the mask 78 is removed and the resulting structure is shown in FIG. 4(b). The first set of trenches 80 are arranged in the X-direction across the memory structure 100. The anisotropic etch process etches or remove all layers in the areas exposed by the mask 78, stopping at the insulation layer 54, which functions as an etch stop. In the present description, the first set of trenches 80 is referred to as operational trenches or active trenches or local word line trenches (LWT), as the trenches will eventually accommodate the active ferroelectric storage transistors. In one example, each of the trenches 80 has a width of about 60 nm at the top of the trench and a pitch of 230 nm, with the trenches having a spacing of 170 nm apart. In other words, the operational trenches 80 are separated by a mesa of 170 nm. In subsequent processing, auxiliary trenches are to be formed in the mesa between each pair or operational trenches 80. The auxiliary trenches are to be formed equidistant between an adjacent pair of operational trenches 80. In one example, the auxiliary trenches may have a width of about 60 nm, resulting in a mesa between an operational trench and an auxiliary trench of about 55 nm, where the remaining mesa forms the active stack in the memory structure, as will be described in more details below.

Referring to FIG. 4(c), with the operational trenches 80 thus formed, a channel layer 66 is deposited on the sidewalls of the trenches 80. For example, the channel layer 66 is deposited conformally on the sidewalls of the trenches 80. In one embodiment, the channel layer 66 is deposited by atomic layer deposition (ALD), chemical vapor deposition (CVD) or a combination thereof. In the present embodiment, the channel layer 66 is a semiconductor oxide layer, such as indium gallium zinc oxide (IGZO), indium zinc oxide (IZO), indium tungsten oxide (IWO), or indium tin oxide (ITO). In other examples, the channel layer 66 can be formed using other semiconductor oxide material compatible with IGZO. Furthermore, in some embodiments, the channel layer 66 may have a thickness in the X-direction of 1.5 nm to 10 nm. In one example, the channel layer 66 has a thickness of 6 nm in the X-direction. A liner layer 81 is deposited to cover the channel layer 66 and the remaining volume in the trenches 80 is filled with a sacrificial material 82. In one embodiment, the liner layer 81 can be a silicon nitride layer or an undoped amorphous silicon layer and may have a thickness of 3-5 nm. In one embodiment, the sacrificial material 82 is silicon germanium or carbon. To best protect the channel layer 66, the liner layer 81 is preferably deposited in the same deposition tool to avoid exposure of the channel layer to oxidation. After the deposition steps, excess material may be removed from the top of memory structure 50 using, for example, chemical-mechanical polishing (CMP). The resulting memory structure 50 is shown in FIG. 4(c).

Thereafter, the memory structure 50 is patterned to form the local word line structures. In the present description, local word line structures refer to the columnar structures formed by the ferroelectric dielectric layer and the gate conductor layer. In the present description, the term “gate electrode structure” is used to refer to a local word line structure and the portions of the channel layer intersecting with the local word line structure. Referring to FIG. 4(d)(i), a mask (e.g. an amorphous hard mask) is applied to the memory structure 50 with openings 86 exposing areas for forming deep shafts which will be used to isolate the storage transistors to be formed along a memory string. In the present embodiments, the mask openings 86 have a first dimension d1 in the Y-direction and an elongated second dimension d4 in the X-direction. The openings 86 are spaced apart by a dimension d2 in the Y-direction. In one embodiment, a pitch d3 is the sum of the dimensions d1 and d2 and may be used to define the pitch of the global word line conductors to be formed above the memory array (not shown) for connecting to the local word line gate conductors yet to be formed. Typically the global word line pitch is around 100 nm or less, with d1 around 50 nm and d2 around 50 nm. With the openings 86 thus defined, the sacrificial material 82 is removed, such as by a selective anisotropic etch process. The exposed liner layer 81 is then removed, such as by a selective wet etch process. Lastly, the semiconductor oxide channel layer 66 in the area defined by the openings 86 are removed, by selective anisotropic dry etch or by atomic layer etch (ALE), or by controlled selective wet etch process. As a result, shafts 88 are formed in the LWL trenches between areas where LWL structures are to be formed, as shown in FIG. 4(d). In particular, the mask openings 86 overlap the mesas of the memory structure 50 and the etch process is self aligned to the edges of the capping layer 76, forming shafts 88 in the area of the LWL trenches only.

More specifically, the etching of the channel layer 66 should be performed to limit any unintended sideway etch into the active stacks of multilayers 51 at the face of the vertical sidewalls of the LWL trenches that have become exposed to the etchant when the channel material 66 has been etched away. By removing the channel material in shafts 88, physical separation of the storage transistors to be formed along each memory string in the Y-direction is realized.

Referring to FIG. 4(e), the shafts 88 are filled with a dielectric material, forming dielectric filled shafts 98. For example, the dielectric material can be a low dielectric constant oxide, such as silicon oxide (SiO₂). The dielectric filled shafts 98 serve as dielectric separation between adjacent local word lines or gate conductors to be formed in the LWL trenches. Storage transistors are to be formed along each active stack bordering the LWL trenches (in the Y-direction), in the spaces between adjacent dielectric filled shafts 98.

In the above-described embodiments, the channel layer 66 is removed during the etch process applied to mask openings 86 to form shafts 88. In other embodiments, the etch process may remove only the sacrificial material 82 and the liner layer 81, without removing the channel layer 66. FIG. 4(e1) illustrates the alternate embodiment where the channel layer 66 is not removed from the shafts 88 and the subsequently formed dielectric filled shafts 98 are bonded by the channel layer 66 in the X-direction. Accordingly, in memory structure 50a, the channel layer 66 is a continuous layer in the Y-direction along the NOR memory strings. The portions of the channel layer 66 remaining adjacent the dielectric filled shafts 98 have minimal impact on the operation of the storage transistors of the NOR memory strings.

To form the local word line structures, the sacrificial material 82 and the liner layer 81 are removed by selective etch from the areas between the dielectric filled shafts 98, exposing the channel layer 66 which remains on the sidewalls of the mesas. The fabrication process then proceeds to form the gate dielectric layer of the storage transistors. Referring to FIG. 4(f), a gate dielectric layer 67 is deposited onto the sidewalls of the excavated cavities in the LWL trenches, on top of the channel layer 66. For example, the gate dielectric layer 67 may be deposited using atomic layer deposition. Then, a gate conductor layer 68 is deposited into the remaining volume of the excavated cavities. After the deposition steps, excess material may be removed from the top of memory structure 50 using, for example, chemical-mechanical polishing (CMP). The resulting memory structure 50 is shown in FIG. 4(f). Between each pair of dielectric-filled trenches 98, the conductive layer 68 provides a vertical local word line (LWL) that serves as gate electrode for each of the storage transistors that are vertically aligned in the same active stack.

In the present embodiment, the memory structure 50 is used to form ferroelectric storage transistors and the gate dielectric layer 67 is a ferroelectric polarization layer. The ferroelectric polarization layer 67 can be deposited using an atomic layer deposition (ALD) technique and may have a thickness between 2 nm to 8 nm. A thermal anneal is performed to form the ferroelectric phase in the deposited ferroelectric material. In some embodiments, the thermal anneal of the ferroelectric polarization layer 67 is carried out with a conductive capping layer formed thereon. For example, the gate conductor layer 68 may function as the conductive capping layer in some embodiments. In one embodiment, the ferroelectric polarization layer is formed of a doped hafnium oxide material, such as zirconium-doped hafnium oxide (HfZrO or “HZO”). In other embodiments, the hafnium oxide can be doped with silicon (Si), iridium (Ir) or lanthanum (La). In some embodiments, the ferroelectric polarization layer is a material selected from: zirconium-doped hafnium oxide (HZO), silicon-doped hafnium oxide (HSO), aluminum zirconium-doped hafnium oxide (HfZrAlO), aluminum-doped hafnium oxide (HfO₂:Al), lanthanum-doped hafnium oxide (HfO₂:La), hafnium zirconium oxynitride (HfZrON), hafnium zirconium aluminum oxide (HfZrAlO), and any hafnium oxide that includes zirconium impurities.

In some embodiments, an interfacial layer 65 may be provided between the semiconductor oxide channel layer 66 and the ferroelectric polarization layer 67. In some embodiments, the interfacial layer 65 is formed using a material with a high dielectric constant (K) (“high-K” material). In some embodiments, the interfacial layer 65 may be a silicon nitride (Si₃N₄) layer, or a silicon oxynitride layer, or an aluminum oxide (Al₂O₃) layer and may have a thickness of 1-2 nm. Other materials for the interfacial layer 65 may be indium tungsten oxide. In some embodiments, the interfacial layer 65 may be deposited using an atomic layer deposition (ALD) technique and furthermore, in some embodiments, the interfacial layer 65 may be deposited in the same process chamber as the ferroelectric polarization layer 67, without breaking vacuum between the deposition of the two layers. The interfacial layer 65 is optional and may be omitted in other embodiments of the present invention. In one embodiment, the interfacial layer 65 is an aluminum oxide (Al₂O₃) layer and is annealed to yield an amorphous film with the desired characteristics. In some embodiments, the aluminum oxide (Al₂O₃) layer can be annealed in oxygen (O₂), ozone (O₃), nitrous oxide (N₂O), forming gas (H₂N₂), or argon (Ar). In some embodiments an optional interfacial layer (not shown), similar to the interfacial layer 65, may be deposited on the ferroelectric polarization layer 67.

In the present embodiment, the gate conductor layer 68 is a metal layer and can include a conductive liner 68a and a conductive filler material 68b. The conductive liner 68a may be a titanium nitride (TiN) liner or a tungsten nitride (WN) liner. The conductive filler material 68b may be a metal, such as tungsten (W) or molybdenum (Mo), or heavily doped n-type or p-type polysilicon. In embodiments of the present invention, the gate conductor layer 68, as deposited on the ferroelectric polarization layer 67, functions as a capping layer for the ferroelectric polarization layer which has the beneficial effect of providing tensile stress or compressive force onto the ferroelectric polarization layer to aid in the crystallization of the ferroelectric polarization layer and the formation of the desired ferroelectric crystallization phase—the orthorhombic phase—in the ferroelectric film. In some embodiments, the gate conductor layer 68 is formed by a single conductive layer, such as a titanium nitride (TiN) layer or a tungsten nitride (WN) layer. The single conductive layer is deposited in the excavated cavities on the ferroelectric polarization layer 67. The single conductive layer provides tensile stress or compressive force onto the ferroelectric polarization layer to aid in the crystallization of the ferroelectric polarization layer and the formation of the desired orthorhombic ferroelectric crystallization phase.

In some embodiments, the gate conductor layer 68, including the conductive liner 68a and the conductive filler material 68b, is deposited using atomic layer deposition at a relatively low temperature, such as between 300-400° C. In alternate embodiments, after the deposition of the ferroelectric polarization layer 67, at least the conductive liner 68a is deposited at a reduced temperature, such as a temperature below 350° C., to prevent crystallization of the ferroelectric polarization layer. Thereafter, thermal anneal of the ferroelectric polarization layer is performed with at least the conductive liner 68a as the conductive capping layer to realize the desired ferroelectric crystallization phase (the orthorhombic phase) in the ferroelectric film.

The fabrication process has now formed the vertical local word lines in the LWL trenches. Masks used in the local word line process are removed. Referring to FIG. 4(g), a mask 83 is applied which covers the LWL trenches and protects the local word line structures formed therein while exposing openings where the auxiliary trenches are to be formed. In some embodiments, the mask is an amorphous hard mask, such as an amorphous carbon hard mask. With the mechanical support from the dielectric filled shafts 98 and the local word line structures therebetween, a second set of trenches 84 are formed using substantially the same technique as discussed in conjunction with FIGS. 4(a) and 4(b) above. For example, the memory structure is selectively anisotropically etched with the patterned mask 83 as the masking layer. The anisotropic etch process etches or removes all layers in the areas exposed by the patterned mask 83, stopping at the etch stop layer 54. After the trench etch process, remaining portions of the mask is removed and the resulting memory structure 50 is shown in FIG. 4(h). The second set of trenches 84 is referred to as the auxiliary trenches.

In some examples, the auxiliary trenches 84 may be 60 nm wide. Each of the second set of trenches 84 is cut between an adjacent pair of the LWL trenches (trenches 80) and each of the second set of trenches 84 is cut substantially equidistant between an adjacent pair of the first set of trenches 80. As a result of trenches 80 and 84 being cut in the multilayer structure, memory stacks in the multilayer structure are formed which are referred to as “active stacks” in the present description. In some examples, the active stacks are each approximately 40 nm wide, which is the width of the bit-lines. The narrow strips resulting from the cutting of the multilayers 51 are referred herein as “active strips” and the multilayer 51 is also referred to as an “active layer.”

In embodiments of the present invention, the fabrication process forms the LWL trenches to house the local word line structures for forming storage transistors with the active stacks bordering the LWL trenches. Meanwhile, the fabrication process forms the auxiliary trenches to facilitate metal replacement and channel separation processes. The auxiliary trenches do not include local word line structures and do not form storage transistors with the bordering active stacks. With the auxiliary trenches 84 thus formed, the fabrication process performs metal replacement where the first and second sacrificial layers 72 and 74 are removed and replaced with the respective first and second conductive layers.

Referring to FIG. 4(i), the first and second sacrificial layers 72 and 74 are removed using, for example, a selective dry etch or a selective wet etch process, thereby creating cavities 172 between the channel spacer dielectric layer 63 and the inter-layer sacrificial layer 70. At the same time, the dummy sacrificial layer 71 is also removed to create a cavity 172 between the insulating layer 54 and the first inter-layer sacrificial layer 70. The removal of the first and second sacrificial layers 72 and 74 (and the dummy sacrificial layer 71) exposes the backside of the channel layer 66 through the cavities 172. In one example, the first, second and dummy sacrificial layers 72, 74 and 71 are silicon nitride layers which are removed using a selective wet etch process using hot phosphoric acid. The remaining layers 63 and 70 are typically 30 nm or less in thickness and 30 nm to 60 nm long; they are held in place by being attached to the channel layer 66, the ferroelectric layer 67 and the conductive liner 68a. All of these layers are supported by the rigid metallic vertical local word line 68b, which is repeated every local word line pitch (as shown in FIG. 4(i)(i)) along the entire length of each memory string. The feature of having strong mechanical support by metallic local word lines spanning the entire depth of very tall and narrow memory stacks results in physical stability of the stacks, thereby enabling scaling up the height of the memory stacks even in case of very high aspect ratio memory structures.

Then, referring to FIG. 4(j), a conductive layer 176 is deposited on the memory structure 50. Prior to the deposition process, the exposed backside of the channel layer 66 can be cleaned of any surface oxidation without damaging the channel layer. In some embodiments, the conductive layer 176 is deposited using chemical vapor deposition or atomic layer deposition. The conductive layer 176 fills the cavities 172 in the multilayer structure and is also formed on the sidewalls of the auxiliary trenches 84 and also on the top surfaces of the multilayer structure. The excess material formed on the sidewalls (portions 174) and on the top surface of the multilayer structure is removed by a dry selective etch, and in some cases, followed by a selective wet etch process to remove remaining metal residues or stringers. The resulting structure is shown in FIG. 4(k)

Referring to FIG. 4(k), as a result of the metal replacement process, a first conductive layer 62 and a second conductive layer 64 are formed. The first and second conductive layers are in contact with the channel layer 66 and are spaced apart by the channel spacer dielectric layer 63. In each multilayer 51, the first conductive layer 62 forms the common drain (bit) line and the second conductive layer 64 forms the common source line of the NOR memory string to be formed. In some embodiments, the first and second conductive layers 62, 64 are each a metal layer and may be a titanium nitride (TiN) liner and a tungsten (W) layer, a tungsten nitride (WN) liner and a tungsten (W) layer, a molybdenum layer or a cobalt layer, or other conductive materials described above. Furthermore, in the present embodiment, the memory structure 50 includes a dummy metal layer 61 formed on the insulating layer 54. In particular, the dummy metal layer 61 is formed between the bottommost active layer and the insulating layer 54. The dummy metal layer 61 is formed in the same metal replacement process as the first and second conductive layers 62, 64 and therefore has the same material composition as the first and second conductive layers. The dummy metal layer 61, being formed directly on the insulating layer 54, provides mechanical support for the memory stacks formed thereon.

Following the metal replacement process, the auxiliary trenches 84 will now be used for separating the channel layer 66 between each multilayer 51, in a process referred to as channel separation. Referring to FIG. 4(l), using the auxiliary trenches 84 which exposes the inter-layer sacrificial layer 70 from the sides of the active stack, the fabrication process removes the third sacrificial layer 70, leaving cavities 180 in places where the third sacrificial layer 70 used to be. Various removal processes can be used depending on the material used for the third sacrificial layer 70. For example, in the case the sacrificial layer 70 is a carbon layer, the carbon layer can be removed by ashing in an oxygen ambient. In the case the sacrificial layer 70 is amorphous silicon or silicon germanium, a selective wet or dry etch process can be used. The resulting memory structure 50 is shown in FIG. 4(l). FIG. 4(l) illustrates the function of the dummy metal layer 61 for providing structural support of the memory stacks, especially during the channel separation process after the sacrificial layer 70 has been removed. The dummy metal layer 61 provides mechanical bracing of the memory stacks to the insulating layer 54, enhancing the stability of the memory stacks during the channel separation process.

As shown in FIG. 4(l), the cavities 180 thus formed expose portions of the channel layer 66 between the multilayers 51 in the active stacks. In particular, the backside of the channel layer 66 is exposed through auxiliary trenches 84 and the cavities 180. The auxiliary trenches 84 and the cavities 180 are then used to remove the exposed portions of the channel layer 66 that straddle two adjacent multilayers 51 in the active stack (in the Z-direction). Referring to FIG. 4(m), the fabrication process uses the auxiliary trenches 84 and cavities 180 to deliver high etch selectivity etchant to the backside of the channel layer 66 to selectively etch the exposed portions of the channel layer 66, as indicated by the dotted circles in FIG. 4(m). As a result, the channel layer 66 is separated in the Z-direction to each multilayer 51. In some embodiments, the channel layer 66 is a semiconductor oxide, such as IGZO, and the fabrication process uses, for example, sulfuric acid, citric acid, acetic acid, or ammonium hydroxide (NH₄OH) in a wet etch process to selectively etch the exposed portions of the channel layer 66. In some embodiments, the memory structure 50 includes the interfacial layer 65 and the backside etch of the channel layer 66 is selective to the interfacial layer 65 so that the interfacial layer acts as an etch stop for the backside etch process. That is, the exposed portion of the channel layer 66 is etched through the auxiliary trenches 84 and the cavities 180 and the etch process will stop when the interfacial layer 65 is reached. In one embodiment, the interfacial layer 65 is an aluminum oxide (Al₂O₃) layer. In another embodiment, the backside etch process may be implemented as a multi-step etch process, including an atomic layer etch step used in the removal of the last 1-2 nm of the channel layer, in which the atomic layer etch step stops on the interfacial layer 65 or stop on the ferroelectric polarization layer 67.

Returning to the embodiment shown in FIG. 4(m), the channel separation process stops when the exposed portions of the channel layer 66 are removed and the channel region is physically separated and isolated to each multilayer 51 in each active stack. In some embodiments, the channel separation process can continue, by a change of etchant chemistry or process, to remove the now exposed portions of the ferroelectric polarization layer 67, as shown in FIG. 4(m1). In memory structure 50b of FIG. 4(m1), the ferroelectric polarization layer 67, serving as the storage layer of the storage transistors, is also physically separated and isolated to each multilayer 51 in each active stack. The separation of the ferroelectric polarization layer 67 is optional and may be omitted in other embodiments of the present invention. In some cases, care can be taken to minimize excessive undercutting by sideway etching of the channel layer 66 or the ferroelectric dielectric layer 67.

Referring to FIG. 4(n), after the channel separation process, the exposed surfaces of the memory structure 50 may be passivated, such as by forming a thin liner layer 92. The liner layer 92 is a thin dielectric layer, such as around 1-2 nm thick. The liner layer 92 can be a silicon oxide layer, a silicon nitride layer or an aluminum oxide layer and serves to passivate or seal the exposed surfaces in the cavities 180 and the auxiliary trenches 84. In some embodiments, the liner layer 92 is deposited conformally and may be deposited using an atomic layer deposition (ALD) process. In the present description, the thin liner layer 92 is also referred to as an air gap liner layer. In some embodiments, the liner layer 92 is formed of the same material as the interfacial layer 65. In one embodiment, the interfacial layer 65 and the liner layer 92 are both aluminum oxide layers.

Referring to FIG. 4(o), the remaining cavities in the memory structure 50 may be filled with a low-K dielectric material 185, such as silicon oxide. The dielectric layer 185 fills the cavities 180 between active layers and also fills the auxiliary trenches 84. A cap oxide layer 97 may be formed above the completed memory structure 50. In some embodiments, the cap oxide layer 97 may be a silicon oxide layer and may have a thickness of 100 nm to 200 nm. FIG. 4(o) illustrates the resulting memory structure 50.

In an alternate embodiment, the remaining cavities 93 in the memory structure 50 are not filled. Instead, the auxiliary trenches 84 are used to provide air gap isolation in the memory structure 50. Referring to FIG. 4(o1), the memory structure 50c implements two levels of air gap isolation. First, a dielectric layer 94 is deposited nonconformally into auxiliary trenches 84 which covers the sidewalls of the trenches 84 (i.e. covering the liner layer 92 on the trench sidewalls) while capping the ends of the inter-layer cavities 180 facing the auxiliary trenches 84. The dielectric layer 94 serving as a capping layer to create inter-layer air gap isolation regions between adjacent active layers 51 in each memory stack. In some embodiments, the dielectric layer 94 is a non-conformally deposited dielectric layer, such as a silicon oxide (SiO₂) layer or a silicon nitride (Si₃N₄) layer. In some embodiments, the dielectric layer 94 may have a thickness of 5-10 nm in the X-direction. The dielectric layer 94 implements the first level of air gap isolation by providing isolation in the vertical direction between storage transistors formed in an active stack. Furthermore, the dielectric layer 94 also provides mechanical support for the multilayers 51 at the ends facing the auxiliary trenches 84.

Second, a dielectric layer 96 is formed at the top portions of the auxiliary trenches 84, such as by nonconformal deposition of a dielectric layer. In some examples, a dielectric layer, such as a silicon oxide (SiO₂) layer, is deposited at the top portions of the auxiliary trenches 84 around the circumference of the trenches. The deposition process continues by growing the dielectric layer until the dielectric layer merges in the middle of the trenches 84, thereby forming a capping layer covering the remaining cavities 93 of trenches 84. The cap oxide layer 97 may be formed above the completed memory structure 50. The dielectric layer 96 creates an air gap isolation in cavities 93 between adjacent active stacks bordering the auxiliary trenches 84. The dielectric layer 96 implements the second level of air-gap isolation by providing isolation between adjacent memory stacks and reducing the parasitic capacitance therebetween. In particular, the first level of air gap isolation has the effect of minimizing the parasitic capacitive coupling between the first conductive layer (the bit line) in one memory plane and the second conductive layer (the source line) in an adjacent memory plane. The second level of air gap isolation has the effect of minimizing the parasitic capacitance (denoted as Cp) between adjacent active stacks. In some embodiments, the dielectric layer 96 and the dielectric layer 94 are formed of the same dielectric material. In other embodiments, the dielectric layer 96 and the dielectric layer 94 can be formed of different dielectric materials. The dielectric layer 96 and cap oxide layer 97 together provide extra mechanical strength and stability to memory array 50c by preventing listing or collapsing of long strings of tall and narrow memory stacks.

In further embodiments, a memory structure can be constructed to include either one of the two levels of air gap isolation. That is, the memory structure can form the first level of air gap isolation using the dielectric capping layer 94 and the remaining cavities 93 in the auxiliary trenches 84 are filled with a low-K dielectric material, such as silicon oxide (SiO₂). Alternately, the memory structure can fill the inter-layer cavities 180 with a low-K dielectric material, such as silicon oxide (SiO₂) and the remaining cavities 93 is capped by the dielectric capping layer 96 to form the second level of air gap isolation, without the first level of air gap isolation. The materials or types of isolation used for the inter-layer cavities and the auxiliary trench cavities can be selected based on the amount of desired parasitic isolation between the storage transistors within each active stack and between the active stacks.

Referring to FIGS. 4(o) and 4(o1), the memory structure 50 or 50b thus formed includes storage transistors arranged in NOR memory strings in multiple planes. In particular, the storage transistors have the same structure as the storage transistor 20 as described in FIG. 1. Vias and interconnects are formed in and above the cap oxide layer 97 to form interconnection between the storage transistors and the control circuitry, such as the CuA formed in the substrate 52. For example, the bit lines and local word lines of the memory stack are connected with control, select, and sense circuits that are formed in the CuA in the semiconductor substrate. In one example, global word lines, formed using copper metallization processes and materials, can be formed above the cap oxide layer 97 to connect the local word lines to the respective word line drivers formed in the CuA in the substrate 52. In one example, FIG. 4(p) illustrates the memory structure 50c with a global word line metallization layer 194 formed on the cap oxide layer 97 and connected to local word lines 68 formed in the memory structure through vias 192 formed in the cap oxide layer 97. In some embodiments, the global word line metallization layer 194 is one of copper, tungsten, molybdenum, cobalt, or other metals, or compounds thereof. Vias 192 is filled with a metal layer, such as copper or other suitable metals. As thus configured, each global word line 194 is connected to a group of local word lines 68 to provide the control signal to the gate electrodes of the storage transistors formed in multiple memory planes associated with the respective vertical local word lines. More specifically, the global word lines 194 runs in the X-direction, perpendicular to the common bit lines 62 which runs in the Y-direction. Each global word line connects to the local word lines arranged in a row across the X-direction, as shown in FIG. 4(p)(i). Meanwhile, the bit lines from different memory planes of each active stack are connected to bit line selectors through a staircase structure, formed at the ends of the memory structure in the Y-direction. The bit line selectors connect the bit lines to their respective sense amplifiers and voltage drivers circuit formed in the CuA, typically formed under the staircase structure.

It is instructive to note that FIG. 4(p) is illustrative only and is not intended to depict the exact vias and interconnect structures. For example, the vias 192 connecting the local word lines 68 to the global word lines 194 need to be isolated from the channel layer 66 so as not to short the gate conductor to the channel region of the storage transistors. Various methods for forming the vias while providing isolation are possible. In one example, the channel layer 66 may be recessed from the top of the memory array. In another example, additional dummy layers maybe included in the memory structure above the memory array (in the Z-direction) to terminate the channel layer 66 while extending each gate contactor layer for connection to a via to provide the electrical connection to the global word line 194.

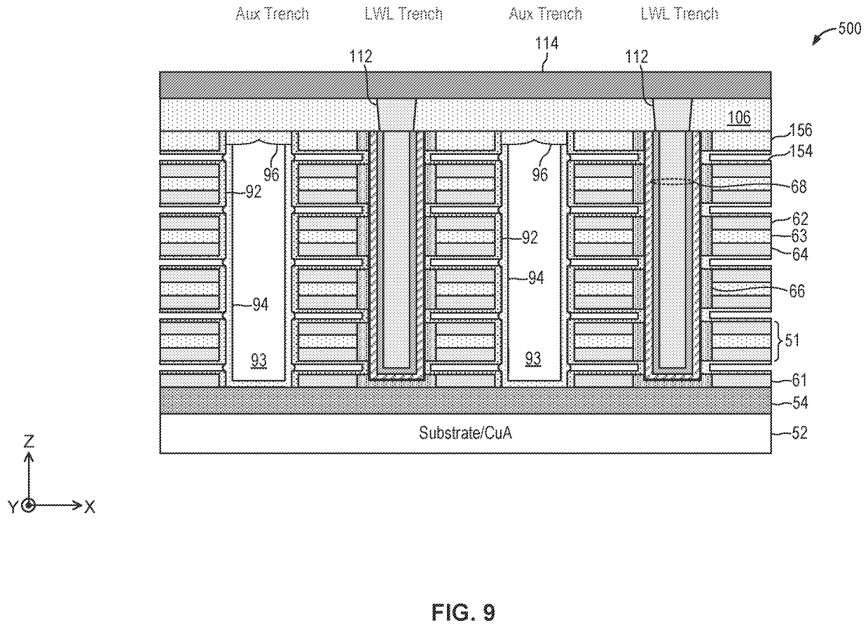

FIG. 9 illustrates a memory structure formed using dummy layers for isolating the channel layer for global word line connections in some embodiments. Referring to FIG. 9, the memory structure 500 includes a dummy isolation layer 154 and a dummy dielectric layer 156. In the initial stack formation, the dummy isolation layer 154 can be provided as an inter-layer sacrificial layer described above (e.g. FIG. 4(a)) which is subsequently replaced by the inter-layer isolation layer, such as an air gap isolation. The dummy dielectric layer 156 functions as a capping layer for the dummy isolation layer 154 during the replacement process. In particular, during intermediate processing steps, the dummy isolation layer 154, as an inter-layer sacrificial layer, is removed to provide access openings to the backside of the channel layer 66. The channel layer 66 is selectively etched through the access openings. Accordingly, the channel layer 66 is isolated to each layer of storage transistors. Then, the liner layer 92 (a thin dielectric layer) is formed around the exposed cavities of the access openings with the remaining portion forming an air gap isolation. In the present embodiment, the dummy isolation layer 154 is therefore also an air gap isolation lined with the liner layer 92. In other embodiments, the inter-layer isolation layer may be a dielectric layer and the dummy isolation layer 154 is also a dielectric layer. As thus constructed, the channel layer 66 for the topmost memory strings in the memory structure 500 is separated and isolated by the dummy isolation layer 154. A cap oxide layer 106 is formed above the memory array. Vias 112 can be formed to contact the local word lines (gate conductor layer 68) without concern for possible electrical shorts to the channel layer. A metallization layer 114 is formed on the cap oxide layer 106 to form the global word lines. Each global word line 114 connects to the local word lines through vias 112 to provide the control signal to the gate electrodes of the storage transistors formed in multiple memory planes associated with the respective vertical local word lines.

In the above-described embodiments, the memory structures are formed using a semiconductor oxide layer as the channel layer of the storage transistors. In some embodiments, the semiconductor oxide channel layer is formed as a bi-layer channel including a first semiconductor oxide layer formed on the trench sidewalls and in electrical contact with the conductive layers forming the drain and source lines and a second semiconductor oxide layer formed on the first semiconductor oxide layer. The first and second semiconductor oxide layers together form the channel layer to function as the channel region for each storage transistor. The first semiconductor oxide layer functions as a low contact resistance contact layer to the drain and source conductive layers to which it contacts. The second semiconductor oxide layer functions as the main channel layer providing the desired high mobility and high on-current for the channel region of the storage transistors. In some embodiments, the first semiconductor oxide layer is a metal oxide semiconductor material that provides a contact resistance to the conductive layers that is lower than the contact resistance provided by the second semiconductor oxide layer. In one embodiment, the first semiconductor oxide layer is, for example, an indium aluminum zinc oxide (InAlZnO or IAZO) layer of thickness around 1 nm-2 nm, and the second semiconductor oxide layer is an IGZO layer of thickness around 6 nm. In other embodiments, other semiconductor oxide materials that provide a desirably low contact resistance to metal layers can be used as the first semiconductor oxide layer. In particular, a metal oxide semiconductor material that has high immunity to deoxidization of the channel layer by the source/drain conductive layer and suppresses oxidation of the source/drain conductive layers during thermal processing is desired for use as the first semiconductor oxide layer.

In the above-described embodiments, various memory structures including multiple active layers (or memory planes) have been described. Each memory structure includes multiple memory stacks, each memory stack including multiple active layers, to realize a three-dimensional array of NOR memory strings. The memory structures can be used as the basic building block to form a high capacity, high density memory device including multiple three-dimensional arrays of the NOR memory strings. For example, the three-dimensional arrays of NOR memory strings may be arranged as a two-dimensional array of tiles, each tile including a three-dimensional array of NOR memory strings constructed using a memory structure of the several memory structures described above and including staircase portions and other supporting circuitry, including connecting wiring through global word lines at the top or bottom of each of the tiles.

In embodiments of the present disclosure, a memory structure can be formed using a single active layer. That is, a memory structure can include an array of NOR memory strings formed using a single layer of storage transistors in the vertical direction, the storage transistors being junctionless ferroelectric storage transistors having a semiconductor oxide as the channel and a ferroelectric polarization layer as the gate dielectric layer. In that case, no inter-layer isolation layer is needed. Alternately, a single layer of inter-layer isolation may be provided between the semiconductor substrate and the single active layer. With a single layer of storage transistors, no channel separation is necessary. The auxiliary trenches are used to perform metal replacement to form the first and second conductive layers serving as the common drain line and the common source line. In practice, a memory structure of a single memory plane forms a two-dimensional array of NOR memory strings. A memory device can be formed using such a memory structure where the memory device includes a two-dimensional array of tiles, each tile including a two-dimensional array of NOR memory strings formed using a single memory plane of storage transistors and other supporting circuitry. In a single layer formation, no staircase structure is needed or in the alternate, a staircase structure of only a single staircase step may be used to connect to the bit lines of each NOR memory string. Alternatively, a single layer or two layer ferroelectric memory tiles can have their first layer bit lines and their second layer bit lines connected directly to logic circuits in the substrate underneath the bit lines, through buried contacts serving as vias. In some examples, a memory device thus constructed is suitable for use as an embedded memory for providing high memory capacity within less than 10 microns distance of connectors directly above one or more processor cores for low latency data intensive applications. Accordingly, in one example, a memory device including one or two memory planes may be built integrated into the same semiconductor substrate of a logic integrated circuit to function as an embedded memory to the processing circuit of the logic integrated circuit.

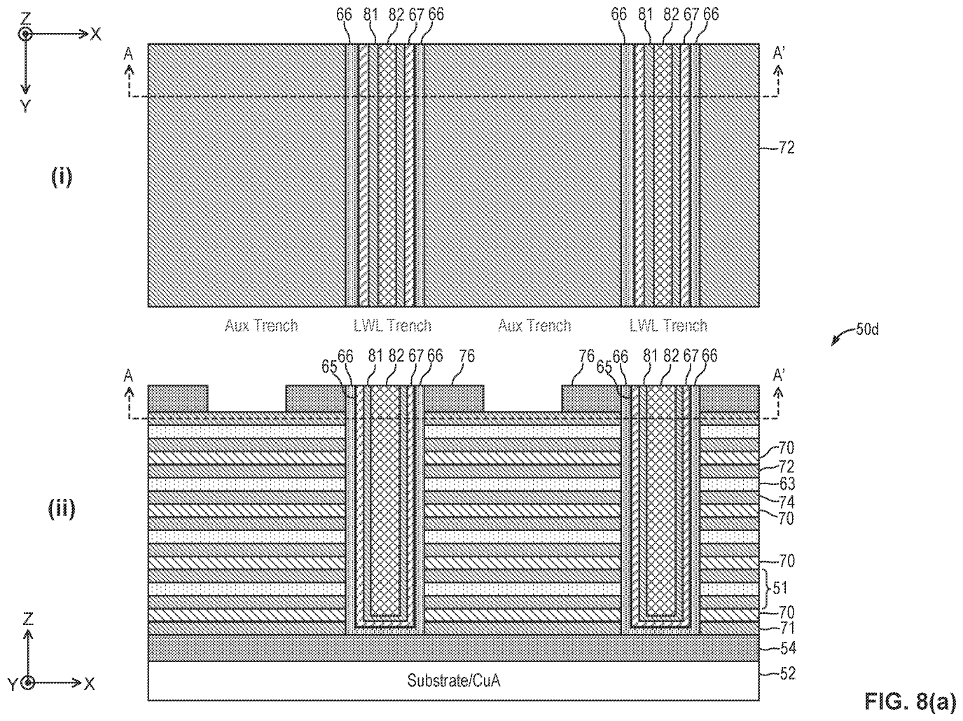

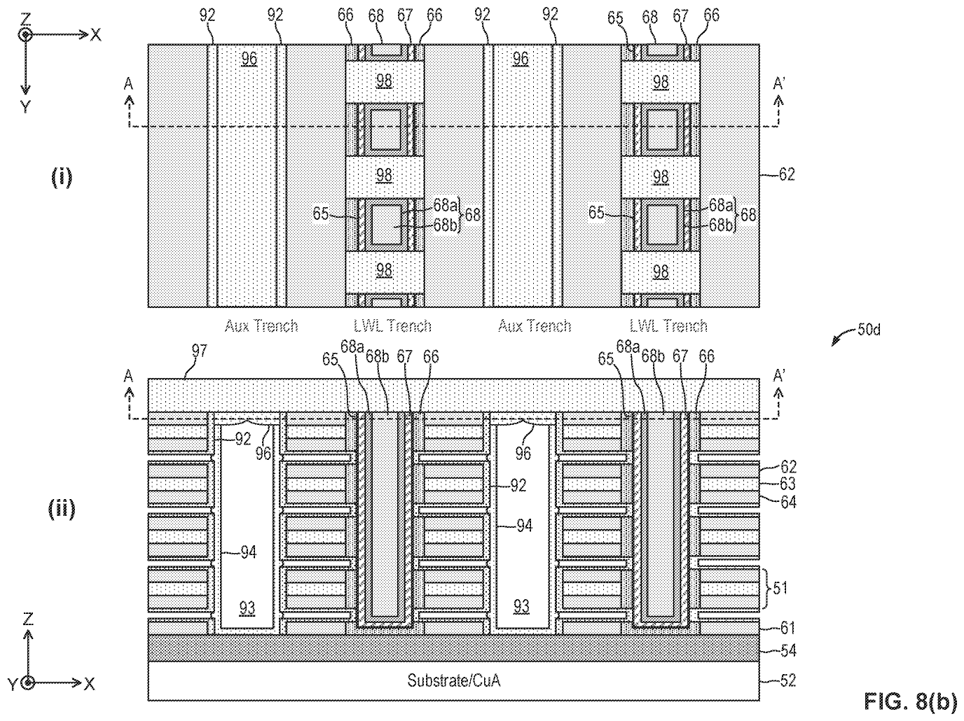

In the above-described embodiments, the channel layer 66 is formed after the LWL trenches are made (FIG. 4(c)) and then protected by sacrificial materials and subsequently processing removes the sacrificial materials to form the ferroelectric polarization layer 67 on the channel layer 66. In some embodiments, the ferroelectric polarization layer can be formed at the same time as the channel layer 66, thereby to avoid oxidation of the channel layer 66 if exposed to oxygen or during elevated temperature anneals. In some cases, the two layers can be formed in the same process chamber without breaking vacuum which makes it more efficient to form the two layers at the same time. FIGS. 8(a) and 8(b) illustrate an alternate process for fabricating a memory structure including HNOR memory strings in embodiments of the present invention. FIGS. 8(a) and 8(b) illustrate a memory structure 50d constructed in substantially the same manner as described above and the structure and method of construction will not be repeated to simplify the discussion. Like elements in FIGS. 8(a) and 8(b) and in previous figures are given like reference numerals and will not be further described.

First, referring to FIG. 8(a) which illustrates an intermediate processing step after the LWL (or operational) trenches 80 are formed in the memory structure 50d, a channel layer 66 is deposited on the sidewalls of the trenches 80. For example, the channel layer 66 is a semiconductor oxide layer, such as indium gallium zinc oxide (IGZO). Then, a gate dielectric layer 67 is deposited onto the channel layer 66. For example, the gate dielectric layer 67 is a ferroelectric polarization layer, such as a doped hafnium oxide layer. An optional interfacial layer 65 may be formed between the channel layer 66 and the gate dielectric layer 67. For example, the interfacial layer 65 may be an ultrathin silicon nitride (Si₃N₄) layer, or a silicon oxynitride layer, or an aluminum oxide (Al₂O₃) layer. Then, a liner layer 81 is deposited to cover the gate dielectric layer 67 and the remaining volume in the trenches 80 is filled with a sacrificial material 82. In one embodiment, the liner layer 81 can be a low temperature (under 500° C.) silicon nitride layer or an undoped amorphous silicon layer and the sacrificial material 82 is silicon germanium. After the deposition steps, excess material may be removed from the top of memory structure 50c using, for example, chemical-mechanical polishing (CMP).

The process of forming the memory structure 50d continues in the same manner as described above with reference to FIG. 4(d) to 4(o) (or 4(o1)), except during the processing steps of forming the local word line structures between the dielectric filled shafts 98 in FIG. 4(f), only the gate conductor layer 68 is formed, as the gate dielectric layer 67 is already formed at this processing step. In forming memory structure 50d, the thermal anneal of the gate dielectric layer 67 may be performed after the gate conductor layer 68 is deposited on the gate dielectric layer. In this manner, the gate conductor layer 68 functions as a capping layer for the crystallization of the ferroelectric material used as the gate dielectric layer.

The resulting memory structure at the end of the fabrication process is shown in FIG. 8(b). Referring to FIG. 8(b), the memory structure 50c includes the channel layer 66 and the gate dielectric layer 67 both extending along the Y-direction between the dielectric filled shafts 98. No gate dielectric layer 67 is formed in the X-direction on the sides of the dielectric filled shafts 98. This results in the ferroelectric storage transistors in memory structure 50d having a slightly wider transistor width (W) than in the storage transistors of the above-described memory structures. The longer transistor width of the storage transistors in memory structure 50d provides higher read current during read operation.

Precharge Transistors

In embodiments of the present invention, a memory structure includes three-dimensional array of NOR memory strings of junctionless ferroelectric storage transistors. The storage transistors in each NOR memory string share the common source line and the common drain line (common bit line). The voltage on each shared common source line can be separately applied directly from one or both ends of each source line in the three-dimensional structure. In some embodiments, the shared common source line is electrically floating and the source voltage is applied from the common bit line using precharge transistors so as to obviate the need to provide connector wires to the source lines at the staircase portions of the three-dimensional structure. In one embodiment, the source voltage on a given source line is set to a desired voltage value (such as the ground voltage) through a precharge operation using one or more precharge transistors formed along the memory string and the source line is then left floating after the precharge operation. In particular, the precharge operation set the common bit line to a desired voltage and then the precharge transistor is momentarily turned on to short the common bit line to the common source line to transfer the bit line voltage to the source line. As a result, the common source line is charged from the voltage on the common bit line to a voltage to equal to the bit line voltage. After the precharge operation is complete, the precharge transistor(s) is turned off. The common source line maintains a relatively constant voltage through the parasitic capacitance at the source terminals, such as the parasitic capacitance between the source terminals and the numerous local word line gate terminals of the storage transistors in the NOR memory string.

In embodiments of the present invention, various schemes can be used to provide precharge transistors in the three-dimensional array of NOR memory strings described above.

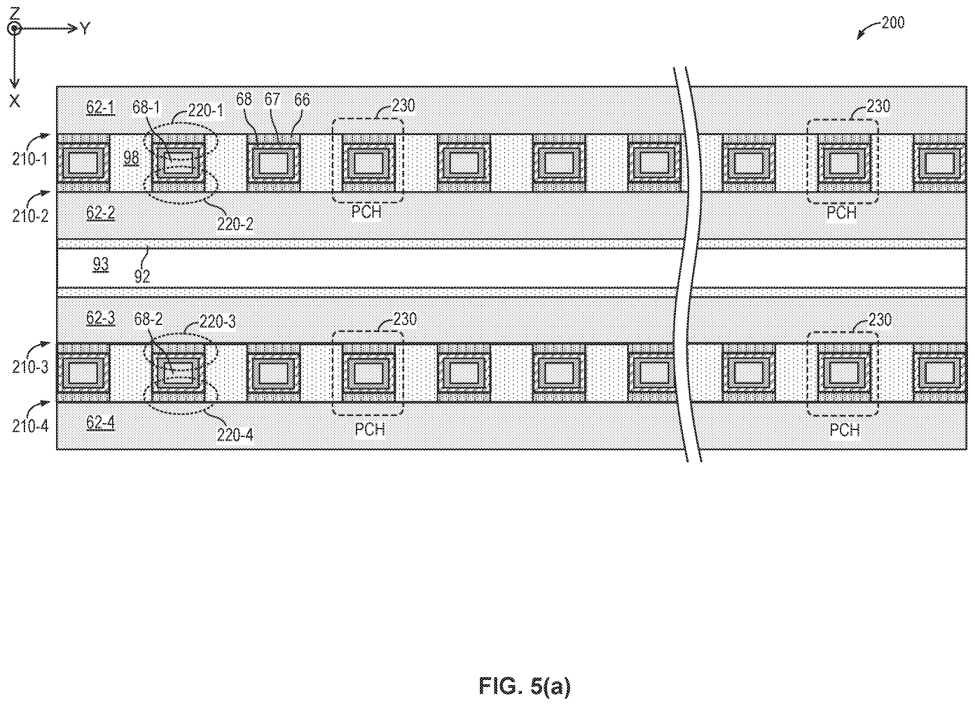

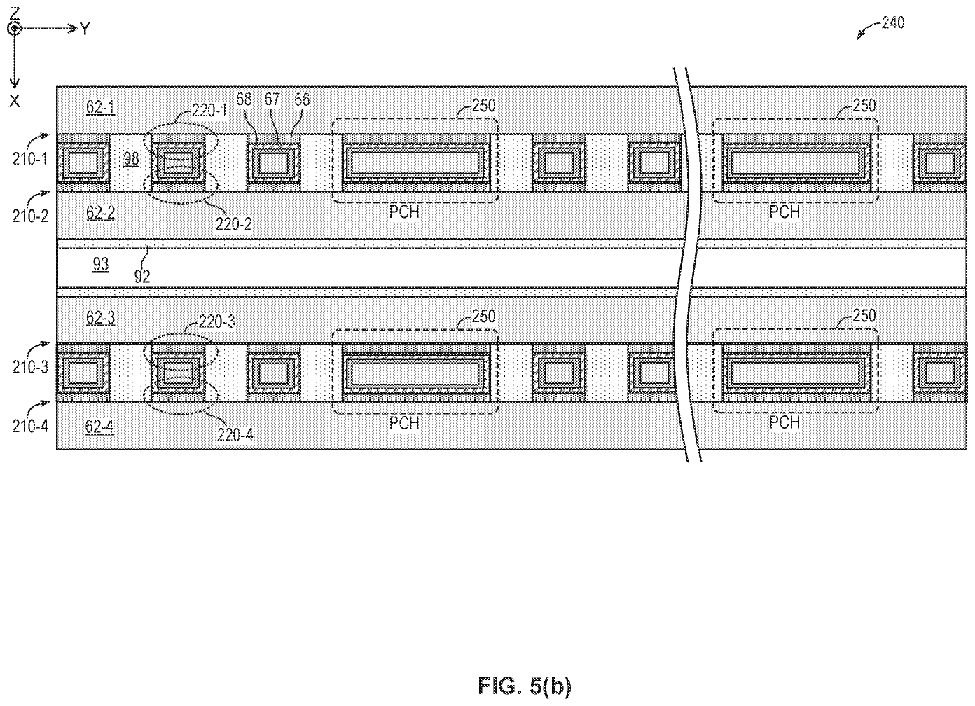

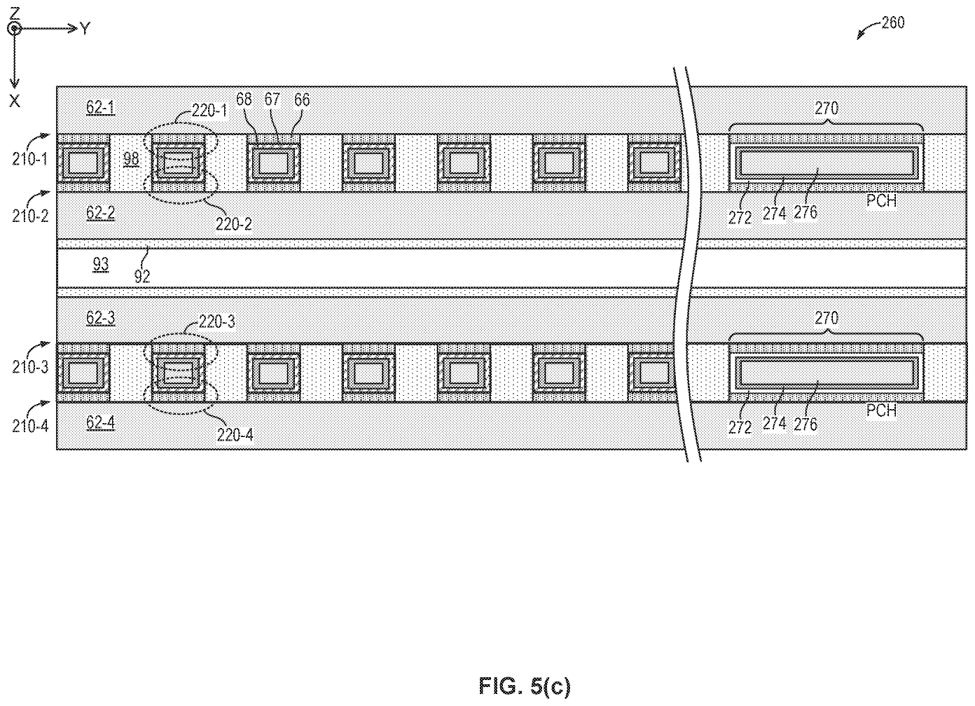

In a first embodiment, selected ferroelectric storage transistors in a NOR memory string are designated as precharge transistors. FIG. 5(a) is a cross-sectional view of a portion of a memory structure in the X-Y plane illustrating NOR memory strings with designated precharge transistors in embodiments of the present invention. Referring to FIG. 5(a), a memory structure 200 includes active stacks bordering operational trenches with local word lines formed therein and auxiliary trenches used for metal replacement and channel separation processes. In the present illustration, the cross-sectional view is taken at the first conductive layer 62 of a given active layer in an active stack. The first conductive layer 62 forms the common bit line of the memory string. A ferroelectric storage transistor 220 is formed at each intersection of the common bit line 62 with the channel layer 66, the ferroelectric polarization layer 67 and the gate conductor 68. FIG. 5(a) illustrates four memory strings 210-1 to 210-4 that are formed extending in the Y-direction along four active stacks (represented by respective first conductive layer 62-1 to 62-4). For example, each memory string 210 includes the ferroelectric storage transistors 220 formed along the active stack 62 and intersecting with all of the local word line structures along the active stack 62. The storage transistors 220 are isolated from other storage transistors in the memory string by the dielectric filled shafts 98.

It is instructive to note that in memory structure 200, a pair of memory strings 210 in each memory plane bordering a LWL trench have corresponding storage transistors sharing a local word line structure. Accordingly, each local word line activates two ferroelectric storage transistors in the memory strings bordering the LWL trench in each memory plane. In one example, in response to the local word line 68-1 being selected, ferroelectric storage transistors 220-1 and 220-2 associated with respective memory strings 210-1 and 210-2 are activated. The common bit lines 62-1 and 62-2 are in turn selected to provide access and the appropriate voltages are provided to the activated ferroelectric storage transistors 220-1 and 220-2. In another example, in response to the local word line 68-2 being selected, ferroelectric storage transistors 220-3 and 220-4 associated with respective memory strings 210-3 and 210-4 are activated. The common bit lines 62-3 and 62-4 are in turn selected to provide access and appropriate voltages are provided to the activated ferroelectric storage transistors 220-3 and 220-4. In some embodiments, when storage transistor 220-1 is to be erased, storage transistor 220-2, which may be in a programmed state, needs to be protected from being erased as well. As an example of a typical erase operation of ferroelectric storage transistor 220-1, the erase operation may require 3.0 Volts applied to the local word line 68-1, and 0.0 Volts applied to its bit line 62-1. To prevent erasing of ferroelectric storage transistor 220-2 (that shares the same local word line 68-1 and therefore has the same 3.0 Volts on its control gate), its bit line 62-2 must be held at an inhibit voltage Vinhb that is close enough to 3.0V to avoid flipping of the polarization state of ferroelectric storage transistor 220-2. The same applies to all program and program inhibit operations, as well as for inhibiting disturbing the polarization state of ferroelectric storage transistors on different planes above or below the plane being accessed, that are not being addressed yet are still being exposed to the voltage on their shared local word lines.

In the present embodiment, a selected number of storage transistors 220 in each memory string 210 are designated for use as precharge transistors 230. In one example, one storage transistor per two hundred and fifty (250) storage transistors along a memory string will be designated as a precharge transistor 230. In a memory string of two thousands (2000) or more storage transistors, 8-10 storage transistors dispersed through the memory string may be designated as precharge transistors. FIG. 5(a) illustrates a portion of the memory strings 210-1 to 210-4 where two storage transistors 230 in each memory string 210 have been designated as precharge transistors. The entire memory string 210 may include 8-10 storage transistors designated as precharge transistors.

In each precharge operation, one or more precharge transistors are activated for setting the common source line voltage. In some embodiments, only a subset of the designated precharge transistors is used in each precharge operation. For example, during the precharge operation, one or more designated precharge transistors in a memory string 210 are activated by the memory controller to perform the precharge operation. In one embodiment, the memory controller selects or rotates randomly the physical addresses of the designated precharge transistors from time to time so that different subset of precharge transistors in the memory string are selected over the course of the memory operation. Randomizing the usage of the precharge transistors in each memory string has the effect of reducing electrical stress that may be experienced by each designated precharge transistor over repetitive precharge operations. In one example, after every X-number of precharge operations or after every given time interval, the memory controller changes the physical address of the precharge transistors to be used so that a different subset of precharge transistors in the memory string is selected for use for the next set of X-number of precharge operations. In the present description, the precharge operation may activate one or more precharge transistors and a “subset” of precharge transistors refers to one or more precharge transistors in the present description.

In an alternate embodiment, the memory controller determines through periodic refresh operations the health conditions of the designated precharge transistors. In the event the memory controller determines through the refresh operation that certain precharge transistors have health conditions indicating the transistors are about to fail, such as when a precharge transistor is exhibiting a high leakage current, the memory controller may retire those precharge transistors and replace them with other designated precharge transistors in the respective memory strings.

In a second embodiment, precharge transistors are provided in each NOR memory string as ferroelectric storage transistors, preferably with increased channel width. FIG. 5(b) is a cross-sectional view of a portion of a memory structure in the X-Y plane illustrating NOR memory strings with precharge transistors in embodiments of the present invention. Like elements in FIGS. 5(a) and 5(b) are given like reference numerals and will not be further described. Referring to FIG. 5(b), precharge transistors 250 are provided in each memory string as ferroelectric storage transistors with increased channel width. That is, a precharge transistor 250 in a memory string 210 is constructed in the same manner the storage transistors 220 but is constructed with a width in the Y-direction greater than the width of the storage transistors 220. Several precharge transistors 250 may be provided in each memory string and dispersed throughout the respective memory string. Increasing the channel width of the ferroelectric storage transistor has the effect of increasing the On current (Ion) of the storage transistor. Accordingly, the precharge transistors 250 have a larger On current as compared to the storage transistors 220. The precharge transistor 250 thus have increased On current and increased drive for use during the precharge operation to effectively bias the common source line to the common bit line voltage.

In a third embodiment, non-memory transistors are formed in each memory string to use as precharge transistors. FIG. 5(c) is a cross-sectional view of a portion of a memory structure in the X-Y plane illustrating NOR memory strings with precharge transistors in embodiments of the present invention. Like elements in FIGS. 5(a) and 5(c) are given like reference numerals and will not be further described. Referring to FIG. 5(c), precharge transistors 270 are provided in each memory string 210 as non-memory transistors. In the present embodiment, the precharge transistors 270 are junctionless transistors formed using the same semiconductor oxide channel layer 66 as the storage transistors but using a non-polarizable gate dielectric film 272 between the channel layer and the gate conductor 276. Several precharge transistors 270 may be provided in each memory string and dispersed throughout the respective memory string.

To form the precharge transistors 270 in the memory structure 260 in FIG. 5(c), a mask is applied to the memory structure 260 to cover all of the memory strings 210 with openings exposing locations where the precharge transistors are to be formed. Note that the precharge transistors 270 may be formed during intermediate processing steps of the memory array. For example, the precharge transistors 270 may be formed in the memory structure 260 after the channel layer 66 is formed (e.g. after the processing step in FIG. 4(c)) but before local word line process (e.g. before the processing step in FIG. 4(d)).

Using the mask defining the precharge transistor openings, the liner layer 81 and the sacrificial material 82 covering the channel layer 66 are removed, such as by one or more wet etch process. A gate dielectric layer 272 is then deposited on the sidewalls of the excavated cavities, on the channel layer 66. In one embodiment, the gate dielectric layer 272 is a silicon oxide (SiO₂) layer. In other embodiments, the gate dielectric layer 272 can be a hafnium oxide layer (HfO₂), or a sandwich of silicon oxide (SiO₂) capped by silicon oxynitride (Si₂NO₃), or aluminum oxide (Al₂O₃). Then, a conductive layer is deposited to serve as the gate conductor of the precharge transistors 270. The gate conductor may include successively deposited conductive liner layer 274 and low resistivity conductor 276. In some embodiments, the conductive liner layer 274 is a titanium nitride (TiN) layer and the conductor 276 is a heavily doped polysilicon layer or a tungsten (W) layer. Excess deposited materials may be removed from the top of memory structure by CMP. The precharge transistors 270 thus formed are controlled by the conductor 276 as the control gate electrode. Subsequent to forming the precharge transistors 270, the fabrication process may cover the precharge transistors 270 and exposing the areas associated with the memory array to continue manufacturing the storage transistors. In some embodiments, the gate electrode of the precharge transistors 270 are connected to global word lines formed above the memory array which connect to the control circuits formed in the CuA to allow the control circuits or the memory controller coupled thereto to select and activate the precharge transistors 270 to perform precharge operations.

Enhanced Fringing Field Effect

In the memory structure 10 of FIG. 1, the channel length of the ferroelectric storage transistor 20 thus formed is determined by the thickness L1 of the channel spacer dielectric layer 23. In embodiments of the present invention, shorter channel lengths, such as L1 less than 10 nm, can accentuate the electric fringing-field effect of the ferroelectric storage transistor which enhances the polarization effect in the ferroelectric dielectric layer. Referring again to FIG. 1, when erase or program voltages are applied between the bit line (BL) electrode 22 and the control gate electrode 28, the electric field between the two electrodes is imposed onto the part of the ferroelectric dielectric layer 27 that is directly opposite the BL electrode to cause the desired change in polarization in the ferroelectric dielectric layer 27. The electric field further includes fringing field that extends into part of the channel 26.

In some embodiments, the fringing electric field is further accentuated by biasing the bit line (BL) and the source line (SL) to the same voltage during erase and program operations. In other words, the bit line (BL) and the source line (SL) of the ferroelectric storage transistor is being used as a single electrode during the erase and program operations. With the bit line and the source line biased as a single electrode, the fringing electric fields from both the bit line 22 and the source line 24 extends into the channel 26 from both ends and the fringing electric field overlaps most of, or the entire length of, the channel 26 when the channel is sufficiently short. By biasing the ferroelectric storage transistor in a single electrode mode to accentuate the fringing electric field, the polarization of the ferroelectric dielectric layer is enhanced which can result in a wider threshold voltage window between the erase and program states.

In one embodiment, when the memory structure implements the floating source architecture, the precharge transistors described above can be used to facilitate the equalization of the voltages of the bit line 22 and the source line 24 during erase or program operations so that the bit line 22 and the source line 24 operates as a joint electrode to maximize the fringing field coverage of ferroelectric dielectric layer 27.

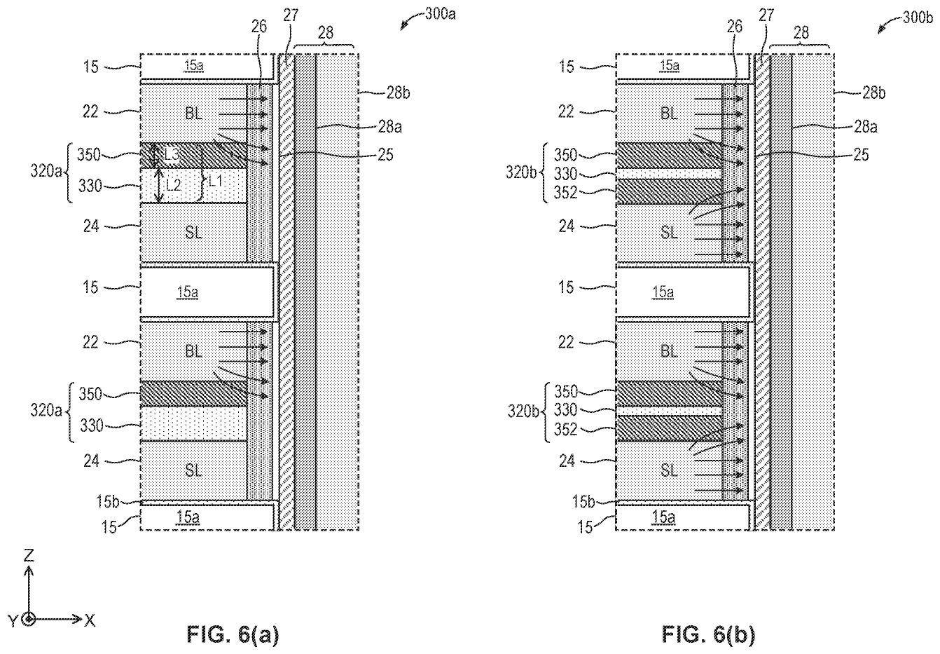

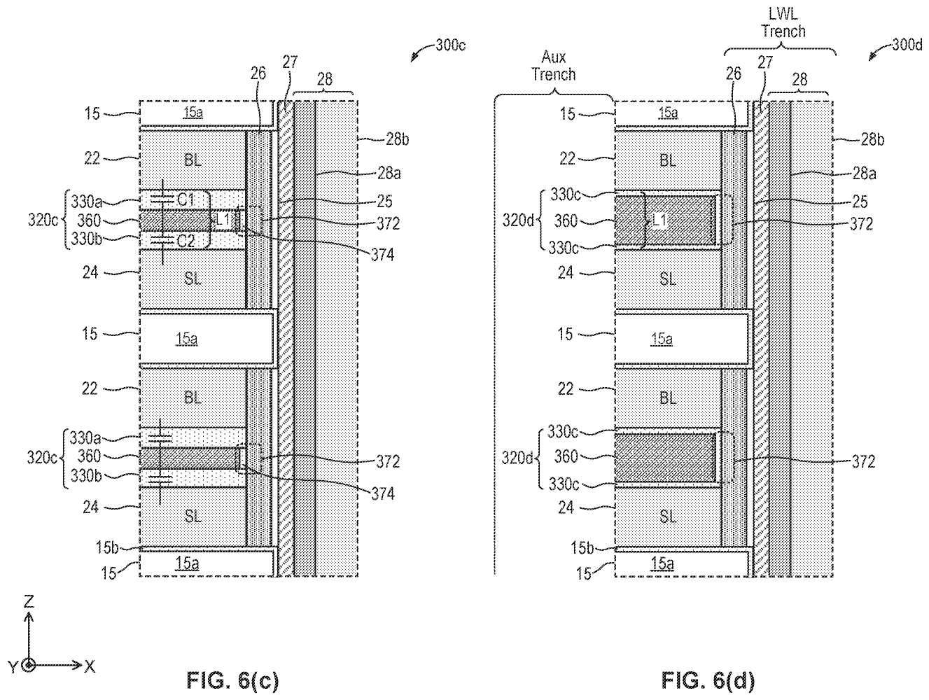

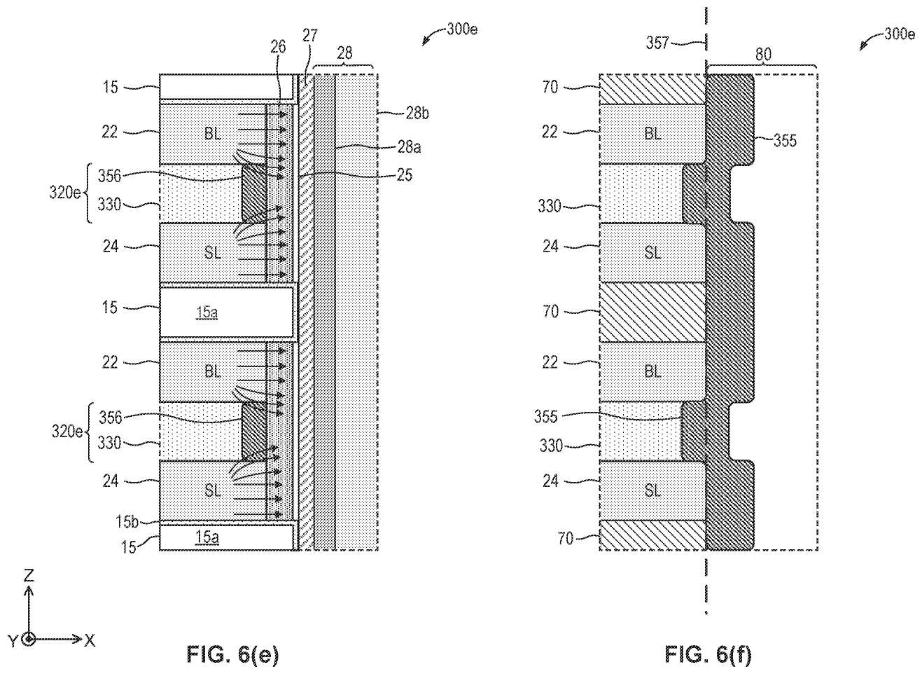

In another embodiment of the present invention, the fringing electric field is enhanced by using a high dielectric constant (high-K) dielectric layer in the channel spacer region adjacent the bit line. FIGS. 6(a), 6(b), 6(c) and 6(d) illustrate the detail construction of junctionless ferroelectric storage transistors in alternate embodiments. Like elements in FIGS. 1 and 6(a) to 6(d) are given like reference numerals and may not be further described in detail. Referring first to FIG. 6(a), a ferroelectric storage transistor 300a includes a bit line 22 forming the common drain line of the NOR memory string, and a source line 24 forming the common source line of the NOR memory string, the bit line 22 and the source line 24 being spaced apart by a channel spacer dielectric layer 320a. The storage transistor 300a further includes a semiconductor oxide channel layer 26 formed vertically along the sidewall of the memory stack and in contact with both the bit line 22 and the source line 24. A ferroelectric dielectric layer 27 and a gate conductor layer 28 are formed on the sidewall of the memory stack adjacent the channel layer 26. In some embodiments, an optional interfacial layer 25 may be provided between the channel layer 26 and the ferroelectric dielectric layer 27. In the present embodiment, the gate conductor layer 28 includes a conductive liner 28a as an adhesion layer and a low resistivity conductor 28b. The storage transistor 300a is isolated from adjacent storage transistors in the stack by an inter-layer isolation layer 15, which can be include an air-gap isolation 15a surrounded by a liner layer 15b. As thus configured, the storage transistors 300a are junctionless ferroelectric storage transistors.

In embodiments of the present invention, the channel spacer dielectric layer 320a includes a first dielectric layer 330 and a second dielectric layer 350. The second dielectric layer 350 is formed between the bit line 22 and the first dielectric layer 330. The second dielectric layer 350 has a dielectric constant greater than the dielectric constant of the first dielectric layer 330 and is referred to as a high dielectric constant (high-K) dielectric layer in the present description. In some examples, a high dielectric constant dielectric layer or high-K dielectric as used in the present description refers to a dielectric layer with a dielectric constant greater than the dielectric constant of a silicon oxide layer. By incorporating the high-K dielectric layer 350 adjacent the bit line 22, the fringing electric field between the bit line electrode 22 and the gate electrode 28 is concentrated in the portion of the channel 26 closest to the bit line 22, which has the effect of enhancing the polarization effect of the ferroelectric polarization layer 27 during program and erase operations.

In some embodiments, the high-K dielectric layer 350 can be formed using silicon nitride (having a dielectric constant of about 6) or hafnium oxide (having a dielectric constant of about 19). Other high-K dielectric materials that can be used include silicon oxynitride (SiON). Meanwhile, the first dielectric layer 330 can be formed using silicon dioxide (having a dielectric constant of about 4). In some embodiments, the first dielectric layer 330 has a thickness L2 and the high-K dielectric layer 350 has a thickness L3 and the ferroelectric storage transistor 300 has an effective channel length of L1=L2+L3. In one example, the thickness L2 is 15 nm and the thickness L3 is 10 nm, and the effective channel length of the storage transistor 300 is 25 nm. The high-K dielectric layer 350 may be provided in the fabrication process by including the high-K dielectric layer in the deposition process forming the multilayer stack, such as described with reference to FIG. 4(a). Alternately, the high-K dielectric layer may be provided initially as a sacrificial layer, subsequently replaced by the desired material to form the high-K dielectric layer.

The higher dielectric constant of the high-K dielectric layer 350 serves to concentrate the fringing electric field that extend over the channel 26 when polarization voltage is applied between the bit line electrode 22 and the control gate electrode 28. The accentuation of the fringing electric field is particularly effective if the bit line conductive layer 22 is very thin (e.g. 20 nm or less), in which case any contribution to the electric field from the field fringing into channel 26 is reinforcing the polarization effect during erase or program operation.

In the embodiment shown in FIG. 6(a), the high-K dielectric layer 350 is provided only adjacent the bit line conductive layer 22. In other embodiments, as shown in FIG. 6(b), a ferroelectric storage transistor 300b maybe formed with a channel spacer dielectric layer 320b including two high-K dielectric sub-layers. Referring to FIG. 6(b), the channel spacer dielectric layer 320b may include a first high-K dielectric layer 350 provided adjacent the bit line conductive layer 22 and a second high-K dielectric layer 352 provided adjacent the source line conductive layer 24. A narrow dielectric layer 330 may separate the first and second high-K dielectric layers 350, 352. In alternate embodiments, the entire channel spacer dielectric layer can be formed entirely of a high-K dielectric layer, such as a dielectric layer with a dielectric constant greater than the dielectric constant of a silicon oxide layer.

FIGS. 6(c) and 6(d) illustrate alternate constructions of ferroelectric memory transistors including a virtual back-gate in some embodiments. Referring to FIG. 6(c), a ferroelectric memory transistor 300c includes a virtual back-gate formed in the channel spacer layer 320c. In particular, the channel spacer layer 320c includes a first dielectric sub-layer 330a provided adjacent the bit line conductive layer (BL) 22 and a second dielectric sub-layer 330b provided adjacent the source line conductive layer (SL) 24. The channel spacer layer 320c further includes a third sub-layer 360 provided between the dielectric sub-layers 330a and 330b and is thereby electrically insulated from the bit line conductive layer 22 and the source line conductive layer 24. As a result, the third sub-layer 360 is an electrically floating sub-layer. First and second dielectric sub-layer 330a and 330b can be any dielectric materials, such as silicon dioxide, or silicon nitride, or a high dielectric constant dielectric material, such as hafnium oxide. Sub-layer 360 can be formed using a material selected from a semiconductor, or a low resistivity material such as titanium nitride (TiN), tungsten, molybdenum or other metallic materials. In some examples, sub-layer 360 can be undoped silicon, P-type or N-type doped silicon, undoped polysilicon, or P-type or N-type doped polysilicon.

In some embodiments, dielectric sub-layers 330a and 330b can be silicon dioxide layers while sub-layer 360 can, for example, be an amorphous silicon layer, or a polysilicon layer, or a silicon germanium layer. Sub-layer 360 may be undoped, or can be doped with boron to form a P-type semiconductor layer, or doped with phosphorous to form an N-type semiconductor layer. Sub-layer 360 overlaps with a channel portion 372 of the channel layer 26, which is an oxide semiconductor material, such as IGZO. A dielectric interfacial layer 374 is provided between the sub-layer 360 and the channel portion 372 to isolate the sub-layer 360 from the channel layer 26. In one embodiment, an ultra-thin dielectric interfacial layer 374 (such as between 0.5 nm and 2 nm) is provided between the channel layer 26 and the sub-layer 360. In one embodiment, the dielectric interfacial layer is one of silicon dioxide, silicon nitride, silicon oxynitride, aluminum oxide or a high dielectric constant material, such as hafnium oxide.

As thus configured, sub-layer 360 is capacitively coupled to both the bit line conductive layer 22 and the source line conductive layer 24, denoted by respective capacitor C1 and capacitor C2 in FIG. 6(c), as well as being capacitively coupled to the channel layer 26. During program or erase operations of the ferroelectric memory transistor 300c, the voltage applied to the bit line and the source line can be made to track each other, for example, through a pre-charge transistor connecting between the bit line and the source line. With the bit line 22 and the source line 24 thus biased, the bit line and the source line also function to capacitively hold the voltage of the electrically floating sub-layer 360. As thus operated, sub-layer 360 becomes a virtual back-gate for the channel portion 372 of the channel layer 26. In the present description, the term “virtual” is used herein to denote that sub-layer 360 is electrically floating, i.e., sub-layer 360 is not hard-wire connected to a voltage source; instead the voltage on sub-layer 360 is established by following the voltages of the capacitive-coupled bit line, source line and the channel portion 372. This arrangement of the ferroelectric memory transistor 300c with a channel being formed between the vertical front-gate 28 and the horizontal back-gate 360 accentuates the polarization field between the hard-wired front-gate 28 and the floating virtual back-gate 360, resulting in maximum polarization along the channel section 372 of the channel region for both erase and program polarization states. In some embodiments, the doping type and concentration of the virtual back-gate 360 determines its work function relative to the channel layer 26 and hence can play a role in shifting the native threshold voltage of the ferroelectric memory transistor 300c.

In the ferroelectric memory transistor 300c, sub-layers 330a, 360 and 330b together make up the channel length L1 of the transistor. In the embodiment shown in FIG. 6(c), the three sub-layers are of approximately the same thickness in the Z-direction between the bit line 22 and the source line 24. In other embodiments, the sub-layers 330a and 330b are made thinner than the sub-layer 360, allowing channel section 372 to occupy more or almost the entire channel length L1 of the transistor channel. In some embodiments, the dielectric sub-layers 330a and 330b can be as thin as around 1 to 7 nm, while the thickness of sub-layer 360 can be several times thicker. For example, each of the dielectric sub-layers 330a and 330b can be as thin as 3 nm. As thus configured, the channel section 372 of the virtual back-gate 360 can be made to cover nearly the entire channel length L1 of the channel layer 26. This extended length of the virtual back-gate formed by sub-layer 360 has the benefit of reducing the threshold voltage variability for erased and programmed polarization states of the ferroelectric storage transistors 300c across the memory die or across a wafer of memory die.

FIG. 6(d) illustrates an alternate embodiment of ferroelectric memory transistors including a virtual back-gate. In the embodiment shown in FIG. 6(d), a ferroelectric memory transistor 300d has a channel spacer layer 320d including a dielectric sub-layer 330c formed as a dielectric liner layer surrounding a sub-layer 360 forming the virtual back-gate. In particular, the dielectric sub-layer 330c is a dielectric insulator liner layer, such as one of silicon dioxide, silicon nitride, silicon oxynitride, aluminum oxide or a high dielectric constant material, such as hafnium oxide, that is formed along the bit line conductive layer 22, the source line conductive layer 22 and the vertical sidewall region adjacent the channel layer 26 between the bit line 22 and the source line 24. In some embodiments, the dielectric liner layer 330c may have a thickness of 1 to 10 nm, and typically has a thickness between 2 nm to 5 nm in some examples. In some embodiments, virtual back-gate 360 can be formed by access from the auxiliary trench. The sub-layer 360 forming the virtual back-gate can be formed using the materials described above with reference to the FIG. 6(c), including undoped or doped semiconductor or a low resistivity material. For example, after the auxiliary trench is formed, as shown in FIG. 4(h) above, providing backside access to the active stacks, an earlier deposited sacrificial layer, such as layer 63 in FIG. 4(a), is removed by selective etching using access from the auxiliary trench to form excavated cavities. After removal of the sacrificial layer 63, dielectric sub-layer 330c can be formed on the walls of the excavated cavities by a deposition process, such as atomic layer deposition, again using access through the auxiliary trench. As a result, a dielectric liner layer 330c is deposited on the exposed sidewalls of the excavated cavities, insulating the bit line 22, the channel layer 26 and the source line 24. The remaining space in the excavated cavities is then filled from the auxiliary trench with deposited sub-layer 360 to form the virtual back-gate for memory transistor 330d, as shown in FIG. 6(d). As an example, if back-gate 360 is formed by doped amorphous silicon, and if the desired length L1 of the back-gate 360 is 15 nanometers, then a deposition of around 8-10 nanometer of the doped amorphous silicon will fill the excavated cavities. In the deposition process, 8-10 nm of unwanted residual silicon will be deposited on the sidewalls of the auxiliary trench outside the excavated cavities and on other peripheral structures. These residual silicon can be removed by controlled selective silicon etching, including atomic-layer etch (ALE) to leave intact most of the silicon inside the cavities to form the back-gate 360 while avoiding electrical shorting between bit lines 22 and source lines 24 of adjacent memory planes in the memory stack (Z-direction). In embodiments of the present disclosure, the back-gate replacement process can be carried out before or after the metal replacement process described above with reference to FIGS. 4(i) to 4(k).

In memory transistor 300d as thus configured, the channel section 372 of the virtual back-gate is made to cover nearly the entire channel length L1 of the channel layer 26. When selected for erase or program, transistor 300d operates as a virtual capacitor at the intersection area between the vertical (in the Z-direction) gate conductor 28 as one capacitor electrode, and the horizontal (in the Y-direction) virtual back-gate 360, in combination with the bit line 22 and the source line 24 together making up the other capacitor electrode. This virtual capacitor configuration enhances the polarization field across the ferroelectric dielectric layer 27 and improves the polarization uniformity across the entire length of the channel 36, which, in the absence of back-gate 360 would depend primarily on the polarization fringing fields at each of bit line 22 and source line 24. The configuration of transistor 300d also improves the threshold voltage uniformity across the memory die as well across a wafer of memory die. This is because the polarization area 372 is essentially shielded from both sides by the closely adjacent polarization areas under bit line 22 and source line 22.

In the ferroelectric memory transistors 300c and 300d of FIGS. 6(c) and 6(d), the voltage differential between the selected bit line BL and the source line SL during erase, program or read operations is kept at sufficiently low voltage values to avoid injection of electrons from the bit line or the source line into the floating back-gate 360. For example, the voltage differential can be in the range of 0.05V to 0.5V.

In some embodiments the voltage on the back-gate 360 is hard-wire connected to external voltage sources by conductive connectors accessed through the auxiliary trenches (not shown in FIG. 6(c), (6d)). This allows a memory array configuration wherein the external voltage can be shared by the back-gates 360 of more than one memory plane in the memory stack along the Z-direction.

FIGS. 6(e) and 6(f) illustrate the detail construction of junctionless ferroelectric storage transistors in alternate embodiments. In particular, FIGS. 6(e) and 6(f) illustrates an alternate embodiment of junctionless ferroelectric storage transistors with a high dielectric constant (high-K) dielectric layer in the channel spacer region. Like elements in FIGS. 1, 6(a)-6(b) and 6(e)-6(f) are given like reference numerals and may not be further described in detail. FIG. 6(e) illustrates ferroelectric storage transistors 300e including a sidewall high-K dielectric layer 356 provided between the bit line conductive layer 22 and the source line conductive layer 24 and adjacent and in contact with the channel layer 26. FIG. 6(f) illustrates ferroelectric storage transistors 300e at an intermediate processing step to illustrate a method for forming the sidewall high-K dielectric layer in some embodiments.

Referring first to FIG. 6(e), a ferroelectric storage transistor 300e includes a bit line 22 forming the common drain line of the NOR memory string, and a source line 24 forming the common source line of the NOR memory string, the bit line 22 and the source line 24 being spaced apart by a channel spacer dielectric layer 320e. The storage transistor 300e further includes a semiconductor oxide channel layer 26 formed vertically along the sidewall of the memory stack and in contact with both the bit line 22 and the source line 24. A ferroelectric dielectric layer 27 and a gate conductor layer 28 are formed on the sidewall of the memory stack adjacent the channel layer 26. In some embodiments, an optional interfacial layer 25 may be provided between the channel layer 26 and the ferroelectric dielectric layer 27. In the present embodiment, the gate conductor layer 28 includes a conductive liner 28a as an adhesion layer and a low resistivity conductor 28b. The storage transistor 300e is isolated from adjacent storage transistors in the stack by an inter-layer isolation layer 15, which can be include an air-gap isolation 15a surrounded by a liner layer 15b. As thus configured, the storage transistors 300e are junctionless ferroelectric storage transistors.

In embodiments of the present invention, the channel spacer dielectric layer 320e includes a first dielectric layer 330 and a second dielectric layer 356. The second dielectric layer 356, also referred to as a sidewall high-K dielectric layer, is formed between the bit line 22 and the source line 24 and adjacent to and in physical and electrical contact with the channel layer 26. The second dielectric layer 356, as a high-K dielectric layer, has a dielectric constant greater than the dielectric constant of the first dielectric layer 330. In some examples, a high dielectric constant dielectric layer or high-K dielectric layer as used in the present description refers to a dielectric layer with a dielectric constant greater than the dielectric constant of a silicon oxide layer. In some embodiments, the second dielectric layer has a thickness in the X-direction that is between 3-10% of the thickness of the first dielectric layer. By incorporating the high-K dielectric layer 356 on the sidewall of the channel layer 26 between the bit line 22 and the source line 24, the fringing electric field from the bit line electrode 22 and the source line electrode 24 are concentrated in the portion of the channel 26 in the channel spacer region, which has the effect of functioning as a back-gate to enhance the polarization effect of the ferroelectric polarization layer 27 during program and erase operations.

In some embodiments, the high-K dielectric layer 356 can be formed using silicon nitride or hafnium oxide (HfO₂) or silicon oxynitride (SiON). Meanwhile, the first dielectric layer 330 can be formed using silicon dioxide. In some embodiments, the first dielectric layer 330 and the sidewall high-K dielectric layer 356 has a thickness in the Z-direction of 20-25 nm, which also establishes the effective channel length of the ferroelectric storage transistors 300e.

In some embodiments, the sidewall high-K dielectric layer 356 can be provided in the fabrication process by forming a recess in the channel spacer insulating layer and etching a conformally deposited high-K dielectric layer. In some examples, after the deposition process of the multilayer stack (e.g. FIG. 4(a)) and the patterning of the multilayer stack to form local word line trenches 80 (e.g. FIG. 4(b)), the channel spacer dielectric layer 330 is recessed, such as by using an atomic layer etch (ALE) process, as shown in FIG. 6(f). In some embodiments, the channel spacer dielectric layer 330 is a silicon oxide layer and is recessed by 2-6 nm. Then, referring to FIG. 6(f), a conformal layer of high-K dielectric material 355 is deposited on the sidewall of the trenches, filling the recess in the channel spacer dielectric layer 330. In some embodiments, the high-K dielectric layer 355 is a hafnium oxide (HfO₂) layer. After deposition of the high-K dielectric layer 355, the high-K dielectric layer 355 is etched back anisotropically to the sidewall of the trench 80, as shown by the dotted line 357. Remaining portions of the high-K dielectric layer in the recess of the channel spacer dielectric layer forms the sidewall high-K dielectric layer 356 (FIG. 6(e)). In some embodiments, the conformally deposited high-K dielectric layer 355 has a thickness that is about twice the thickness of the recess formed in the channel spacer dielectric layer. For example, when the channel spacer dielectric layer is recessed by 2-6 nm, the conformally deposited high-K dielectric layer 355 can have a thickness of 4-12 nm. In this manner, the high-K dielectric layer 355 formed on trench sidewall can be etched back with the portions remaining in the recess areas. The fabrication process of the ferroelectric storage transistors continue with the deposition of the channel layer and continues to form the local word line structures, as described above with reference to FIGS. 4(c) to 4(p). Ferroelectric storage transistors 300e including the sidewall high-K dielectric layer 356 are thus formed, as shown in FIG. 6(e).

In some embodiments, the ferroelectric memory transistors 300c and 300d can be formed using the fabrication process described above with reference to FIGS. 4(a) to 4(p). For example, the dielectric sub-layers 300a and 300b and the sub-layer 360 may be provided in the fabrication process by including the sub-layers in the deposition process forming the multilayer stack, such as described with reference to FIG. 4(a). Alternately, the sub-layers may be provided initially as sacrificial layers, subsequently selectively replaced by the desired materials for the dielectric sub-layers 330a, 300b and the virtual back-gate sub-layer 360.

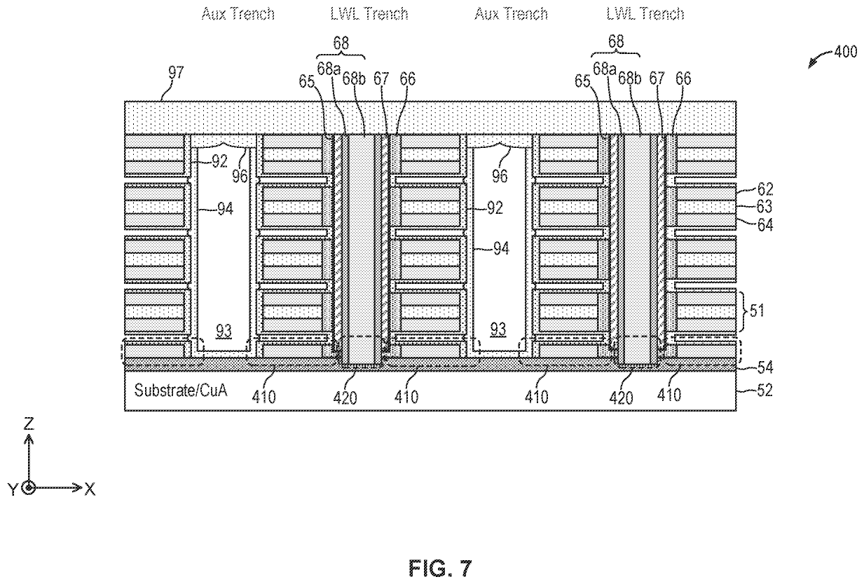

FIG. 7 is a cross-sectional view of a memory structure including a 3-dimensional array of NOR memory strings in alternate embodiments of the present invention. Referring to FIG. 7, a memory structure 400 is constructed in substantially the same way as described above and the structure and method of construction will not be repeated to simplify the discussion. Like elements in FIG. 7 and in previous figures are given like reference numerals and will not be further described. In the present embodiment, the memory structure 400 is constructed with metal bracing to provide anchoring and support to the memory stacks thus formed. The metal bracing is particularly beneficial when the memory structure includes a large number of memory planes, such as 16 or 32 or more memory planes (or active layers). In some embodiments, the memory structure 400 includes a base metal layer 410 formed at the bottom of the active layers and attached to the insulating layer 54 to provide metal bracing and anchoring of the gate conductors 68 in the LWL trenches formed thereon, thereby securing the active layers 51 formed adjacent the LWL trenches. In the present embodiment, the base metal layer 410 is a dummy metal layer formed in the same manner as one of the first and second conductive layers serving as the drain line and source line of the storage transistors, as described above with reference to FIGS. 4(a) to 4(p). For example, the base metal layer 410 can be formed by a metal replacement process where an initial sacrificial layer is removed and replaced with a metal layer.

More specifically, the base metal layer 410 can be introduced as an additional sacrificial layer 71 during the deposition of the thin films forming the multilayer 51 and the inter-layer sacrificial layer 70, as shown and described in FIG. 4(a). That is, an additional metal replacement sacrificial layer can be deposited on the insulating layer 54 before the remaining layers of thin films are deposited. Subsequent processing replaces the additional sacrificial layer with a metal layer, such as tungsten, or titanium-nitride lined tungsten, or tungsten-nitride lined tungsten, to form the dummy metal layer 61, as shown in FIG. 4(k).

In the present embodiment, the memory structure 400 further includes metal bracing provided by the metal pillars of the gate conductors 68 in the Z-direction. During the fabrication of forming the gate conductor layer, such as during the step shown in FIG. 4(f), after the removal of the sacrificial material 82 and the liner 81, the excavated cavity can be etched anisotropically to punch through the bottom of the LWL shafts into the insulating layer 54. The subsequent deposition of the gate conductor layer 68 includes portions 420 of the gate conductor being formed in the insulating layer 54. By extending the gate conductor layer 68 into the insulating layer 54, the gate conductor layer 68 is anchored into the insulating layer and provides additional support to the memory stacks formed on the two sides of the gate conductor. In some embodiments, the insulating layer 54 is a silicon oxycarbide (SiOC) layer.

In the present description, layer dimensions and thicknesses or materials used to form the three-dimensional NOR memory strings of ferroelectric storage transistors are provided as illustrative examples only and are not intended to be limiting. In other embodiments, other dimension and thickness values or other materials may be used to form the memory structure of the present invention.

The memory structures disclosed herein are illustrated above by arranging junctionless ferroelectric storage transistors in three-dimensional horizontal NOR memory strings. In other embodiments, the memory structures may also be formed by arranging the ferroelectric storage transistors in three-dimensional vertical NOR memory strings, by applying substantially the same principles and methods disclosed herein. Vertical NOR memory strings are described in copending and commonly assigned U.S. patent application Ser. No. 17/559,101, entitled “Vertical NOR Thin-film Transistor Strings and Fabrication Thereof,” filed on Dec. 22, 2021. In some embodiments, the storage transistors of the memory string are arranged along a direction substantially normal to the planar surface of the semiconductor substrate to form vertical NOR memory strings of junctionless ferroelectric storage transistors.

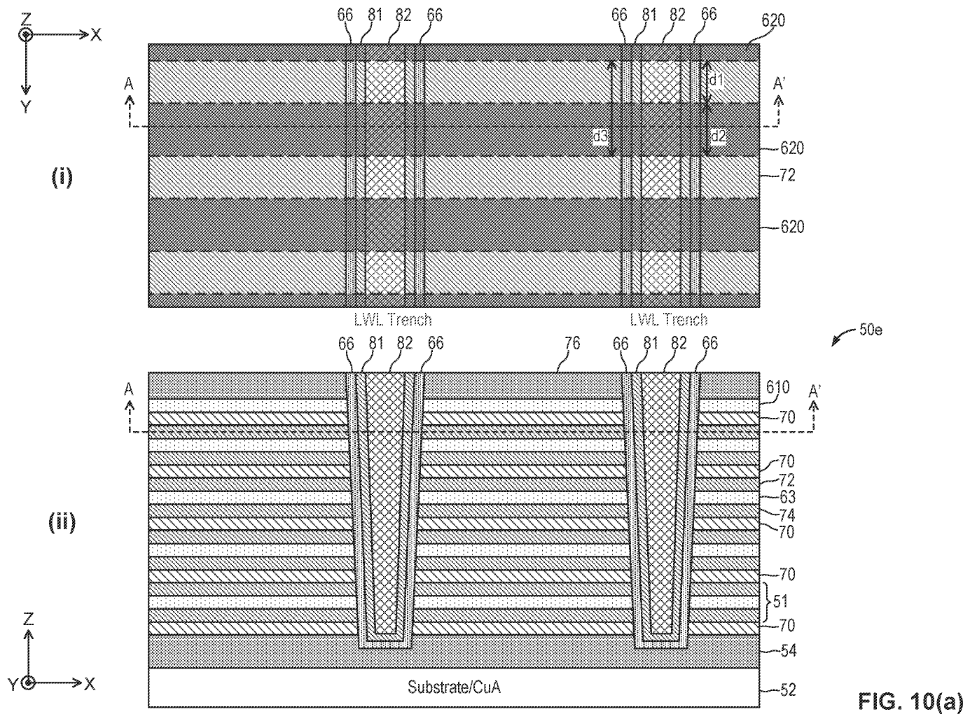

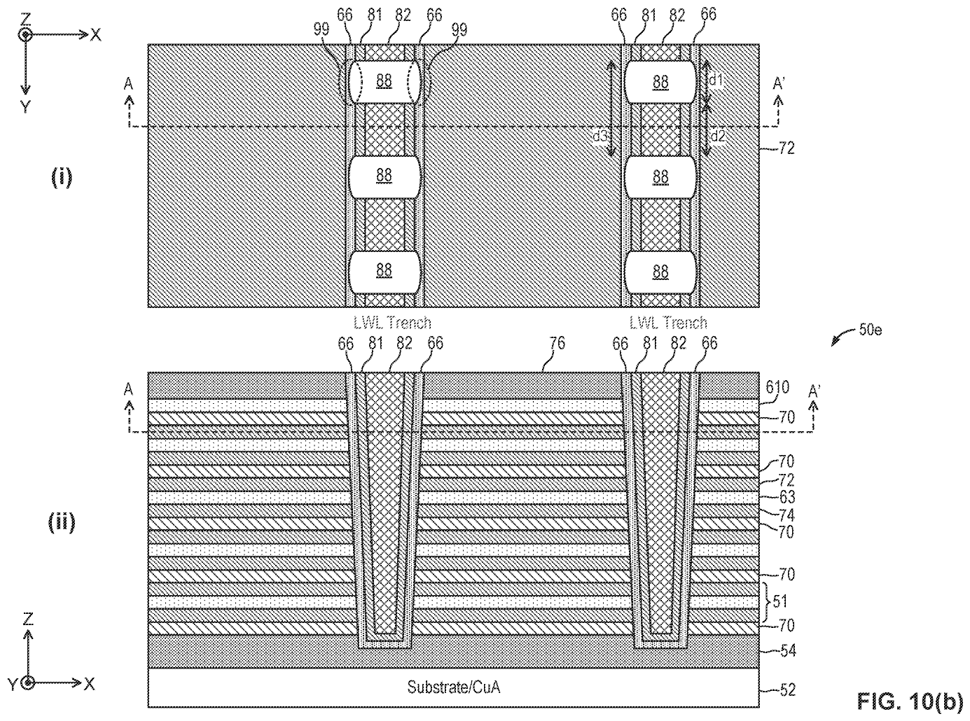

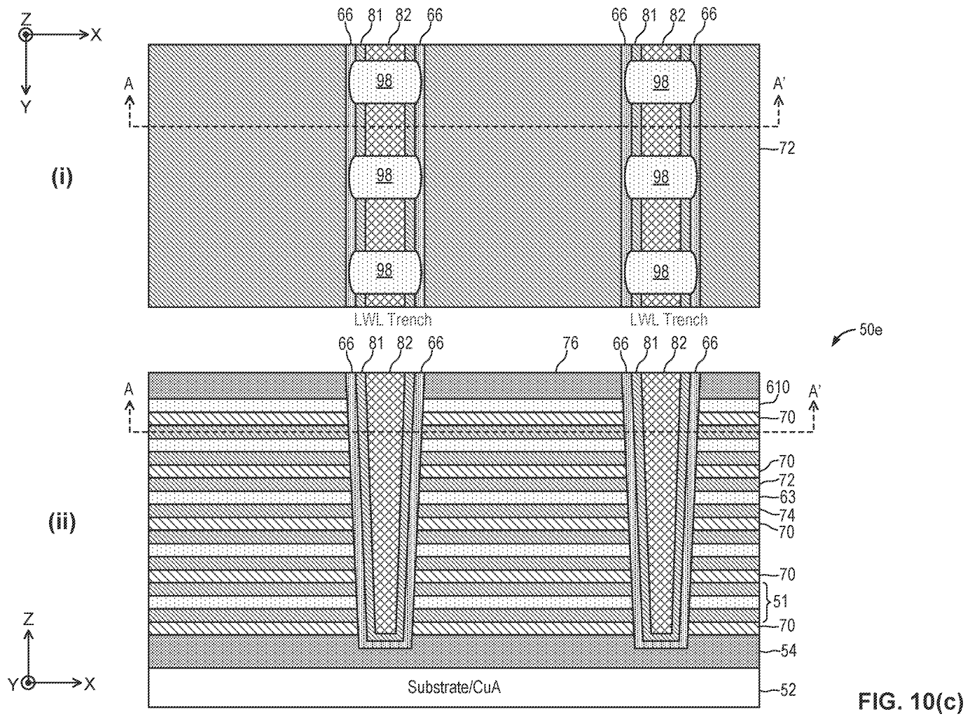

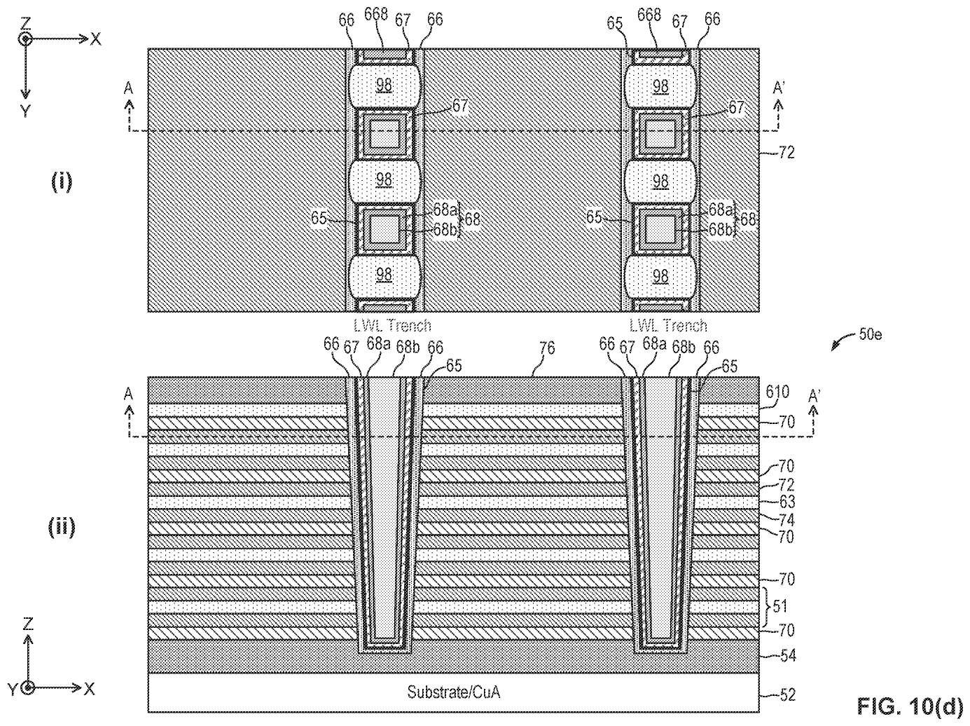

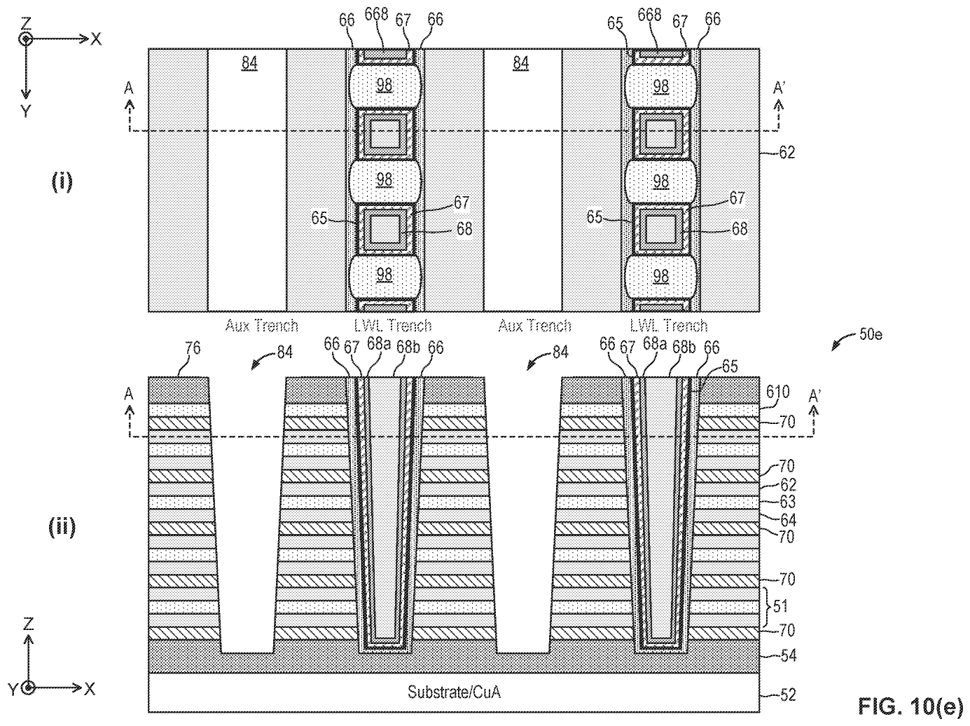

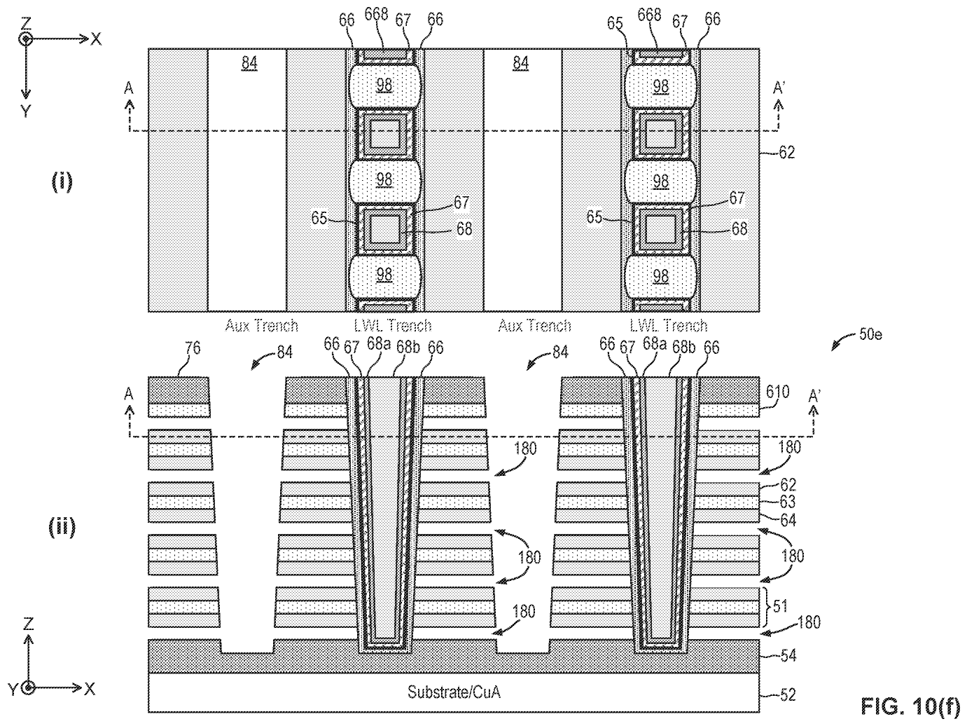

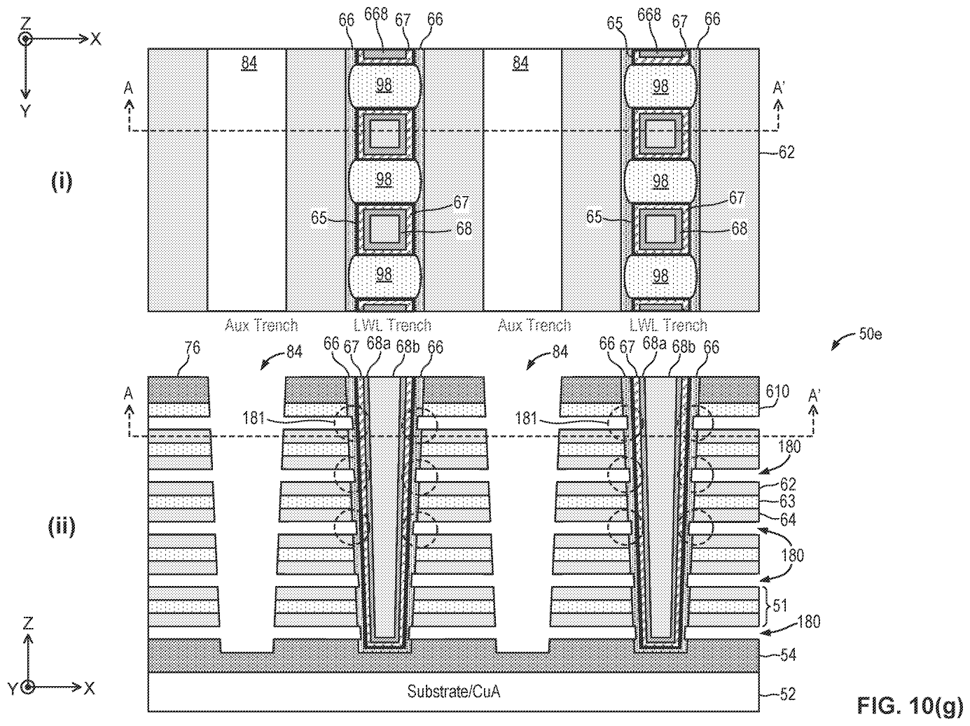

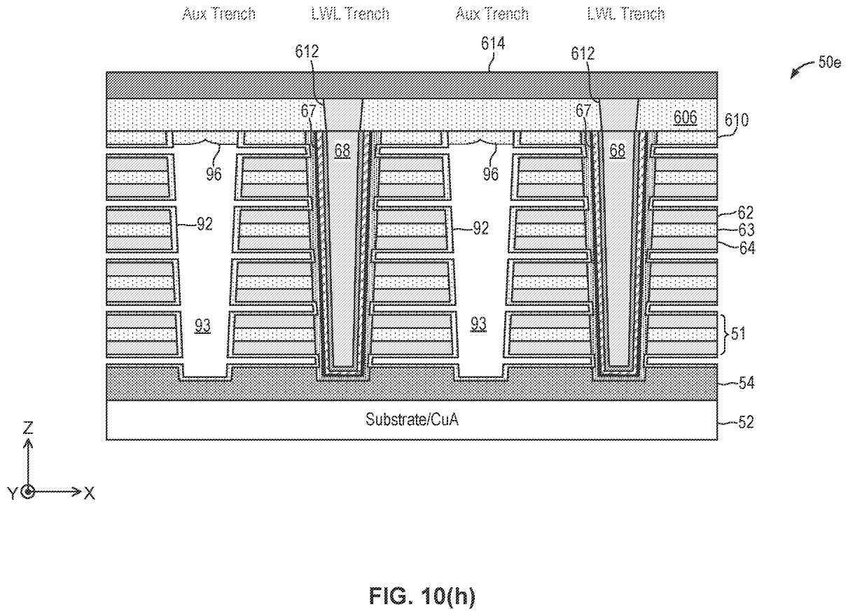

FIGS. 10(a) to 10(h) illustrate an alternate process for fabricating a memory structure including HNOR memory strings in embodiments of the present invention. FIGS. 10(a) to 10(h) illustrate a memory structure 50e constructed in a similar manner as described above. Like elements in FIGS. 10(a) to 10(h) and in previous figures are given like reference numerals and will not be further described.

First, referring to FIG. 10(a), the memory structure 50e, including inter-layer sacrificial layer 70 and active layers 51 successively formed on the insulating layer 54 on the semiconductor substrate 52, is shown in an intermediate processing step after the LWL (or operational) trenches 80 are formed in the memory structure. A channel layer 66 is deposited conformally on the sidewalls of the trenches 80. For example, the channel layer 66 is a semiconductor oxide layer, such as indium gallium zinc oxide (IGZO). Then, a liner layer 81 is deposited to cover the channel layer 66 and the remaining volume in the trenches 80 is filled with a sacrificial material 82. In one embodiment, the liner layer 81 is a silicon nitride layer or an undoped amorphous silicon layer and the sacrificial material 82 is silicon germanium or carbon. After the deposition steps, excess material may be removed from the top of memory structure 50e using, for example, chemical-mechanical polishing (CMP). The resulting memory structure 50e is shown in FIG. 10(a). In the present illustration, the trenches 80 are illustrated as having tapered sidewalls to depict more closely actual fabrication process conditions where trench openings can have smaller dimensions towards the bottom, or the depth, of the openings, in the semiconductor structure, as a result of the high aspect ratio etching to form the trench openings.

In the present example, the memory structure 50e further includes a topmost inter-layer sacrificial layer 70 and a dummy dielectric layer 610 formed on the topmost inter-layer sacrificial layer 70. The topmost inter-layer sacrificial layer 70 will be subsequently replaced by the inter-layer isolation layer, such as an air gap isolation. The dummy dielectric layer 610 functions as a capping layer for the topmost inter-layer sacrificial layer 70 during the replacement process. In particular, during subsequent processing steps, the topmost inter-layer sacrificial layer is removed to provide access openings to the backside of the channel layer 66. The channel layer 66 is selectively etched through the access openings. Accordingly, the channel layer 66 is isolated to each layer of storage transistors. The dummy dielectric layer 610 is used to provide isolation of the channel layer 66 from the global word line contacts to be formed, as will be explained in more details below.

Thereafter, the memory structure 50e is patterned to form the local word line structures. Referring to FIG. 10(a), a mask 620 (e.g. an amorphous hard mask) is applied to the memory structure 50e with openings exposing areas for forming deep shafts which will be used to isolate the storage transistors to be formed along a memory string (in the Y-direction). In the present embodiments, the mask 620 is configured in a line and space pattern where the mask 620 includes lines covering areas to be protected and space or openings exposing areas to be etched to form the deep shafts. The lines in the mask 620 can have a dimension d2 and a separation d1 in the Y-direction to define a pitch d3 of the global word line conductors to be formed above the memory array (not shown) for connecting to the local word line gate conductors yet to be formed. With the mask 620 defining the openings, the exposed sacrificial material 82 is removed, such as by a selective anisotropic etch process. The exposed liner layer 81 is then removed, such as by a selective wet etch process. Subsequently, the semiconductor oxide channel layer 66 in the area defined by the openings (or between the lines in mask 620) are removed, such as by selective anisotropic dry etch or by atomic layer etch (ALE), or by controlled selective wet etch process. As a result, shafts 88 are formed in the LWL trenches between areas where LWL structures are to be formed, as shown in FIG. 10(b). In particular, the openings in mask 620 overlap the mesas of the memory structure 50e and the etch process is self aligned to the edges of the capping layer 76, forming shafts 88 in the area of the LWL trenches only.

In the present embodiment, after removal of the sacrificial material 82 and the liner layer 81, the exposed channel material 66 is only partially etched in a controlled etch to not etch all the way through the full thickness of the channel layer 66, leaving a much thinner remaining channel material along the exposed sidewalls in shafts 88, as indicated by the dotted circles 99 in FIG. 10(b)(i). The channel layer 66 is partially etched in the shaft areas to substantially reduce its effectiveness as a parasitic channel conductor between adjacent LWL structures to be formed in the LWL trenches. The partial etching of the channel layer 66 also prevents any unintended sideway etch into the active stacks of active layers 51 at the face of the vertical sidewalls of the LWL trenches. By removing, wholly or partially, the channel material in shafts 88, physical or electrical separation of the storage transistors to be formed along each memory string in the Y-direction is realized.

Referring to FIG. 10(c), the shafts 88 are filled with a dielectric material, forming dielectric filled shafts 98. For example, the dielectric material can be a low dielectric constant oxide, such as silicon oxide (SiO₂). The dielectric filled shafts 98 serves as dielectric separation between adjacent local word lines or gate conductors to be formed in the LWL trenches. Storage transistors are to be formed along each active stack bordering the LWL trenches (in the Y-direction), in the spaces between adjacent dielectric filled shafts 98.

To form the local word line structures, the sacrificial material 82 and the liner layer 81 are removed by selective etch from the areas between the dielectric filled shafts 98, exposing the channel layer 66 which remains on the sidewalls of the mesas. The fabrication process then proceeds to form the gate dielectric layer of the storage transistors. Referring to FIG. 10(d), a gate dielectric layer 67 is deposited onto the sidewalls of the excavated cavities in the LWL trenches, on top of the channel layer 66. For example, the gate dielectric layer 67 may be deposited using atomic layer deposition. In the present embodiment, the gate dielectric layer 67 is a ferroelectric polarization layer, such as a doped hafnium oxide layer. An optional interfacial layer 65 may be formed between the channel layer 66 and the gate dielectric layer 67. For example, the interfacial layer 65 may be an ultrathin silicon nitride (Si₃N₄) layer, or a silicon oxynitride layer, or an aluminum oxide (Al₂O₃) layer. In some embodiments an optional interfacial layer (not shown), similar to the interfacial layer 65, may be deposited on the gate dielectric layer 67.

Then, a gate conductor layer 68 is deposited into the remaining volume of the excavated cavities. For instance, the gate conductor layer 68 may be deposited on the gate dielectric layer 67. After the deposition steps, excess material may be removed from the top of memory structure 50e using, for example, chemical-mechanical polishing (CMP). The resulting memory structure 50e is shown in FIG. 10(d). Between each pair of dielectric-filled trenches 98, the conductive layer 68 provides a vertical local word line (LWL) that serves as gate electrode for each of the storage transistors that are vertically aligned in the same active stack. In embodiments of the present disclosure, the gate conductor layer 68 is a metal layer. In one embodiment, the gate conductor layer 68 can be a single conductive layer, such as a titanium nitride (TiN) layer or a tungsten nitride (WN) layer.

In the present embodiment, the gate conductor 68 is formed using a two-step deposition process to deposit two different types of conductive materials. For instance, the gate conductor 68 may be formed with a first deposition step forming a metal cap layer 68a, such as a titanium nitride (TiN) layer or a tungsten nitride (WN) liner, on the ferroelectric polarization layer 67. The deposition of the metal cap layer 68a does not completely filling the trench. The process is followed by a second deposition step of a metal filler layer 68b, such as a tungsten layer, on the metal cap layer to fill the remaining space in each LWL trench. The metal filler layer 68b may be other metal or conductive materials, such as molybdenum (Mo), or heavily doped n-type or p-type polysilicon.

In performing the depositions of layers 65, 67, 68, it is preferable for these depositions to be performed as much as possible without breaking vacuum, or at least minimizing the time between depositions that may cause unwanted surface oxidation of the exposed surfaces. Similarly, it is important that the deposition temperatures, the ambient chemicals existing during depositions, and pre-deposition and post-depositions anneal conditions be optimized for maximum orthorhombic crystallization of the ferroelectric gate dielectric layer.

The process of forming the memory structure 50e continues in the same manner as described above with reference to FIGS. 4(f) to 4(p). For instance, referring to FIG. 10(e), a mask is applied to form auxiliary trenches 84 between the LWL trenches already formed. With the auxiliary trenches 84 thus formed, the fabrication process performs metal replacement where the first and second sacrificial layers 72 and 74 are removed and replaced with the respective first and second conductive layers 62, 64.

Following the metal replacement process, the auxiliary trenches 84 will now be used for separating the channel layer 66 between each active layer 51, in a process referred to as channel separation. Referring to FIG. 10(f), using the auxiliary trenches 84 which exposes the inter-layer sacrificial layer 70 from the sides of the active stack, the fabrication process removes the inter-layer sacrificial layer 70, leaving cavities 180 in places where the inter-layer sacrificial layer 70 used to be. The cavities 180 thus formed expose backside portions of the channel layer 66 between the multilayers 51 in the active stacks. The auxiliary trenches 84 and the cavities are then used to remove the exposed portions of the channel layer 66 that straddle two adjacent multilayers 51 in the active stack (in the Z-direction). As a result, the channel layer 66 is separated in the Z-direction to each multilayer 51.

Referring to FIG. 10(g), in the present embodiment, the exposed portions of the channel layer 66 between two adjacent multilayers 51 in the active stack (in the Z-direction) is partially removed, leaving a thin portion of the channel material behind between adjacent multilayers 51, as shown by the dotted circles 181. The partially etched channel layer does not function effectively as a parasitic channel conductor and the multilayers 51 are effectively separated. Meanwhile, unintended undercutting of the channel layer into the multilayers is avoided.

Referring to FIG. 10(h), after the channel separation process, the exposed surfaces of the memory structure 50e may be passivated, such as by forming a thin dielectric liner layer 92. The liner layer 92 can be a silicon oxide layer, a silicon nitride layer or an aluminum oxide layer and serves to passivate or seal the exposed surfaces in the cavities and the auxiliary trenches 84.

In some embodiments, the remaining cavities 93 in the memory structure 50e may be filled with a low-K dielectric material, such as silicon oxide. In the embodiment shown in FIG. 10(h), the cavities 93 are left unfilled to form air gap isolation. A dielectric layer 96 is formed at the top portions of the auxiliary trenches 84, such as by non-conformal deposition of a dielectric layer. A cap oxide layer 606 may be formed above the completed memory structure 50e. In some embodiments, the cap oxide layer 606 may be a silicon oxide layer. In other embodiments a two-level air-gap isolation, such as that shown in FIG. 4(o1), may be used.

As thus formed, the memory structure 50e includes storage transistors arranged in NOR memory strings in multiple planes. In particular, the storage transistors have substantially the same structure as the storage transistor 20 as described in FIG. 1. Vias and interconnects are formed in and above the cap oxide layer 606 to form interconnection between the storage transistors and the control circuitry, such as the CuA formed in the substrate 52. For example, a global word line metallization layer 614 is formed on the cap oxide layer 606 and connected to local word lines 68 formed in the memory structure through vias 612 formed in the cap oxide layer 606. As thus constructed, the memory structure 50e includes ferroelectric storage transistors with desired ferroelectric properties in the ferroelectric polarization layer. In particular, crystallization of the ferroelectric polarization layer is effectuated by using the gate conductor layer 68 as a capping layer to provide the desired tensile stress to encourage the beneficial crystallization of the ferroelectric polarization layer into the ferroelectric orthorhombic phase. In some embodiments, the crystallization is in-situ during the deposition of the gate conductor capping layer.

It is instructive to note that the channel layer 66 for the topmost memory strings in the memory structure 50e is separated and isolated by the topmost isolation layer formed under the dummy dielectric layer 610. Vias 612 can be formed to contact the local word lines (gate conductor layer 668) without concern for possible electrical shorts to the channel layer. Each global word line 614 connects to the local word lines through vias 612 to provide the control signal to the gate electrodes of the storage transistors formed in multiple memory planes associated with the respective vertical local word lines.

In this detailed description, process steps described for one embodiment may be used in a different embodiment, even if the process steps are not expressly described in the different embodiment. When reference is made herein to a method including two or more defined steps, the defined steps can be carried out in any order or simultaneously, except where the context dictates or specific instruction otherwise are provided herein. Further, unless the context dictates or express instructions otherwise are provided, the method can also include one or more other steps carried out before any of the defined steps, between two of the defined steps, or after all the defined steps. For example, formation of the auxiliary (“back alley”) trenches can be implemented partially or in whole, either after formation of the operational (“LWL”) trenches or before formation of the operational trenches. Likewise, formation of the precharge transistors can be completed before or after formation of the operational trenches.

In this detailed description, various embodiments or examples of the present invention may be implemented in numerous ways, including as a process; an apparatus; a system; and a composition of matter. A detailed description of one or more embodiments of the invention is provided above along with accompanying figures that illustrate the principles of the invention. The invention is described in connection with such embodiments, but the invention is not limited to any embodiment. Numerous modifications and variations within the scope of the present invention are possible. The scope of the invention is limited only by the claims and the invention encompasses numerous alternatives, modifications, and equivalents. Numerous specific details are set forth in the description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured. The present invention is defined by the appended claims.

1. A three-dimensional memory structure formed above a planar surface of a semiconductor substrate, the memory structure comprising:
a plurality of memory stacks arranged along a first direction, each memory stack being separated from each of its immediately neighboring memory stacks along the first direction by a trench, each memory stack and each trench extending in a second direction, the first and second directions being orthogonal to each other and both being substantially parallel to the planar surface of the semiconductor substrate,
wherein (i) each memory stack comprises at least one active layer, the active layer comprising a first conductive layer and a second conductive layer spaced apart by a first isolation layer; and (ii) the trenches comprise trenches of a first type and trenches of a second type, alternately arranged along the first direction;
a plurality of gate electrode structures being provided in the trenches of the first type and arranged spaced apart in the second direction, the gate electrode structures extending in a third direction substantially normal to the planar surface of the semiconductor substrate, each gate electrode structure including (i) a semiconductor oxide layer formed on the sidewalls of the trenches of the first type and in contact with the first and second conductive layers; (ii) a ferroelectric dielectric layer provided adjacent the semiconductor oxide layer; and (iii) a gate conductor layer formed adjacent the ferroelectric dielectric layer; and
an isolation material provided in the trenches of the second type,
wherein each active layer in the memory stack forms a plurality of thin-film ferroelectric memory transistors organized as a NOR memory string, each memory transistor being formed at the intersection of the active layer and a gate electrode structure, the plurality of memory stacks forming a plurality of NOR memory strings in the trenches of the first type.

2. The three-dimensional memory structure of claim 1, wherein the memory transistors within each NOR memory string share the first conductive layer, which serves as a common drain line, and share the second conductive layer, which serves as a common source line, the semiconductor oxide layer in contact with and in between the first and second conductive layers serving as a junctionless channel region of each memory transistor in each NOR memory string.

3. The three-dimensional memory structure of claim 2, wherein the common source line is an electrically floating source.

4. The three-dimensional memory structure of claim 2, wherein each memory stack comprises a plurality of active layers being provided one on top of another along the third direction and being isolated one from the other active layer by a second isolation layer, the plurality of memory stacks forming a plurality of stacks of NOR memory strings of thin-film memory transistors in the trenches of the first type.

5. The three-dimensional memory structure of claim 4, wherein, within a memory stack of NOR memory strings, the channel regions for the memory transistors of a first NOR memory string are separated from the channel regions for the memory transistors of a second adjacent NOR memory string in the third direction by the second isolation layer.

6. The three-dimensional memory structure of claim 5, wherein, within a memory stack of NOR memory strings, the semiconductor oxide layer is removed in a region between two adjacent active layers in the third direction.

7. The three-dimensional memory structure of claim 5, wherein, within a memory stack of NOR memory strings, a part of the semiconductor oxide layer opposite the ferroelectric dielectric layer is removed in a region between two adjacent active layers in the third direction, at least part of the semiconductor oxide layer remaining in the region between two adjacent active layers.

8. The three-dimensional memory structure of claim 5, wherein the second isolation layer comprises an air gap cavity.

9. The three-dimensional memory structure of claim 1, wherein the isolation material in the trenches of the second type comprises a silicon oxide layer.

10. The three-dimensional memory structure of claim 1, wherein the ferroelectric dielectric layer comprises a doped hafnium oxide layer.

11. The three-dimensional memory structure of claim 1, further comprises an interfacial layer formed between the semiconductor oxide layer and the ferroelectric dielectric layer.

12. The three-dimensional memory structure of claim 1, wherein the semiconductor oxide layer comprises one of an indium gallium zinc oxide (IGZO) layer, an indium zinc oxide (IZO) layer, an indium tungsten oxide (IWO) layer, or an indium tin oxide (ITO) layer.

13. The three-dimensional memory structure of claim 12, wherein the semiconductor oxide layer comprises a first semiconductor oxide layer and a second semiconductor oxide layer, the first semiconductor oxide layer being provided in contact with the first and second conductive layers and providing a contact resistance to the first and second conductive layers lower than the contact resistance of the second semiconductor layer.

14. The three-dimensional memory structure of claim 1, wherein the first conductive layer and the second conductive layer each comprises a metal layer.

15. The three-dimensional memory structure of claim 1, wherein the first isolation layer comprises a silicon oxide layer.

16. The three-dimensional memory structure of claim 1, wherein a channel length of each memory transistor is a function of a thickness of the first isolation layer in the third direction.

17. The three-dimensional memory structure of claim 16, wherein the thickness of the first isolation layer in the third direction is in the range of 5-10 nm.

18. The three-dimensional memory structure of claim 1, wherein a first group of memory transistors within each NOR memory string is designated as precharge transistors, the precharge transistors being activated during a precharge operation to electrically connect the first and second conductive layers in each NOR memory string to equalize the voltage on the second conductive layer to the voltage on the first conductive layer.

19. The three-dimensional memory structure of claim 18, wherein in each NOR memory string, a memory transistor in the first group is selected to operate as the precharge transistor for the NOR memory string in a substantially random manner.

20. The three-dimensional memory structure of claim 18, wherein in each NOR memory string, each of the memory transistors in the first group is selected in turn to operate as the precharge transistor for a given number of precharge operations or for a given time interval.

21. The three-dimensional memory structure of claim 18, wherein in each NOR memory string, a memory transistor in the first group selected to operate as the precharge transistor is evaluated to determine a health condition of the selected memory transistor, and in response to the selected memory transistor being determined to have a health condition indicative of a failing condition, the selected memory transistor is retired and another memory transistor in the first group is selected to operate as the precharge transistor for the NOR memory string.

22. The three-dimensional memory structure of claim 1, wherein the memory transistors in the NOR memory strings each have a first transistor width, each NOR memory string further comprises a second group of memory transistors having a second transistor width greater than the first transistor width, the memory transistors in the second group being designated as precharge transistors, the precharge transistors being activated during a precharge operation to electrically connect the first and second conductive layers in each NOR memory string to equalize the voltage on the second conductive layer to the voltage on the first conductive layer.

23. The three-dimensional memory structure of claim 1, further comprising a plurality of non-memory transistors formed in each NOR memory string, the non-memory transistors being designated as precharge transistors, the precharge transistors being activated during a precharge operation to electrically connect the first and second conductive layers in each NOR memory string to set the voltage on the second conductive layer to equal to the voltage on the first conductive layer.

24. The three-dimensional memory structure of claim 23, wherein in each NOR memory string, each of the non-memory precharge transistors shares with the memory transistors the common source line, the common drain line, and the semiconductor oxide channel layer, and wherein the non-memory precharge transistor includes a non-polarizable gate dielectric layer.

25. The three-dimensional memory structure of claim 2, wherein in each memory transistor in the NOR memory string, the common drain line and the common source line are biased to substantially the same voltage during a program or an erase operation of the memory transistor.

26. The three-dimensional memory structure of claim 1, wherein the first isolation layer comprises a first dielectric layer having a first dielectric constant formed adjacent the first conductive layer and a second dielectric layer having a second dielectric constant formed adjacent the second conductive layer, the first dielectric constant being greater than the second dielectric constant.

27. The three-dimensional memory structure of claim 1, wherein the first isolation layer comprises a first dielectric layer having a first dielectric constant formed adjacent the first conductive layer, a second dielectric layer having a second dielectric constant formed adjacent the second conductive layer, and a third dielectric layer having a third dielectric constant formed between the first and second dielectric layers, the first and second dielectric constants being greater than the third dielectric constant.

28. The three-dimensional memory structure of claim 1, wherein the first isolation layer comprises a dielectric layer having a dielectric constant greater than a dielectric constant of silicon oxide.

29. The three-dimensional memory structure of claim 1, wherein each of the thin-film ferroelectric memory transistors comprises a front-gate electrode formed by the gate conductor layer and an electrically floating back-gate electrode formed by a back-gate layer provided in the first isolation layer.

30. The three-dimensional memory structure of claim 29, wherein the electrically floating back-gate electrode at each memory transistor has its voltage controlled by capacitive coupling to the voltages on the first conductive layer, the second conductive layer, and a portion of the semiconductor oxide layer.

31. The three-dimensional memory structure of claim 29, wherein the first isolation layer comprises a first dielectric layer formed adjacent the first conductive layer, a second dielectric layer formed adjacent the second conductive layer, and a third layer as the back-gate layer formed between the first and second dielectric layers and insulated from the first and second conductive layers, the third layer interacting with a portion of the semiconductor oxide layer to form the electrically floating back-gate electrode at each memory transistor.

32. The three-dimensional memory structure of claim 31, wherein the first conductive layer and the second conductive layer are spaced apart in the third direction by a first distance being the channel length of the thin-film ferroelectric memory transistor, the third layer having a thickness in the third direction being a portion of the channel length or being almost the entire channel length.

33. The three-dimensional memory structure of claim 31, wherein each of the first and second dielectric layers is formed from a material selected from silicon dioxide, silicon nitride, hafnium oxide, or a high dielectric constant material.

34. The three-dimensional memory structure of claim 31, wherein the third layer is formed from a material selected from a semiconductor or a low resistivity material or a metallic material.

35. The three-dimensional memory structure of claim 31, wherein the third layer is formed from a material selected from undoped silicon, P-type or N-type doped silicon, undoped polysilicon, P-type or N-type doped polysilicon, silicon germanium, titanium nitride, tungsten, or molybdenum.

36. The three-dimensional memory structure of claim 29, wherein the first isolation layer comprises a dielectric liner layer formed adjacent the first conductive layer, the channel layer and the second conductive layer, and a third layer as the back-gate layer surrounded by the dielectric liner layer and insulated from the first and second conductive layers, the third layer interacting with a portion of the semiconductor oxide layer to form the electrically floating back-gate electrode at each memory transistor.

37. The three-dimensional memory structure of claim 36, wherein the first conductive layer and the second conductive layer are spaced apart in the third direction by a first distance being the channel length of the thin-film ferroelectric memory transistor, the third layer having a thickness in the third direction being almost the entire channel length.

38. The three-dimensional memory structure of claim 36, wherein the dielectric liner layer is formed from a material selected from silicon dioxide, silicon nitride, silicon oxynitride, aluminum oxide, hafnium oxide, or a high dielectric constant material.

39. The three-dimensional memory structure of claim 36, wherein the third layer is formed from a material selected from a semiconductor or a low resistivity material or a metallic material.

40. The three-dimensional memory structure of claim 36, wherein the third layer is formed from a material selected from undoped silicon, P-type or N-type doped silicon, undoped polysilicon, P-type or N-type doped polysilicon, silicon germanium, titanium nitride, tungsten, or molybdenum.

41. The three-dimensional memory structure of claim 29, wherein at each thin-film ferroelectric memory transistor, the gate conductor layer operates as the front-gate electrode, and the first conductive layer together with the second conductive layer and the back-gate layer, operate substantially as the back-gate electrode of each of the ferroelectric memory transistors.

42. The three-dimensional memory structure of claim 41, wherein for each of the plurality of thin-film ferroelectric memory transistors, an area in the ferroelectric dielectric layer between the front-gate electrode and the back-gate electrode is an area of maximum polarization of the program state and erase state of the ferroelectric memory transistors.

43. The three-dimensional memory structure of claim 1, wherein circuitry for supporting memory operations of the memory transistors is formed at the planar surface of the semiconductor substrate substantially underneath the plurality of memory stacks.

44. The three-dimensional memory structure of claim 43, further comprising a plurality of connectors providing data path signals from the circuitry supporting the memory operations of the plurality of NOR memory strings, the plurality of connectors to be connected to corresponding connectors of a memory controller circuit formed on a second semiconductor substrate separate from the semiconductor substrate on which the memory structure is formed, the memory controller circuit including memory control circuitry for accessing and operating the memory transistors in the plurality of NOR memory strings in the memory structure.

45. The three-dimensional memory structure of claim 44, wherein the second semiconductor substrate comprises a logic integrated circuit including a processor core and the memory controller circuit is formed in a portion of the second semiconductor substrate.

46. The three-dimensional memory structure of claim 2, wherein the gate conductor layer in each gate electrode structure activates first and second ferroelectric memory transistors in each active layer in respective first and second memory strings bordering the gate electrode structure.

47. The three-dimensional memory structure of claim 46, wherein in response to the gate conductor layer being biased to a first potential to program or erase the first ferroelectric memory transistor, an inhibit voltage is applied to the common drain line associated with the second ferroelectric memory transistor to prevent the second ferroelectric memory transistor from being program or erased.

48. The three-dimensional memory structure of claim 2, wherein the gate conductor layer comprises a metal layer of a first type formed on the ferroelectric dielectric layer.

49. The three-dimensional memory structure of claim 48, wherein the gate conductor layer comprises a conductive layer selected from titanium nitride or tungsten nitride.

50. The three-dimensional memory structure of claim 2, wherein the gate conductor layer comprises a first metal layer formed on the ferroelectric dielectric layer and a second metal layer formed on the first metal layer.

51. The three-dimensional memory structure of claim 50, wherein the first metal layer comprises a metal layer selected from titanium nitride or tungsten nitride and the second metal layer comprises a metal layer selected from tungsten, or molybdenum.

52. The three-dimensional memory structure of claim 5, wherein, within a trench of the first type, the semiconductor oxide layer is removed in a region between two adjacent gate electrode structures in the second direction.

53. The three-dimensional memory structure of claim 5, wherein, within a trench of the first type, a part of the semiconductor oxide layer is removed in a region between two adjacent gate electrode structures in the second direction, at least part of the semiconductor oxide layer remaining in the region between two adjacent gate electrode structures.

54. The three-dimensional memory structure of claim 1, wherein each metal stack in the plurality of metal stacks further comprises a third conductive layer formed between the bottommost active layer and the semiconductor structure.

55. The three-dimensional memory structure of claim 1, wherein in each gate electrode structure, the gate conductor layer extends into the semiconductor substrate.

56. The three-dimensional memory structure of claim 1, wherein the semiconductor oxide layer is a continuous layer on the sidewalls of the trenches of the first type in the second direction.

57-75: (canceled)
